(19) United States
(12) Patent Application Publication
(10) Pub. No.: US 2025/0247071 A1
(43) Pub. Date: Jul. 31, 2025

(54) ACOUSTIC WAVE FILTER AND HIGH FREQUENCY MODULE

(71) Applicant: Murata Manufacturing Co., Ltd., Kyoto (JP)

(72) Inventors: Minoru IWANAGA, Kyoto (JP); Takuma KUROYANAGI, Kyoto (JP); Takashi WATANABE, Kyoto (JP); Yuudai TANOUE, Kyoto (JP); Akira OGASAWARA, Kyoto (JP); Hiroyuki YAMAMOTO, Kyoto (JP); Mayuka ONO, Kyoto (JP); Morio TAKEUCHI, Kyoto (JP); Terumichi KITA, Kyoto (JP)

(21) Appl. No.: 19/037,128

(22) Filed: Jan. 25, 2025

(30) Foreign Application Priority Data
Jan. 26, 2024 (JP) 2024-010265

(51) Int. Cl. H03H 9/05; H03H 9/00; H03H 9/54; H03H 9/56

(52) U.S. Cl. CPC H03H 9/0552; H03H 9/0004; H03H 9/0542; H03H 9/542; H03H 9/568

(57) ABSTRACT

An acoustic wave filter includes a first series arm resonance unit in a series arm path connecting a first input/output terminal and a second input/output terminal, and a first parallel arm resonance unit between the series arm path and a ground, in which each of the first series arm resonance unit and the first parallel arm resonance unit includes an acoustic wave resonator, a first resonant frequency of the first series arm resonance unit and a second resonant frequency of the first parallel arm resonance unit are equal to or lower than a low frequency end of a pass band of the acoustic wave filter, a first anti-resonant frequency of the first series arm resonance unit and a second anti-resonant frequency of the first parallel arm resonance unit are equal to or higher than a high frequency end of the pass band.

### CROSS REFERENCE TO RELATED APPLICATION

This application claims priority from Japanese Patent Application No. 2024-010265 filed on Jan. 26, 2024. The content of this application is incorporated herein by reference in its entirety.

### BACKGROUND ART

The present disclosure relates to an acoustic wave filter and a high frequency module.

Japanese Unexamined Patent Application Publication No. 2018-088675 discloses a filter module provided with a band pass type filter and a matching resonance unit. Since the pass band of the filter is included in a range between the resonant frequency and the anti-resonant frequency of the matching resonance unit, the impedance of the pass band of the filter module can be inductive.

### BRIEF SUMMARY

In the filter module disclosed in Japanese Unexamined Patent Application Publication No. 2018-088675, since the impedance of the pass band can be made inductive by the matching resonance unit, the matching loss in a case of being connected to an external circuit having capacitive impedance can be reduced. However, there is a case where the insertion loss of the matching resonance unit itself cannot be reduced, and there is a problem in that the low loss characteristics of the filter module cannot be ensured.

The present disclosure provides an acoustic wave filter in which low loss characteristics are ensured, and a high frequency module including the same.

An acoustic wave filter according to an aspect of the present disclosure is a band pass type acoustic wave filter, the filter including a first series arm resonance unit disposed in a series arm path connecting a first input/output terminal and a second input/output terminal, and a first parallel arm resonance unit connected between the series arm path and a ground, in which each of the first series arm resonance unit and the first parallel arm resonance unit includes an acoustic wave resonator, a first resonant frequency, which is a resonant frequency of the first series arm resonance unit, and a second resonant frequency, which is a resonant frequency of the first parallel arm resonance unit, are equal to or lower than a low frequency end of a pass band of the acoustic wave filter, a first anti-resonant frequency, which is an anti-resonant frequency of the first series arm resonance unit, and a second anti-resonant frequency, which is an anti-resonant frequency of the first parallel arm resonance unit, are equal to or higher than a high frequency end of the pass band, and the first resonant frequency is higher than the second resonant frequency, and the first anti-resonant frequency is higher than the second anti-resonant frequency.

In addition, a high frequency module according to an aspect of the present disclosure includes a mounting substrate that has a first main surface and a second main surface facing each other, the acoustic wave filter, and a low noise amplifier in which an input terminal is connected to a first input/output terminal, in which the acoustic wave filter is disposed on the first main surface, the low noise amplifier is disposed on the second main surface, and in a plan view of the mounting substrate, the acoustic wave filter and the low noise amplifier at least partially overlap with each other.

According to the present disclosure, it is possible to provide an acoustic wave filter and a high frequency module in which low loss characteristics are ensured.

### BRIEF DESCRIPTION OF THE DRAWINGS

FIG. 1 is a circuit configuration diagram of an acoustic wave filter and a high frequency module according to an embodiment;

FIGS. 2AA to 2AC are a plan view and a cross-sectional view schematically illustrating a first example of an acoustic wave resonator forming the acoustic wave filter according to the embodiment;

FIG. 2B is a cross-sectional view schematically illustrating a second example of an acoustic wave resonator forming the acoustic wave filter according to the embodiment;

FIG. 2C is a cross-sectional view schematically illustrating a third example of an acoustic wave resonator forming the acoustic wave filter according to the embodiment;

FIG. 3 is a graph illustrating bandpass characteristics of the acoustic wave filter and impedance characteristics of each acoustic wave resonance unit according to the embodiment;

FIG. 4 is a diagram schematically illustrating the bandpass characteristics of the acoustic wave filter according to the embodiment and the impedance characteristics of a first series arm resonance unit and a first parallel arm resonance unit;

FIG. 5A is a circuit configuration diagram of the high frequency module according to the embodiment;

FIG. 5B is a circuit configuration diagram of a high frequency module according to a comparative example;

FIG. 6A is a Smith chart illustrating the impedance of a pass band of the high frequency module according to the embodiment and the comparative example;

FIG. 6B is a graph illustrating a relationship between an inductance value and a noise figure of a matching inductor of the high frequency module according to the comparative example;

FIG. 6C is a graph illustrating frequency characteristics of noise figures according to the embodiment and the comparative example;

FIG. 7 is a circuit configuration diagram of an acoustic wave filter according to Modification Example 1 of the embodiment;

FIG. 8A is a circuit configuration diagram of an acoustic wave filter according to Modification Example 2 of the embodiment;

FIG. 8B is a graph illustrating bandpass characteristics of the acoustic wave filter according to Modification Example 2 in a band near a pass band and impedance characteristics of the first parallel arm resonance unit;

FIG. 8C is a graph illustrating impedance characteristics of a wide-band first parallel arm resonance unit of the acoustic wave filter according to Modification Example 2;

FIGS. 9A-9C include a plan view and a cross-sectional view of the high frequency module according to the embodiment;

FIG. 10 is a circuit configuration diagram of a high frequency module according to Modification Example 3;

FIG. 11A is a plan view of the high frequency module according to Modification Example 3;

FIG. 11B is a cross-sectional view of the high frequency module according to Modification Example 3;

FIG. 12A is a plan view of a high frequency module according to Modification Example 4;

FIG. 12B is a cross-sectional view of a high frequency module according to Modification Example 4;

FIG. 13 is a cross-sectional view of a high frequency module according to Modification Example 5;

FIG. 14A is a plan view of a high frequency module according to Modification Example 6;

FIG. 14B is a cross-sectional view of the high frequency module according to Modification Example 6;

FIG. 15A is a circuit configuration diagram of a high frequency module according to Modification Example 7;

FIG. 15B is a schematic plan view of the high frequency module according to Modification Example 7;

FIG. 15C is a cross-sectional view of the high frequency module according to Modification Example 7;

FIG. 16A is a plan view of a filter integrated component according to Modification Example 8;

FIG. 16B is a plan view of a filter integrated component according to Modification Example 9;

FIG. 17A is a circuit configuration diagram of a high frequency module according to Modification Example 10;

FIG. 17B is a plan view of a filter integrated component according to Modification Example 10;

FIGS. 18A-18C include a plan view and a cross-sectional view of a filter integrated component according to Modification Example 11;

FIG. 19A is a circuit configuration diagram of a high frequency module according to Modification Example 12;

FIG. 19B is a plan view of the high frequency module according to Modification Example 12;

FIG. 20A is a circuit configuration diagram of a high frequency module according to Modification Example 13;

FIG. 20B is a plan view of the high frequency module according to Modification Example 13;

FIG. 21A is a circuit configuration diagram of a high frequency module according to Modification Example 14;

FIG. 21B is a plan view of the high frequency module according to Modification Example 14;

FIG. 22A is a circuit configuration diagram of a high frequency module according to Modification Example 15;

FIG. 22B is a plan view of the high frequency module according to Modification Example 15;

FIG. 23A is a circuit configuration diagram of a high frequency module according to Modification Example 16;

FIG. 23B is a plan view of the high frequency module according to Modification Example 16;

FIG. 24A is a circuit configuration diagram of a high frequency module according to Modification Example 17;

FIG. 24B is a plan view of the high frequency module according to Modification Example 17;

FIG. 25A is a circuit configuration diagram of a high frequency module according to Modification Example 18;

FIG. 25B is a plan view of the high frequency module according to Modification Example 18;

FIG. 26 is a plan view of a high frequency module according to Modification Example 19;

FIG. 27A is a circuit configuration diagram of a high frequency module according to Modification Example 20;

FIG. 27B is a plan view of the high frequency module according to Modification Example 20;

FIG. 28A is a circuit configuration diagram of a high frequency module according to Modification Example 21;

FIG. 28B is a plan view of the high frequency module according to Modification Example 21;

FIG. 29A is a circuit configuration diagram of a high frequency module according to Modification Example 22; and

FIG. 29B is a plan view of the high frequency module according to Modification Example 22.

### DETAILED DESCRIPTION

Hereinafter, embodiments of the present disclosure will be described in detail with reference to the drawings. All of the embodiments described below describe comprehensive or specific examples. Numerical values, shapes, materials, components, or dispositions and connection forms of the components which are described in the following embodiments are merely examples, and are not intended to limit the present disclosure. In the components of the following embodiments, components which are not described in an independent claim will be described as optional components. In addition, sizes or size ratios of the components illustrated in drawings are not necessarily exact.

Each drawing is a schematic view in which emphasis, omission, or ratio adjustment is made as appropriate to represent the present disclosure, and is not necessarily illustrated strictly. In some cases, a shape, a positional relationship, and a ratio may be different from actual ones. In the drawings, the substantially same configurations are represented by the same reference numerals, and repeated description thereof will not be given or will be simplified in some cases.

In the circuit configuration of the present disclosure, the term “being connected” means not only a case of being directly connected through a connection terminal and/or a wire conductor but also a case of being electrically connected with a matching element or a switch circuit interposed therebetween. The term “being connected between A and B” means being connected to both A and B between A and B.

In the present disclosure, the term “terminal” means a point where a conductor ends inside an element. In a case where the impedance of the conductor between the elements is sufficiently low, the terminal is interpreted not only as a single point but also as any point (node) on the conductor between the elements or the entire conductor.

In addition, in a circuit element disposition of the present disclosure, the fact that “a circuit element A being arranged in series in a path B” means that a signal input terminal and a signal output terminal of the circuit element A are connected to two wires forming at least a part of the path B. At least one of the two wires may be an electrode or a terminal.

In the following drawings, an x-axis and a y-axis are axes orthogonal to each other on a plane parallel to a main surface of a module substrate. Specifically, in a case where the module substrate is rectangular in plan view, the x-axis is parallel to a first edge of the module substrate, and the y-axis is parallel to a second edge of the module substrate orthogonal to the first edge. In addition, a z-axis is an axis perpendicular to the main surface of the module substrate, a positive direction thereof indicates an up direction, and a negative direction thereof indicates a down direction.

In addition, a term representing a relationship between elements such as “parallel” and “perpendicular”, a term representing a shape of an element such as “rectangular”, and a numerical range means not only strict meanings but also a substantially equivalent range, for example, a range including an error of approximately several percent.

In the component disposition of the present disclosure, the term “in a plan view of the module substrate” means that an object is viewed in an orthogonal projection from a z-axis positive side to an xy plane. The fact that “A overlaps with B in a plan view” means that at least a part of a region of A that is orthogonally projected onto the xy-plane overlaps with at least a part of a region of B that is orthogonally projected onto the xy-plane. The fact that “A is disposed between B and C” means that at least one of a plurality of line segments connecting any point in B and any point in C passes through A.

In a component disposition of the present disclosure, the fact that “the component is disposed on the substrate” means that the component is disposed on the main surface of the substrate and that the component is disposed in the substrate. The fact that “the component is disposed on the main surface of the substrate” means that the component is disposed above the main surface without necessarily being in contact with the main surface (for example, the component is stacked on another component disposed in contact with the main surface), in addition to meaning that the component is disposed in contact with the main surface of the substrate. The expression “the component is disposed on the main surface of the substrate” may mean that the component is disposed in a recess portion formed in the main surface. The fact that “the component is disposed in the substrate” means that the entire component is disposed between both main surfaces of the substrate, but a part of the component is not covered with the substrate, and only a part of the component is disposed in the substrate, in addition to meaning that the component is encapsulated in the module substrate.

In addition, in the following embodiments, a pass band of a filter is defined as a frequency band between two frequencies which are 3 dB higher than a minimum value of an insertion loss inside the pass band.

The acoustic wave resonance unit is defined as any of (1) a resonant circuit (a parallel connection circuit between an acoustic wave resonator and a circuit (or a circuit element)) configured with the acoustic wave resonator and the circuit (or the circuit element) connected in parallel to the acoustic wave resonator, (2) a resonant circuit (a series connection circuit between an acoustic wave resonator and a circuit (or a circuit element)) configured with the acoustic wave resonator and the circuit (or the circuit element) connected to only one of two input/output terminals of the acoustic wave resonator, and having a configuration in which other circuits (and other circuit elements) and the ground are not connected to a connection node that connects the acoustic wave resonator and the circuit (or the circuit element), (3) a resonant circuit (a parallel connection circuit of divided resonators) configured with a plurality of acoustic wave resonators connected in parallel to each other, and (4) a resonant circuit (a series connection circuit of divided resonators) configured with a plurality of acoustic wave resonators connected in series to each other, and having a configuration in which the circuit (and the circuit element) other than the plurality of acoustic wave resonators and the ground are not connected to a connection node that connects the plurality of acoustic wave resonators.

In addition, in the embodiments of the present disclosure, a resonance band width means a frequency difference between an anti-resonant frequency and a resonant frequency of the acoustic wave resonator.

A resonant frequency and an anti-resonant frequency illustrated in the above-described embodiment and the modification example are derived, for example, by bringing RF probes into contact with two input/output electrodes of the acoustic wave resonator or the acoustic wave resonance unit and measuring reflection characteristics (impedance characteristics) with a network analyzer or the like, in a state where the acoustic wave resonator or the acoustic wave resonance unit is not connected to other circuit elements.

In addition, in the present disclosure, the term “band” means at least one of an uplink operating band and a downlink operating band of a frequency band defined in advance by a standardization group or the like (for example, 3GPP (registered trademark) and the Institute of Electrical and Electronics Engineers (IEEE)) for a communication system constructed by using a Radio Access Technology (RAT). In the present embodiment, as the communication system, for example, a long term evolution (LTE) system, a 5th generation (5G)-new radio (NR) system, a wireless local area network (WLAN) system, and the like can be used, but the present disclosure is not limited thereto. An uplink operating band of a frequency band means a frequency range designated for uplink in the frequency band. In addition, a downlink operating band of a frequency band means a frequency range designated for downlink in the frequency band.

### Embodiment

### 1 Circuit Configuration of Acoustic Wave Filter 1 and High Frequency Module 100

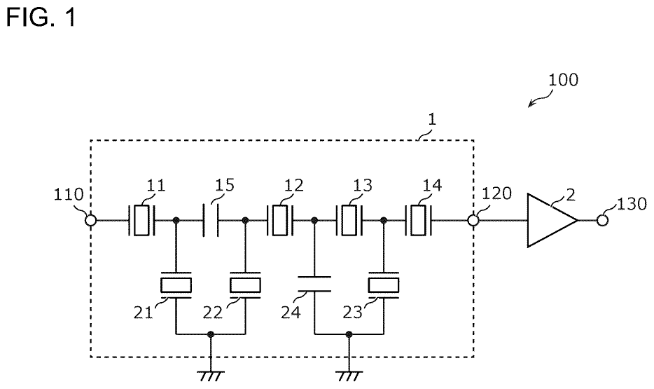

FIG. 1 is a circuit configuration diagram of an acoustic wave filter 1 and a high frequency module 100 according to the embodiment. As illustrated in the figure, the high frequency module 100 is provided with an acoustic wave filter 1, a low noise amplifier 2, and an output terminal 130.

The low noise amplifier 2 is connected between the acoustic wave filter 1 and the output terminal 130, specifically, the input terminal of the low noise amplifier 2 is connected to the input/output terminal 120 of the acoustic wave filter 1. The low noise amplifier 2 includes, for example, an amplification transistor which is a field effect transistor (FET) or a bipolar transistor, a gate (or a base) of the amplification transistor is connected to the input/output terminal 120, a drain (or a collector) is connected to the output terminal 130, and a source (or an emitter) is connected to ground. Furthermore, a direct current bias voltage (direct current bias current) is supplied to the gate (or a base) of the amplification transistor. With the above-described configuration, the low noise amplifier 2 amplifies the high frequency signal that passes through the acoustic wave filter 1 and outputs the amplified signal to the output terminal 130 by supplying the direct current bias voltage (direct current bias current) to the gate (or a base). In addition, the input impedance of the low noise amplifier 2 is capacitive and high impedance.

The acoustic wave filter 1 is a band pass type filter (band pass filter), and is provided with the series arm resonators 11, 12, 13, and 14, the parallel arm resonators 21, 22, and 23, the capacitors 15 and 24, and the input/output terminals 110 and 120.

Each of the series arm resonators 11 to 14 is an example of an acoustic wave resonance unit including an acoustic wave resonator, and is disposed in a series arm path connecting the input/output terminal 110 (second input/output terminal) and the input/output terminal 120 (twelfth input/output terminal). The series arm resonator 11 constitutes one series arm resonance unit (acoustic wave resonance unit) with only the series arm resonator 11, the series arm resonator 12 constitutes one series arm resonance unit (acoustic wave resonance unit) with only the series arm resonator 12, the series arm resonator 13 constitutes one series arm resonance unit (acoustic wave resonance unit) with only the series arm resonator 13, and the series arm resonator 14 constitutes one series arm resonance unit (acoustic wave resonance unit) with only the series arm resonator 14. The capacitor 15 is an example of a first capacitor and is arranged in series in the above series arm path.

Each of the series arm resonators 11 to 14 and the capacitor 15 is connected in the order of the series arm resonator 11, the capacitor 15, and the series arm resonators 12, 13, and 14 from the input/output terminal 110.

Each of the parallel arm resonators 21 to 23 is an example of an acoustic wave resonance unit including an acoustic wave resonator, and is connected between the above-described series arm path and the ground. The parallel arm resonator 21 is connected between a connection point of the series arm resonator 11 and the capacitor 15 and the ground. The parallel arm resonator 22 is connected between a connection point of the capacitor 15 and the series arm resonator 12 and the ground. The parallel arm resonator 21 constitutes one parallel arm resonance unit (acoustic wave resonance unit) with only the parallel arm resonator 21, the parallel arm resonator 22 constitutes one parallel arm resonance unit (acoustic wave resonance unit) with only the parallel arm resonator 22, and the parallel arm resonator 23 constitutes one parallel arm resonance unit (acoustic wave resonance unit) with only the parallel arm resonator 23. The capacitor 24 is an example of a second capacitor, and is arranged in series in a parallel arm path connecting the series arm path between the series arm resonators 12 and 13 and the ground. The parallel arm resonator 23 is connected between a connection point of the series arm resonators 13 and 14 and the ground.

Among the series arm resonators 11 to 14, the series arm resonator 14 is an example of a first series arm resonance unit, and has a resonant frequency frs14 (first resonant frequency) and an anti-resonant frequency fas14 (first anti-resonant frequency).

Among the parallel arm resonators 21 to 23, the parallel arm resonator 23 is an example of a first parallel arm resonance unit, and has a resonant frequency frp23 (second resonant frequency) and an anti-resonant frequency fap23 (second anti-resonant frequency).

Each of the series arm resonators 11 to 14 and the parallel arm resonators 21 to 23 (acoustic wave resonance units) has only one acoustic wave resonator, and each of the series arm resonators 11 to 14 and the parallel arm resonators 21 to 23 may be any of (1) a resonance unit configured with an acoustic wave resonator and a circuit including at least one of a capacitor and an inductor connected in parallel to the acoustic wave resonator, (2) a resonance unit configured with an acoustic wave resonator and a circuit including at least one of a capacitor and an inductor connected in series to the acoustic wave resonator, (3) a resonance unit configured with a plurality of acoustic wave resonators connected in parallel, and (4) a resonance unit configured with a plurality of acoustic wave resonators connected in series.

In addition, the acoustic wave filter 1 according to the present embodiment may be provided with one or more series arm resonance units including the series arm resonator 14, and one or more parallel arm resonance units including the parallel arm resonator 23, and does not need to be provided with other acoustic wave resonators and capacitors.

In addition, the acoustic wave filter 1 according to the present embodiment may be provided with the longitudinally coupled resonance unit in addition to the series arm resonance unit and the parallel arm resonance unit constituting a ladder filter.

### 2 Structure of Acoustic Wave Resonator

Next, a structure of the acoustic wave resonators (series arm resonators and parallel arm resonators) constituting the acoustic wave filter 1 will be exemplified.

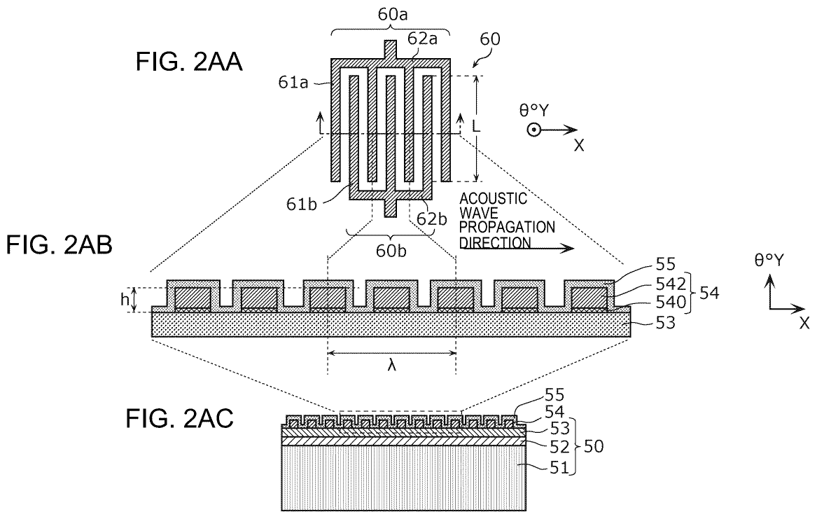

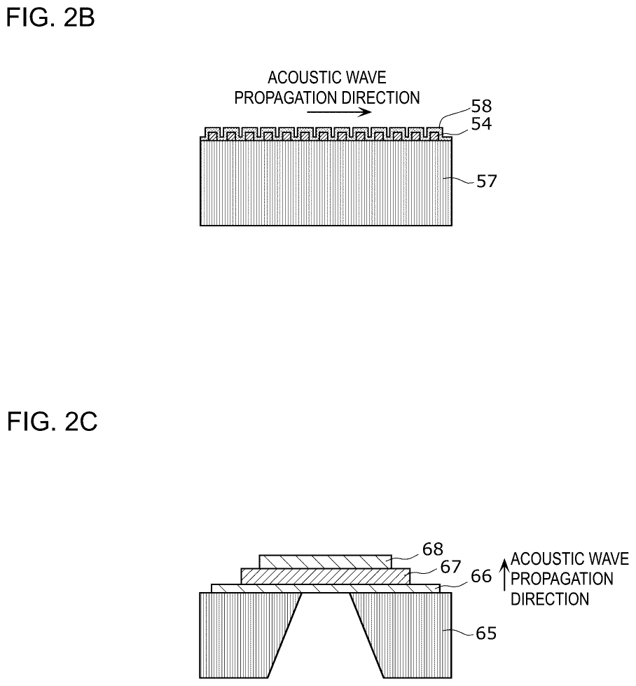

FIGS. 2AA-2AC include a plan view and a cross-sectional view schematically illustrating a first example of an acoustic wave resonator forming the acoustic wave filter 1 according to the embodiment. In the same drawing, a basic structure of each of the plurality of acoustic wave resonators forming the acoustic wave filter 1 is illustrated as an example. An acoustic wave resonator 60 illustrated in FIG. 2AA-2AC is an example for describing a typical structure of the surface acoustic wave resonator forming the acoustic wave filter 1, and the number and length of electrode fingers forming the electrode are not limited thereto.

The acoustic wave resonator 60 includes a piezoelectric substrate 50 and comb-shaped electrodes 60a and 60b.

As illustrated in FIG. 2AA, the pair of comb-shaped electrodes 60a and 60b facing each other are formed on the piezoelectric substrate 50. The comb-shaped electrode 60a includes a plurality of electrode fingers 61a parallel to each other and a busbar electrode 62a that connects the plurality of electrode fingers 61a to each other. The comb-shaped electrode 60b includes a plurality of electrode fingers 61b parallel to each other and a busbar electrode 62b that connects the plurality of electrode fingers 61b to each other. The plurality of electrode fingers 61a and 61b are formed along a direction orthogonal to the acoustic wave propagation direction (X-axis direction).

In addition, as illustrated in FIG. 2AB, an interdigital transducer (IDT) electrode 54 including the plurality of electrode fingers 61a and 61b and the busbar electrodes 62a and 62b has a multilayer structure of a close contact layer 540 and a main electrode layer 542.

The close contact layer 540 is a layer for improving close contact between the piezoelectric substrate 50 and the main electrode layer 542, and as a material thereof, for example, Ti is used. As a material of the main electrode layer 542, for example, Al containing 1% Cu is used. A protective layer 55 is formed to cover the comb-shaped electrodes 60a and 60b. The protective layer 55 is a layer for protecting the main electrode layer 542 from an outside environment, for adjusting frequency-temperature characteristics, and for improving humidity resistance, and for example, is a dielectric film containing silicon dioxide as the main component.

Materials forming the close contact layer 540, the main electrode layer 542, and the protective layer 55 are not limited to the above-described materials. Furthermore, the IDT electrode 54 does not need to have the above-described multilayer structure. The IDT electrode 54 may be formed of, for example, a metal or an alloy, such as Ti, Al, Cu, Pt, Au, Ag, or Pd, and may include a plurality of multilayer bodies formed of the above-described metal or alloy. In addition, the protective layer 55 does not need to be formed.

Next, the multilayer structure of the piezoelectric substrate 50 will be described.

As illustrated in FIG. 2AC, the piezoelectric substrate 50 is provided with a high acoustic velocity support substrate 51, a low acoustic velocity film 52, and a piezoelectric film 53, and has a structure in which the high acoustic velocity support substrate 51, the low acoustic velocity film 52, and the piezoelectric film 53 are stacked in this order.

For example, the piezoelectric film 53 is formed of a 0° Y-cut X propagation LiTaO₃ piezoelectric single crystal or a piezoelectric ceramic (a single crystal or a ceramic through which the surface acoustic wave propagates in an X-axis direction, which is lithium tantalate single crystal or a ceramic cut along a plane in which the X-axis is set as a central axis, and an axis rotated by θ° from the Y-axis is set as a normal line). A material and a cut-angle θ of the piezoelectric single crystal used as the piezoelectric film 53 are appropriately selected depending on the required specifications of each filter.

The high acoustic velocity support substrate 51 supports the low acoustic velocity film 52, the piezoelectric film 53, and the IDT electrode 54. Furthermore, the high acoustic velocity support substrate 51 is a substrate in which the acoustic velocity of a bulk wave in the high acoustic velocity support substrate 51 is higher than the acoustic velocity of the acoustic wave of a surface acoustic wave or a boundary acoustic wave propagating through the piezoelectric film 53, and functions to prevent the surface acoustic wave from leaking down from the high acoustic velocity support substrate 51 by confining the surface acoustic wave in a portion at which the piezoelectric film 53 and the low acoustic velocity film 52 are stacked. As a material of the high acoustic velocity support substrate 51, for example, a piezoelectric body, such as aluminum nitride, lithium tantalate, lithium niobate, or crystal, a ceramic, such as alumina, sapphire, magnesia, silicon nitride, silicon carbide, zirconia, cordierite, mullite, steatite, forsterite, spinel, or sialon, a dielectric, such as aluminum oxide, silicon oxynitride, diamond-like carbon (DLC), and diamond, or a semiconductor, such as silicon, or a material containing the above-described materials as the main components can be used. The above-described spinel includes an aluminum compound containing one or more elements selected from Mg, Fe, Zn, and Mn, oxygen, and the like. Examples of the above-described spinel can include MgAl₂O₄, FeAl₂O₄, ZnAl₂O₄, and MnAl₂O₄.

The low acoustic velocity film 52 is a film in which the acoustic velocity of the bulk wave in the low acoustic velocity film 52 is lower than that of the bulk wave propagating through the piezoelectric film 53, and is disposed between the piezoelectric film 53 and the high acoustic velocity support substrate 51. This structure and the property that the energy of an acoustic wave essentially concentrates on a medium having a low acoustic velocity reduce leakage of surface acoustic wave energy to the outside of the piezoelectric film 53. As a material of the low acoustic velocity film 52, for example, a dielectric material, such as glass, silicon oxide, silicon oxynitride, lithium oxide, tantalum oxide, or a compound of silicon oxide with fluorine, carbon, or boron added, or a material containing the above materials as a main component can be used.

According to the above-described multilayer structure of the piezoelectric substrate 50, a Q value in a resonant frequency and an anti-resonant frequency can be significantly increased, compared to a structure in the related art in which the piezoelectric substrate is used as a single layer. That is, since an acoustic wave resonator having a high Q value can be configured, a filter having a small insertion loss can be configured by using the acoustic wave resonator.

The high acoustic velocity support substrate 51 may have a structure in which a support substrate and a high acoustic velocity film where the acoustic velocity of the bulk wave propagating through the piezoelectric film 53 is higher than that of the acoustic wave such as the surface acoustic wave or the boundary acoustic wave propagating through the piezoelectric film 53 are stacked. In this case, as a material of the high acoustic velocity film, the same material as the material of the high acoustic velocity support substrate 51 can be used. As a material of the support substrate, for example, a piezoelectric body, such as aluminum nitride, lithium tantalate, lithium niobate, or crystal, ceramic, such as alumina, sapphire, magnesia, silicon nitride, silicon carbide, zirconia, cordierite, mullite, steatite, or forsterite, a dielectric, such as diamond or glass, a semiconductor, such as silicon or gallium nitride, or a resin, or a material containing the above-described material as the main components can be used.

In the present specification, the term “main component of the material” refers to a component in which an occupancy in the material exceeds 50% by weight. The above-described main component may exist in any one state of single crystal, polycrystal, and amorphous, or in a mixed state thereof.

FIG. 2B is a cross-sectional view schematically illustrating a second example of an acoustic wave resonator forming the acoustic wave filter 1 according to the embodiment. In the acoustic wave resonator 60 illustrated in FIGS. 2AA-2AC, an example in which the IDT electrode 54 is formed on the piezoelectric substrate 50 having the piezoelectric film 53 has been described. However, as illustrated in FIG. 2B, the substrate on which the IDT electrode 54 is formed may be a piezoelectric single crystal substrate 57 formed of a single layer of the piezoelectric layer.

For example, the piezoelectric single crystal substrate 57 includes a piezoelectric single crystal of LiNbO₃. The acoustic wave resonator according to this example includes the piezoelectric single crystal substrate 57 of LiNbO₃, the IDT electrode 54, and a protective layer 58 formed on the piezoelectric single crystal substrate 57 and on the IDT electrode 54.

The multilayer structure, the material, the cut-angle, and the thickness of the piezoelectric film 53 and the piezoelectric single crystal substrate 57 described above may be appropriately changed depending on the required bandpass characteristics and the like of the acoustic wave filter device. An acoustic wave resonator using a LiTaO₃ piezoelectric substrate or the like having another cut-angle other than the above-described cut-angle can achieve the same effect as that of the acoustic wave resonator 60 using the piezoelectric film 53 described above.

In addition, the substrate on which the IDT electrode 54 is formed may have a structure in which a support substrate, an energy confinement layer, and a piezoelectric film are stacked in this order. The IDT electrode 54 is formed on the piezoelectric film. As the piezoelectric film, for example, a LiTaO₃ piezoelectric single crystal or a piezoelectric ceramic is used. The support substrate supports the piezoelectric film, the energy confinement layer, and the IDT electrode 54.

The energy confinement layer includes one layer or a plurality of layers, and the velocity of a bulk acoustic wave propagating through at least one layer is higher than the velocity of an acoustic wave propagating in the vicinity of the piezoelectric film. For example, the energy confinement layer may have a multilayer structure including a low acoustic velocity layer and a high acoustic velocity layer. The low acoustic velocity layer is a film in which the acoustic velocity of a bulk wave in the low acoustic velocity layer is lower than the acoustic velocity of an acoustic wave propagating through the piezoelectric film. The high acoustic velocity layer is a film in which the acoustic velocity of a bulk wave in the high acoustic velocity layer is higher than the acoustic velocity of an acoustic wave propagating through the piezoelectric film. The support substrate may be used as the high acoustic velocity layer.

In addition, the energy confinement layer may be an acoustic impedance layer having a configuration in which a low acoustic impedance layer having a relatively low acoustic impedance and a high acoustic impedance layer having a relatively high acoustic impedance are alternately stacked.

Here, electrode parameters of the IDT electrode 54 forming the acoustic wave resonator 60 will be described.

A wavelength of the acoustic wave resonator is defined by a wavelength λ that is a repeating period in the plurality of electrode fingers 61a or 61b forming the IDT electrode 54 illustrated in FIG. 2AB. In addition, an electrode finger pitch is ½ of the wavelength λ, and when a line width of the electrode fingers 61a and 61b forming the comb-shaped electrodes 60a and 60b, respectively, is represented by W, and a space width between the electrode finger 61a and the electrode finger 61b adjacent to each other is represented by S, the electrode finger pitch is defined as (W+S). In addition, the duty of the IDT electrode 54 is a line width occupancy of the electrode fingers 61a and 61b, is a ratio of the line width to a value obtained by adding the line width and the space width of each of the electrode fingers 61a and 61b, and is defined by W/(W+S). In addition, an intersecting width of the IDT electrode 54 is an overlapping length of the electrode fingers when the electrode finger 61a and the electrode finger 61b are viewed from the acoustic wave propagation direction (X-axis direction).

In the IDT electrode 54, in a case where a spacing between the electrode fingers adjacent to each other is not constant, the electrode finger pitch of the IDT electrode 54 is defined as an average electrode finger pitch of the IDT electrode 54. The average electrode finger pitch of the IDT electrode 54 is defined as Di/(Ni-1), when the total number of the electrode fingers 61a and 61b in the IDT electrode 54 is represented by Ni, and when a distance between centers of the electrode finger located in one end and the electrode finger located in another end of the IDT electrode 54 in the acoustic wave propagation direction is represented by Di.

FIG. 2C is a cross-sectional view schematically illustrating a third example of an acoustic wave resonator forming the acoustic wave filter 1 according to the embodiment. FIG. 2C illustrates a bulk acoustic wave resonator as the acoustic wave resonator of the acoustic wave filter 1. As illustrated in the figure, for example, the bulk acoustic wave resonator includes a support substrate 65, a lower electrode 66, a piezoelectric layer 67, and an upper electrode 68, and is configured so that the support substrate 65, the lower electrode 66, the piezoelectric layer 67, and the upper electrode 68 are stacked in this order.

The support substrate 65 supports the lower electrode 66, the piezoelectric layer 67, and the upper electrode 68, and is a silicon substrate, for example. In the support substrate 65, a cavity is provided in a region that comes into contact with the lower electrode 66. As a result, the piezoelectric layer 67 can freely vibrate.

The lower electrode 66 is formed on one surface of the support substrate 65. The upper electrode 68 is formed on one surface of the support substrate 65. As materials of the lower electrode 66 and the upper electrode 68, for example, Al containing Cu by 1% is used.

The piezoelectric layer 67 is formed between the lower electrode 66 and the upper electrode 68. For example, the piezoelectric layer 67 includes at least one of zinc oxide (ZnO), aluminum nitride (AlN), lead zirconate titanate (PZT), potassium niobate (KN), lithium niobate (LN), lithium tantalate (LT), crystal, and lithium borate (LiBO) as the main component.

The bulk acoustic wave resonator having the above-described multilayer configuration induces a bulk acoustic wave inside the piezoelectric layer 67, and generates resonance by applying electric energy between the lower electrode 66 and the upper electrode 68. The bulk acoustic wave generated by the bulk acoustic wave resonator propagates between the lower electrode 66 and the upper electrode 68 in a direction perpendicular to a film surface of the piezoelectric layer 67. That is, the bulk acoustic wave resonator is a resonator using the bulk acoustic wave.

### 3 Resonance Characteristics and Bandpass Characteristics of Acoustic Wave Filter 1

First, a basic operating principle of the ladder band pass filter including one series arm resonator and one parallel arm resonator will be described.

The parallel arm resonator has a resonant frequency frp and an anti-resonant frequency fap (>frp), and the series arm resonator has a resonant frequency frs and an anti-resonant frequency fas (>frs>frp). In the series arm resonator and the parallel arm resonator having the above-described resonance characteristics, in general, the anti-resonant frequency fap of the parallel arm resonator and the resonant frequency frs of the series arm resonator are close to each other. As a result, the vicinity of the resonant frequency frp where the impedance of the parallel arm resonator approaches 0 is a lower frequency side stop band. In addition, as the frequency increases from the lower frequency side stop band, the impedance of the parallel arm resonator in the vicinity of the anti-resonant frequency fap increases, and the impedance of the series arm resonator in the vicinity of the resonant frequency frs approaches 0. As a result, the vicinity of the anti-resonant frequency fap to the resonant frequency frs is a signal pass band in a signal path that is the series arm path. As a result, the pass band on which electrode parameters and an electromechanical coupling coefficient of the acoustic wave resonator are reflected can be formed. Furthermore, when the frequency increases to be in the vicinity of the anti-resonant frequency fas, the impedance of the series arm resonator increases, and a higher frequency side stop band is provided.

In each of the series arm resonator and the parallel arm resonator, the impedance of the resonator is capacitive (C-characteristic) in a frequency band located on a lower frequency side with respect to the resonant frequency, and the impedance of the resonator is inductive (L-characteristic) in a frequency band located on a higher frequency side with respect to the resonant frequency and located on a lower frequency side with respect to the anti-resonant frequency. In addition, the impedance of the resonator is capacitive in a frequency band on a higher frequency side with respect to the anti-resonant frequency.

In a case where the resonance band width is wider than the desired pass band width, the anti-resonant frequency of the parallel arm resonator may be higher than the high end of the pass band, and the resonant frequency of the series arm resonator may be lower than the low end of the pass band. A resonator in which at least a part of a resonance band, which is a frequency range from the resonant frequency to the anti-resonant frequency, overlaps with the pass band of the acoustic wave filter 1 is defined as a resonator that contributes to the formation of the pass band of the acoustic wave filter 1.

Next, impedance characteristics and bandpass characteristics of the acoustic wave filter 1 will be described.

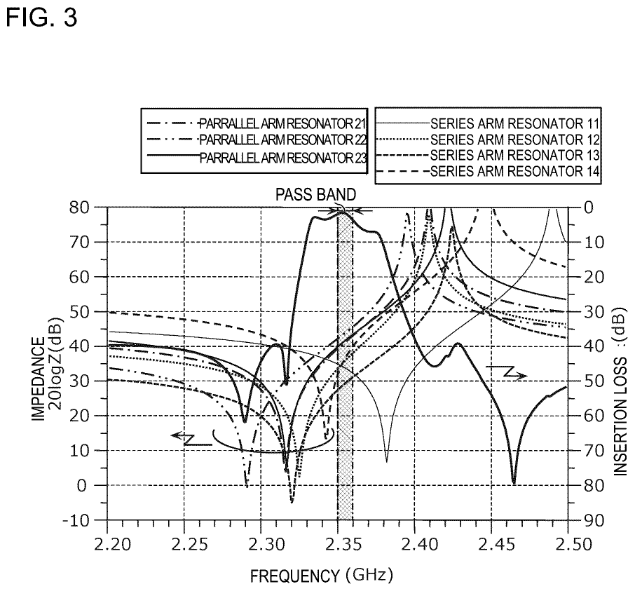

FIG. 3 is a graph illustrating the bandpass characteristics of the acoustic wave filter 1 and the impedance characteristics of each acoustic wave resonance unit according to the embodiment. As illustrated in the figure, the pass band width (10 MHZ) of the acoustic wave filter 1 is a narrow band compared to the resonance band width (80 to 100 MHZ) of each acoustic wave resonator. The acoustic wave filter 1 has a pass band including, for example, a downlink operating band (2350 to 2360 MHZ) of band B30 for LTE or band n30 for 5G-NR.

The pass band (2350 to 2360 MHZ) of the acoustic wave filter 1 according to the present embodiment is located between the resonant frequency and the anti-resonant frequency of each of the series arm resonators 12 to 14, and is located between the resonant frequency and the anti-resonant frequency of each of the parallel arm resonators 21 to 23.

That is, since at least a part of the resonance band overlaps with the pass band of the acoustic wave filter 1, the series arm resonators 12 to 14 and the parallel arm resonators 21 to 23 are resonators that contribute to the formation of the pass band of the acoustic wave filter 1.

On the other hand, since both the resonant frequency and the anti-resonant frequency of the series arm resonator 11 are higher than the high end of the pass band, the series arm resonator 11 is a resonator that does not contribute to the formation of the pass band of the acoustic wave filter 1.

Instead of the capacitors 15 and 24, the acoustic wave resonance units may be disposed. The resonance band widths of the series arm resonators 12 to 14 and the parallel arm resonators 21 to 23 are wider than the desired pass band of the acoustic wave filter 1. On the other hand, in the acoustic wave filter 1 according to the present embodiment, the capacitors 15 and 24 are disposed, so that a narrow pass band is easily formed by using the acoustic wave resonator having a wide resonance band width.

In addition, since the resonance band widths (80 to 100 MHz) of each of the acoustic wave resonators are aligned, all the acoustic wave resonators constituting the acoustic wave filter 1 can be formed on one piezoelectric substrate. Accordingly, the acoustic wave filter 1 can be reduced in size.

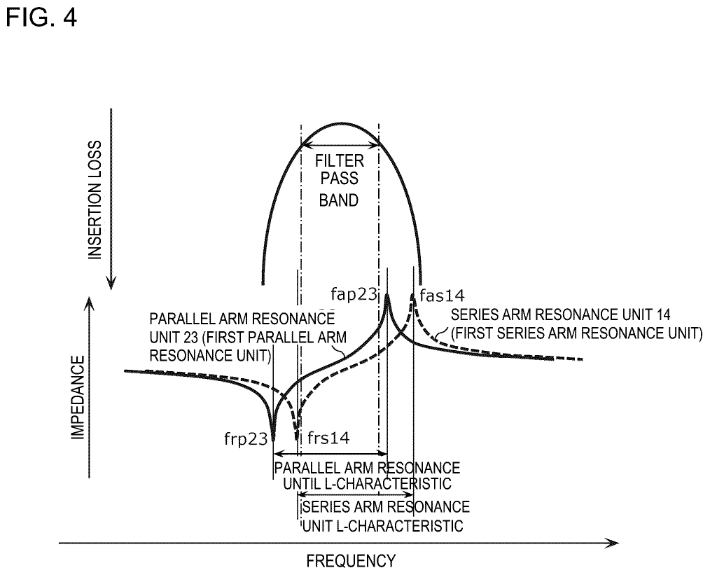

FIG. 4 is a diagram schematically illustrating the bandpass characteristics of the acoustic wave filter 1 according to the embodiment and the impedance characteristics of the series arm resonator 14 (first series arm resonance unit) and the parallel arm resonator 23 (first parallel arm resonance unit).

As illustrated in the figure, the resonant frequency frs14 (first resonant frequency) of the series arm resonator 14 (first series arm resonance unit) and the resonant frequency frp23 (second resonant frequency) of the parallel arm resonator 23 (first parallel arm resonance unit) are equal to or lower than the low frequency end of the pass band of the acoustic wave filter 1. In addition, the anti-resonant frequency fas14 (first anti-resonant frequency) of the series arm resonator 14 (first series arm resonance unit) and the anti-resonant frequency fap23 (second anti-resonant frequency) of the parallel arm resonator 23 (first parallel arm resonance unit) are equal to or higher than the high frequency end of the pass band.

That is, the resonance band of the series arm resonator 14 includes the pass band of the acoustic wave filter 1, and the impedance of the series arm resonator 14 is inductive over the pass band. In addition, the resonance band of the parallel arm resonator 23 includes the pass band of the acoustic wave filter 1, and the impedance of the parallel arm resonator 23 is inductive over the pass band.

Furthermore, the resonant frequency frs14 is higher than the resonant frequency frp23, and the anti-resonant frequency fas14 is higher than the anti-resonant frequency fap23.

That is, the resonant frequency frs14 is closer to the pass band among the resonant frequencies frs14 and frp23 at which the impedance is minimal, and the anti-resonant frequency fas14 is farther from the pass band among the anti-resonant frequencies fas14 and fap23 at which the impedance is maximal. As a result, a low impedance band of the inductive impedance band of the series arm resonator 14 overlaps with the pass band, and a high impedance band of the inductive impedance band of the parallel arm resonator 23 overlaps with the pass band.

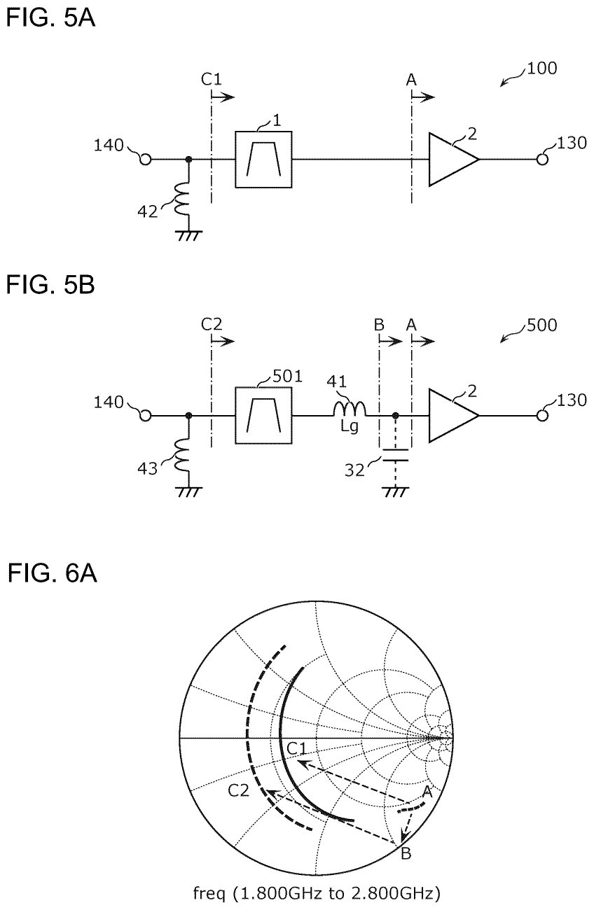

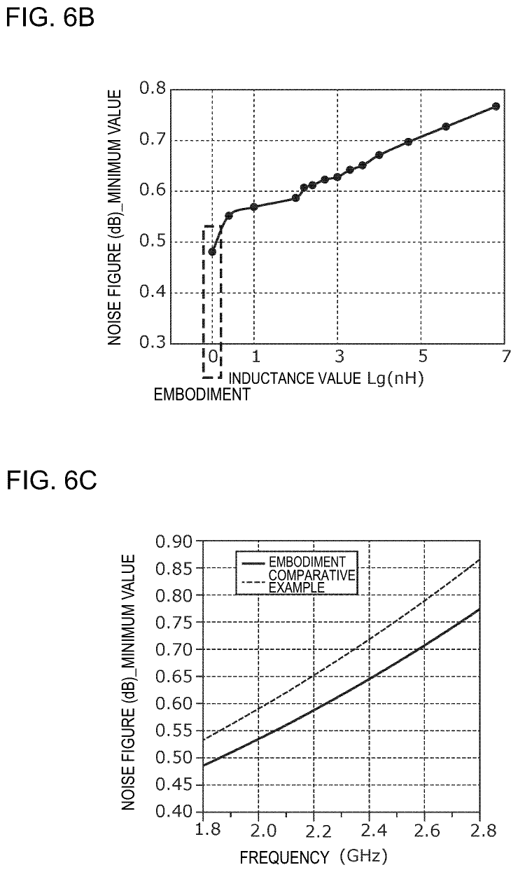

FIG. 5A is a circuit configuration diagram of the high frequency module 100 according to the embodiment. FIG. 5B is a circuit configuration diagram of the high frequency module 500 according to a comparative example. FIG. 6A is a Smith chart illustrating the impedance of a band (1800 to 2800 MHZ) including a pass band of the high frequency module according to the embodiment and the comparative example.

As illustrated in FIG. 5A, in the high frequency module 100 according to the present embodiment, an inductor 42 for impedance matching with an input terminal 140 and an external circuit connected to the input terminal 140 may be added.

On the other hand, the high frequency module 500 according to the comparative example is provided with an acoustic wave filter 501, the low noise amplifier 2, inductors 41 and 43, the input terminal 140, and the output terminal 130. The acoustic wave filter 501 has the same circuit configuration as that of the acoustic wave filter 1, and includes four series arm resonators, three parallel arm resonators, and two capacitors. However, the resonant frequency of each of the four series arm resonators is located within the pass band of the acoustic wave filter 501, and the anti-resonant frequency of each of the three parallel arm resonators is located within the pass band of the acoustic wave filter 501. Due to this fact and the structure of the acoustic wave resonator (the IDT electrode structure or the piezoelectric film multilayer structure), the impedance in the pass band of the acoustic wave filter 501 tends to be capacitive. As a result, the inductor 41 having an inductive impedance is disposed between the low noise amplifier 2 having a capacitive input impedance and the acoustic wave filter 501, so that it is possible to match both at the reference impedance. However, in a case where the inductor 41 is disposed between the low noise amplifier 2 and the acoustic wave filter 501, the parasitic capacitance 32 caused by the wiring of the inductor 41 is generated in the vicinity of the input terminal of the low noise amplifier 2.

As illustrated in FIG. 6A, the impedance of the pass band when the low noise amplifier 2 is viewed from the node A is the capacitive impedance (A).

On the other hand, in the high frequency module 500 according to the comparative example, by adding the parasitic capacitance 32 in parallel, the impedance in the band (1800 to 2800 MHZ) viewed the low noise amplifier 2 from the node B moves clockwise on the equal conductance circle as illustrated in FIG. 6A to be a higher capacitive impedance (B). In addition, the impedance in the band (1800 to 2800 MHZ) viewed the acoustic wave filter 501, the inductor 41, and the low noise amplifier 2 from the node C2 moves clockwise on the equal resistance circle (hereinafter, referred to as an equal resistance circle RB) with respect to the impedance (B) as illustrated in FIG. 6A to be impedance (C2).

On the other hand, in the high frequency module 100 according to the present embodiment, since the inductor 41 for impedance matching is not added, the impedance in the band (1800 to 2800 MHZ) viewed the acoustic wave filter 1 and the low noise amplifier 2 from the node C1 moves clockwise on the equal resistance circle having a resistance higher than the equal resistance circle RB with respect to the impedance (A) as illustrated in FIG. 6A to be the impedance (C1).

As a result, as illustrated in FIG. 6A, in the high frequency module 500 according to the comparative example, the impedance of the pass band of the acoustic wave filter 501 as viewed from the input side is lower than that of the high frequency module 100 according to the embodiment due to the parasitic capacitance 32 generated by the addition of the inductor 41, and deviates from the reference impedance.

That is, in the present embodiment, since it is possible to set the impedance in the pass band of the acoustic wave filter 1 to be inductive, the impedance of the high frequency module 100 can be made to approach the reference impedance without necessarily adding the inductor 41. Therefore, the matching loss of the acoustic wave filter 1 and the high frequency module 100 can be reduced, and the high frequency module 100 can be reduced in size.

Furthermore, as described above, the resonant frequency frs14 is higher than the resonant frequency frp23, and the anti-resonant frequency fas14 is higher than the anti-resonant frequency fap23. As a result, a low impedance band of the inductive impedance band of the series arm resonator 14 overlaps with the pass band, and a high impedance band of the inductive impedance band of the parallel arm resonator 23 overlaps with the pass band. Accordingly, the insertion loss of the acoustic wave filter 1 can be reduced.

Therefore, it is possible to provide the acoustic wave filter 1 and the high frequency module 100 in which the low loss characteristics are ensured from both the viewpoints of the matching loss and the insertion loss.

In the acoustic wave filter 1 according to the present embodiment, the first series arm resonance unit (series arm resonator 14) is connected closest to the input/output terminal 120 among the plurality of series arm resonance units, and the first parallel arm resonance unit (parallel arm resonator 23) is connected closest to the input/output terminal 120 among the plurality of parallel arm resonance units.

Accordingly, since the resonance unit that exhibits the inductive impedance in the pass band is disposed closest to the input terminal of the low noise amplifier 2 that exhibits the capacitive impedance, impedance matching between the acoustic wave filter 1 and the low noise amplifier 2 can be performed with high efficiency and high accuracy.

The first series arm resonance unit does not need to be the series arm resonator 14 and may be any of the series arm resonators 11 to 13. In addition, the first parallel arm resonance unit does not need to be the parallel arm resonator 23 and may be the parallel arm resonator 21 or 22. That is, the first series arm resonance unit does not need to be connected closest to the input/output terminal 120 among the plurality of series arm resonance units, and the first parallel arm resonance unit does not need to be connected closest to the input/output terminal 120 among the plurality of parallel arm resonance units. Even in this case, since it is possible to set the impedance in the pass band of the acoustic wave filter 1 to be inductive, the matching loss of the acoustic wave filter 1 and the high frequency module 100 can be reduced, and the size of the high frequency module 100 can be reduced in size.

In addition, the acoustic wave filter 1 according to the present embodiment may be provided with at least one first series arm resonance unit and one first parallel arm resonance unit. That is, in the acoustic wave filter 1 according to the present embodiment, the resonance band of each of the series arm resonators 11 to 13 and the parallel arm resonators 21 and 22 does not need to include the pass band.

In addition, among the plurality of acoustic wave resonance units in the acoustic wave filter according to the present disclosure, it is desirable that the number of acoustic wave resonance units in which the resonant frequency is equal to or lower than the low frequency end of the pass band and the anti-resonant frequency is equal to or higher than the high frequency end of the pass band is larger than the number of acoustic wave resonance units in which the resonant frequency is higher than the low frequency end of the pass band or the anti-resonant frequency is lower than the high frequency end of the pass band.

Accordingly, since the number of acoustic wave resonance units in which the impedance of the pass band is inductive is larger than the number of acoustic wave resonance units in which the impedance of the pass band is capacitive, the impedance of the pass band of the entire acoustic wave filter 1 is inductive. Therefore, impedance matching between the low noise amplifier 2 having a capacitive input impedance and the acoustic wave filter 1 can be achieved with higher accuracy. Therefore, it is possible to provide the acoustic wave filter 1 and the high frequency module 100 in which the matching loss is further reduced.

FIG. 6B is a graph illustrating a relationship between an inductance value Lg of the inductor 41 and a noise figure of the high frequency module 500 according to the comparative example. As illustrated in the figure, as the inductance value Lg decreases, the resistance component of the inductor 41 decreases, and thus the noise figure of the low noise amplifier 2 is reduced. In addition, in a case where the inductor 41 is not added (the inductance value Lg is 0) as in the high frequency module 100 according to the present embodiment, since the parasitic capacitance 32 generated due to the mounting electrode of the inductor 41 and the wiring from the mounting electrode to the low noise amplifier 2 is reduced, the noise figure of the low noise amplifier 2 is significantly reduced.

FIG. 6C is a graph illustrating frequency characteristics of the noise figures of the low noise amplifier 2 according to the embodiment and the comparative example. The noise figure over a band (1800 to 2800 MHZ) including a pass band in the low noise amplifier 2 according to the embodiment is lower than that of the low noise amplifier 2 according to the comparative example. Therefore, according to the high frequency module 100 according to the present embodiment, the noise figure of the low noise amplifier 2 can be reduced.

### 4 Configuration of Acoustic Wave Filter 1A According to Modification Example 1

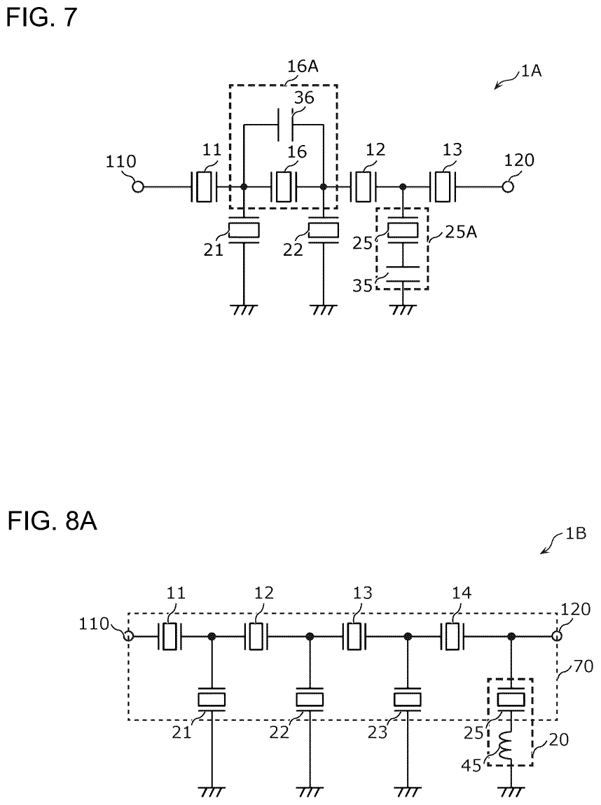

FIG. 7 is a circuit configuration diagram of an acoustic wave filter 1A according to Modification Example 1 of the embodiment. As illustrated in the figure, the acoustic wave filter 1A according to Modification Example 1 is a band pass type filter (band pass filter), and is provided with the series arm resonators 11, 12, 13, and 16, the parallel arm resonators 21, 22, and 25, the capacitors 35 and 36, and the input/output terminals 110 and 120. The acoustic wave filter 1A according to the present modification example is different from the acoustic wave filter 1 according to the embodiment in that the series arm resonator 14, the parallel arm resonator 23, the capacitors 15 and 24 are not disposed, and the series arm resonator 16, the parallel arm resonator 25, and the capacitors 35 and 36 are disposed as the circuit configuration. Hereinafter, the acoustic wave filter 1A according to the present modification example will be described with a focus on different configurations from those of the acoustic wave filter 1 according to the embodiment, and the same configurations will be omitted.

The series arm resonator 16 and the capacitor 36 connected in parallel to each other are examples of an acoustic wave resonance unit including an acoustic wave resonator, and constitute a series arm resonance unit 16A. The series arm resonance unit 16A is disposed in a series arm path connecting the input/output terminal 110 (second input/output terminal) and the input/output terminal 120 (twelfth input/output terminal). The capacitor 36 is connected in parallel to the series arm resonator 16, so that the resonance band width of the series arm resonance unit 16A is narrower than the resonance band width of the series arm resonator 16.

Each of the series arm resonators 11 to 13 and the series arm resonance unit 16A is connected to the series arm resonator 11, the series arm resonance unit 16A, and the series arm resonators 12 and 13 in order from the input/output terminal 110.

The parallel arm resonator 25 and the capacitor 35 connected in series with each other are examples of an acoustic wave resonance unit including an acoustic wave resonator, and constitute a parallel arm resonance unit 25A. The parallel arm resonance unit 25A is connected between a connection point of the series arm resonators 12 and 13 and the ground. The capacitor 35 is connected in series to the parallel arm resonator 25, so that the resonance band width of the parallel arm resonance unit 25A is narrower than the resonance band width of the parallel arm resonator 25.

The series arm resonator 13 is an example of a first series arm resonance unit, and has a resonant frequency frs13 (first resonant frequency) and an anti-resonant frequency fas13 (first anti-resonant frequency).

The parallel arm resonance unit 25A is an example of a first parallel arm resonance unit, and has a resonant frequency frp25A (second resonant frequency) and an anti-resonant frequency fap25A (second anti-resonant frequency).

The resonant frequency frs13 (first resonant frequency) of the series arm resonator 13 (first series arm resonance unit) and the resonant frequency frp25A (second resonant frequency) of the parallel arm resonance unit 25A (first parallel arm resonance unit) are equal to or lower than the low frequency end of the pass band of the acoustic wave filter 1A. In addition, the anti-resonant frequency fas13 (first anti-resonant frequency) of the series arm resonator 13 (first series arm resonance unit) and the anti-resonant frequency fap25A (second anti-resonant frequency) of the parallel arm resonance unit 25A (first parallel arm resonance unit) are equal to or higher than the high frequency end of the above-described pass band.

Furthermore, the resonant frequency frs13 is higher than the resonant frequency frp25A, and the anti-resonant frequency fas13 is higher than the anti-resonant frequency fap25A.

Accordingly, by setting the impedance in the pass band of the acoustic wave filter 1A according to the present modification example to be inductive, the impedance of the high frequency module according to the present modification example, which includes the acoustic wave filter 1A and the low noise amplifier 2, can be brought close to the reference impedance without necessarily adding a matching inductor. Therefore, the matching loss of the acoustic wave filter 1A and the high frequency module according to the present modification example can be reduced, and the high frequency module can be reduced in size.

Furthermore, a low impedance band of the inductive impedance band of the series arm resonator 13 overlaps with the pass band, and a high impedance band of the inductive impedance band of the parallel arm resonance unit 25A overlaps with the pass band. Accordingly, the insertion loss of the acoustic wave filter 1A can be reduced.

Therefore, it is possible to provide the acoustic wave filter 1A and the high frequency module in which the low loss characteristics are ensured from both the viewpoints of the matching loss and the insertion loss.

In the present modification example, the first series arm resonance unit is not limited to the series arm resonator 13, and may be any of the series arm resonators 11 and 12 and the series arm resonance unit 16A. In addition, the first parallel arm resonance unit is not limited to the parallel arm resonance unit 25A, and may be any of the parallel arm resonators 21 and 22.

In the acoustic wave filter 1A according to the present modification example, the first series arm resonance unit (series arm resonator 13) is connected closest to the input/output terminal 120 among the plurality of series arm resonance units, and the first parallel arm resonance unit (parallel arm resonance unit 25A) is connected closest to the input/output terminal 120 among the plurality of parallel arm resonance units.

Accordingly, since the resonance unit that exhibits the inductive impedance in the pass band is disposed closest to the input terminal of the low noise amplifier 2 that exhibits the capacitive impedance, the impedance matching between the acoustic wave filter 1A and the low noise amplifier 2 can be performed with high efficiency and high accuracy.

The first series arm resonance unit (series arm resonator 13) does not need to be connected closest to the input/output terminal 120 among the plurality of series arm resonance units, and the first parallel arm resonance unit (parallel arm resonance unit 25A) does not need to be connected closest to the input/output terminal 120 among the plurality of parallel arm resonance units. Even in this case, since it is possible to set the impedance in the pass band of the acoustic wave filter 1A to be inductive, the matching loss of the acoustic wave filter 1A and the high frequency module can be reduced.

In addition, since the resonance band width of the parallel arm resonance unit 25A is narrower than the resonance band width of the parallel arm resonator 25 and the resonance band width of the series arm resonance unit 16A is narrower than the resonance band width of the series arm resonator 16, a large amount of attenuation can be ensured in the vicinity of the pass band.

### 5 Configuration of Acoustic Wave Filter 1B According to Modification Example 2

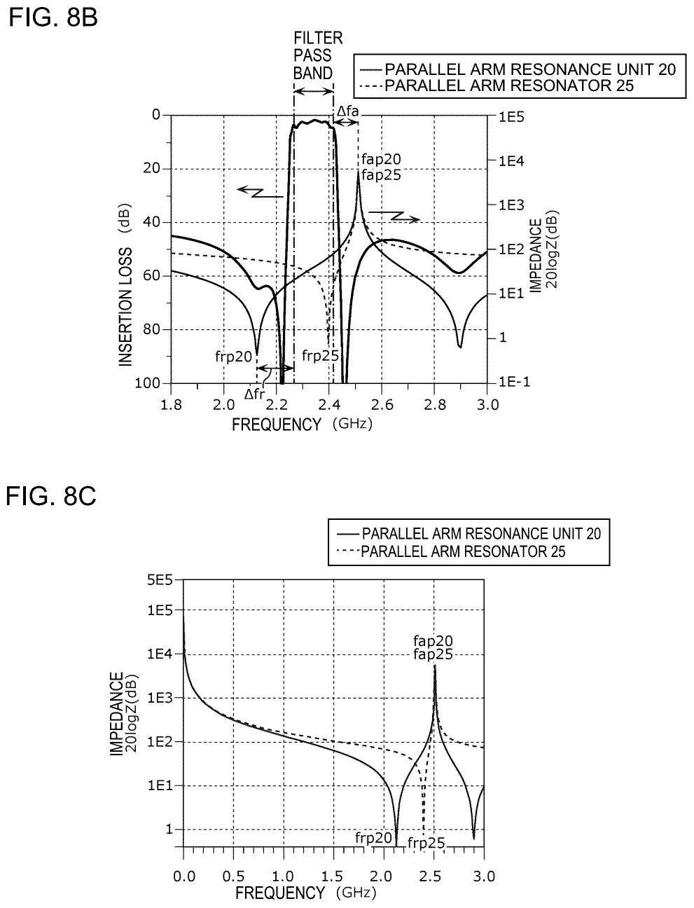

FIG. 8A is a circuit configuration diagram of an acoustic wave filter 1B according to Modification Example 2 of the embodiment. FIG. 8B is a graph illustrating bandpass characteristics of the acoustic wave filter 1B according to Modification Example 2 in a band near a pass band and impedance characteristics of the parallel arm resonance unit 20. FIG. 8C is a graph illustrating impedance characteristics of a wide-band parallel arm resonance unit 20 of the acoustic wave filter 1B according to Modification Example 2.

As illustrated in FIG. 8A, an acoustic wave filter 1B according to Modification Example 2 is a band pass type filter (band pass filter), and is provided with the series arm resonators 11, 12, 13, and 14, the parallel arm resonators 21, 22, 23, and 25, an inductor 45, and the input/output terminals 110 and 120. The acoustic wave filter 1B according to the present modification example is different from the acoustic wave filter 1 according to the embodiment in that the capacitors 15 and 24 are not disposed and the parallel arm resonators 25 and the inductor 45 are disposed as the circuit configuration. Hereinafter, the acoustic wave filter 1B according to the present modification example will be described with a focus on different configurations from those of the acoustic wave filter 1 according to the embodiment, and the same configurations will be omitted.

Each of the series arm resonators 11 to 14 is connected to the series arm resonators 11, 12, 13, and 14 in order from the input/output terminal 110.

The parallel arm resonator 21 is connected between a connection point of the series arm resonators 11 and 12 and the ground. The parallel arm resonator 22 is connected between a connection point of the series arm resonators 12 and 13 and the ground. The parallel arm resonator 23 is connected between a connection point of the series arm resonators 13 and 14 and the ground.

The parallel arm resonator 25 (first acoustic wave resonator) and the inductor 45 (first inductor) connected in series with each other are examples of an acoustic wave resonance unit including an acoustic wave resonator, and constitute the parallel arm resonance unit 20. The parallel arm resonance unit 20 is connected between a connection point between the series arm resonator 14 and the input/output terminal 120 and the ground. By connecting the inductor 45 in series to the parallel arm resonator 25, the resonant frequency frp20 of the parallel arm resonance unit 20 shifts to the low frequency side with respect to the resonant frequency frp25 of the parallel arm resonator 25. That is, the inductor 45 is connected in series to the parallel arm resonator 25, so that the resonance band width of the parallel arm resonance unit 20 is wider than the resonance band width of the parallel arm resonator 25.

Among the series arm resonators 11 to 14, the series arm resonator 14 is an example of a first series arm resonance unit, and has a resonant frequency frs14 (first resonant frequency) and an anti-resonant frequency fas14 (first anti-resonant frequency).

Among the parallel arm resonators 21 to 23 and the parallel arm resonance unit 20, the parallel arm resonance unit 20 is an example of a first parallel arm resonance unit, and has a resonant frequency frp20 (second resonant frequency) and an anti-resonant frequency fap20 (second anti-resonant frequency).

The resonant frequency frs14 (first resonant frequency) of the series arm resonator 14 (first series arm resonance unit) and the resonant frequency frp20 (second resonant frequency) of the parallel arm resonance unit 20 (first parallel arm resonance unit) are equal to or lower than the low frequency end of the pass band of the acoustic wave filter 1B. In addition, the anti-resonant frequency fas14 (first anti-resonant frequency) of the series arm resonator 14 (first series arm resonance unit) and the anti-resonant frequency fap20 (second anti-resonant frequency) of the parallel arm resonance unit 20 (first parallel arm resonance unit) are equal to or higher than the high frequency end of the pass band.

According to the above configuration, by setting the impedance in the pass band of the acoustic wave filter 1B according to the present modification example to be inductive, the impedance of the high frequency module according to the present modification example, which includes the acoustic wave filter 1B and the low noise amplifier 2, can be brought close to the reference impedance without necessarily adding a matching inductor. Therefore, the matching loss of the acoustic wave filter 1B and the high frequency module according to the present modification example can be reduced.

In addition, the resonant frequency frs14 is higher than the resonant frequency frp20, and the anti-resonant frequency fas14 is higher than the anti-resonant frequency fap20. That is, the resonant frequency frs14 is closer to the pass band among the resonant frequencies frs14 and frp20 at which the impedance is minimal, and the anti-resonant frequency fas14 is farther from the pass band among the anti-resonant frequencies fas14 and fap20 at which the impedance is maximal. Furthermore, as illustrated in FIG. 8B, a frequency difference Δfa between the anti-resonant frequency fap20 of the parallel arm resonance unit 20 and the high frequency end of the pass band of the acoustic wave filter 1B is smaller than a frequency difference Δfr between the low frequency end of the pass band and the resonant frequency frp20 of the parallel arm resonance unit 20.

As a result, a low impedance band of the inductive impedance band of the series arm resonator 14 overlaps with the pass band, and a high impedance band of the inductive impedance band of the parallel arm resonance unit 20 overlaps with the pass band. Therefore, the insertion loss of the acoustic wave filter 1B can be reduced.

In the acoustic wave filter 1B according to the present modification example, the first series arm resonance unit (series arm resonator 14) is connected closest to the input/output terminal 120 among the plurality of series arm resonance units, and the first parallel arm resonance unit (parallel arm resonance unit 20) is connected closest to the input/output terminal 120 among the plurality of parallel arm resonance units.

Accordingly, since the resonance unit that exhibits the inductive impedance in the pass band is disposed closest to the input terminal of the low noise amplifier 2 that exhibits the capacitive impedance, the impedance matching between the acoustic wave filter 1B and the low noise amplifier 2 can be performed with high efficiency and high accuracy.

The first series arm resonance unit (series arm resonator 14) does not need to be connected closest to the input/output terminal 120 among the plurality of series arm resonance units, and the first parallel arm resonance unit (parallel arm resonance unit 20) does not need to be connected closest to the input/output terminal 120 among the plurality of parallel arm resonance units. Even in this case, since it is possible to set the impedance in the pass band of the acoustic wave filter 1B to be inductive, the matching loss of the acoustic wave filter 1B and the high frequency module can be reduced.

In addition, as illustrated in FIG. 8C, the parallel arm resonance unit 20 has a high impedance in a direct current (DC) region. As a result, since the leakage of the direct current bias current (direct current bias voltage) supplied to the low noise amplifier 2 to the acoustic wave filter 1B side can be prevented, it is optional to dispose a DC cut capacitor between the acoustic wave filter 1B and the low noise amplifier 2.

Accordingly, the high frequency module according to the present modification example can be reduced in size.

In addition, in the acoustic wave filter 1B according to the present modification example, all the acoustic wave resonators included in the acoustic wave filter 1B are formed on the same piezoelectric substrate 70. As a result, the resonance band of all the acoustic wave resonators forming the pass band of the acoustic wave filter 1B can be set to be the same as the above-described pass band. On the other hand, the parallel arm resonance unit 20 that requires a resonance band wider than the above-described pass band can be set by connecting the inductor 45 in series to the parallel arm resonator 25. Accordingly, since it is optional to prepare an acoustic wave resonator having a wide resonance band width, and all the acoustic wave resonators can be integrated on one piezoelectric substrate, the acoustic wave filter 1B can be reduced in size.

Therefore, it is possible to provide the small-sized acoustic wave filter 1B and the high frequency module in which the low loss characteristics are ensured from both the viewpoints of the matching loss and the insertion loss.

In the present modification example, the first series arm resonance unit is not limited to the series arm resonator 14, and may be any of the series arm resonators 11 to 13. In addition, the first parallel arm resonance unit is not limited to the parallel arm resonance unit 20, and may be any of the parallel arm resonators 21 to 23.

In addition, in the acoustic wave filter 1B according to the present modification example, the second inductor may be connected in parallel to any of the series arm resonators 11 to 14 (second acoustic wave resonators). In this case, a circuit in which the second acoustic wave resonator and the second inductor are connected in parallel may be the first series arm resonance unit.

Since the second inductor is connected in parallel to the second acoustic wave resonator, the first anti-resonant frequency of the first series arm resonance unit is shifted to the high frequency side with respect to the anti-resonant frequency of the second acoustic wave resonator. That is, since the second inductor is connected in parallel to the second acoustic wave resonator, the resonance band width of the first series arm resonance unit is wider than the resonance band width of the second acoustic wave resonator.

In this case, the first resonant frequency of the first series arm resonance unit and the second resonant frequency of the first parallel arm resonance unit are equal to or lower than the low frequency end of the pass band of the acoustic wave filter 1B. In addition, the first anti-resonant frequency of the first series arm resonance unit and the second anti-resonant frequency of the first parallel arm resonance unit are equal to or higher than the high frequency end of the above-described pass band.

According to the above configuration, by setting the impedance in the pass band of the acoustic wave filter 1B according to the present modification example to be inductive, the impedance of the high frequency module according to the present modification example, which includes the acoustic wave filter 1B and the low noise amplifier 2, can be brought close to the reference impedance without necessarily adding a matching inductor. Therefore, the matching loss of the acoustic wave filter 1B and the high frequency module according to the present modification example can be reduced.

In addition, the first resonant frequency is higher than the second resonant frequency, and the first anti-resonant frequency is higher than the second anti-resonant frequency. That is, the first resonant frequency is closer to the pass band among the first resonant frequency and the second resonant frequency at which the impedance is minimal, and the first anti-resonant frequency is farther from the pass band among the first anti-resonant frequency and the second anti-resonant frequency at which the impedance is maximal. Furthermore, a frequency difference Δfr1 between the low frequency end of the pass band of the acoustic wave filter 1B and the first resonant frequency is smaller than a frequency difference Δfa1 between the first anti-resonant frequency and the high frequency end of the pass band.

As a result, a low impedance band of the inductive impedance band of the first series arm resonance unit overlaps with the pass band, and a high impedance band of the inductive impedance band of the first parallel arm resonance unit overlaps with the pass band. Therefore, the insertion loss of the acoustic wave filter 1B can be reduced.

### 6 Component Disposition of High Frequency Module 100

Next, the component disposition of the high frequency module 100 according to the present embodiment will be described.

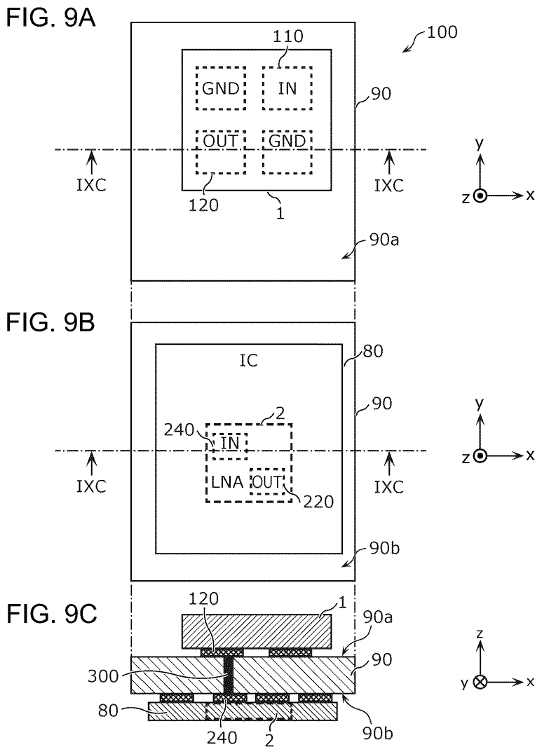

FIGS. 9A-9C is a plan view and a cross-sectional view of the high frequency module 100 according to the embodiment. FIG. 9A illustrates the disposition of the circuit components in a case where the main surface 90a of the mounting substrate 90 is viewed from the z-axis positive direction side. In addition, FIG. 9B illustrates the disposition of the circuit components in a case where the main surface 90b of the mounting substrate 90 is viewed from the z-axis positive direction side. In addition, FIG. 9C illustrates a cross-sectional view taken along the line IXC-IXC of FIGS. 9A and 9B. In FIGS. 9A-9C, the wiring connecting the mounting substrate 90 and each circuit component is partially omitted.

The high frequency module 100 illustrated in FIGS. 9A-9C further includes the mounting substrate 90 with respect to the high frequency module 100 illustrated in FIG. 1.

The mounting substrate 90 has main surfaces 90a (first main surface) and 90b (second main surface) facing each other. In FIGS. 9A-9C, the mounting substrate 90 has a rectangular shape in a plan view, but the shape of the mounting substrate 90 is not limited thereto.

As the mounting substrate 90, for example, a low temperature co-fired ceramics (LTCC) substrate or a high temperature co-fired ceramics (HTCC) substrate having a multilayer structure of a plurality of dielectric layers, a component-embedded substrate, a substrate having a redistribution layer (RDL), a printed board, or the like can be used, and the mounting substrate 90 is not limited thereto.

The acoustic wave filter 1 is disposed on the main surface 90a of the mounting substrate 90. The low noise amplifier 2 is disposed on the main surface 90b of the mounting substrate 90. A resin member and a shield electrode layer may be formed on the main surfaces 90a and 90b. Accordingly, since the acoustic wave filter 1 and the low noise amplifier 2 are distributed and disposed on the main surfaces 90a and 90b of the mounting substrate 90, the high frequency module 100 can be reduced in size.

As illustrated in FIG. 9A, the acoustic wave filter 1 is, for example, formed as one chip (hereinafter, referred to as a filter chip) including a piezoelectric substrate, a package, or the like. The input/output terminal 110 (IN) and 120 (OUT) and a ground electrode (GND) are formed on the main surface of the filter chip facing the mounting substrate 90. The input/output terminals 110 and 120 and the ground electrode may be planar electrodes or bump electrodes.

As illustrated in FIG. 9B, the low noise amplifier 2 is formed in the integrated circuit 80. An input terminal 240 (IN) and an output terminal 220 (OUT) of the low noise amplifier 2 are formed on a main surface of the integrated circuit 80 facing the mounting substrate 90. The input terminal 240 and the output terminal 220 may be planar electrodes or bump electrodes.

The integrated circuit 80 is configured using, for example, a complementary metal oxide semiconductor (CMOS) and specifically, may be manufactured through a silicon on insulator (SOI) process. The integrated circuit 80 is not limited to the CMOS.

As illustrated in FIG. 9C, the input/output terminal 120 and the input terminal 240 are connected to each other with a via conductor 300 interposed therebetween, without necessarily passing through a matching circuit element.

Here, in a case where the mounting substrate 90 is viewed in a plan view, the acoustic wave filter 1 and the low noise amplifier 2 at least partially overlap with each other.

Accordingly, since the wiring connecting the acoustic wave filter 1 and the low noise amplifier 2 can be shortened, the high frequency module 100 can be reduced in the loss.

In addition, in a case where the mounting substrate 90 is viewed in a plan view, the input/output terminal 120 and the input terminal 240 may at least partially overlap with each other.

Accordingly, since the acoustic wave filter 1 and the low noise amplifier 2 can be connected to each other only through the via conductor 300, the high frequency module 100 can be further reduced in the loss.

### 7 Component Disposition of High Frequency Module 200 According to Modification Example 3

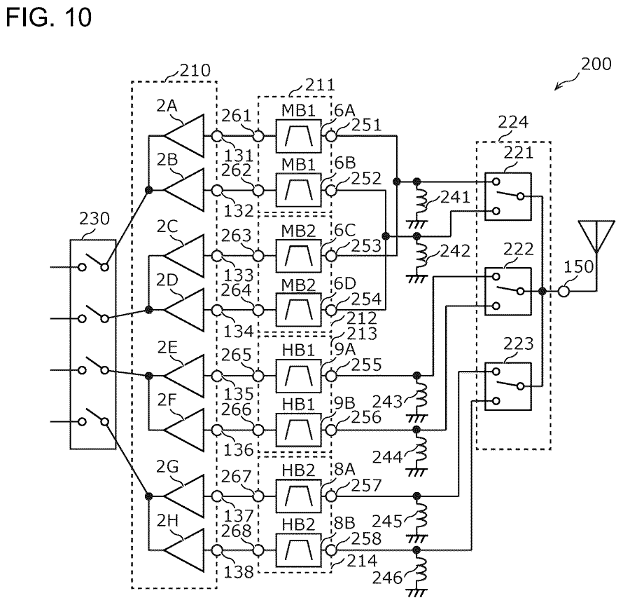

FIG. 10 is a circuit configuration diagram of a high frequency module 200 according to Modification Example 3. As illustrated in the figure, the high frequency module 200 according to the present modification example is provided with acoustic wave filters 6A, 6B, 6C, 6D, 9A, 9B, 8A, and 8B, low noise amplifiers 2A, 2B, 2C, 2D, 2E, 2F, 2G, and 2H, switches 221, 222, 223, and 230, inductors 241, 242, 243, 244, 245, and 246, and an antenna connection terminal 150.

The acoustic wave filters 6A, 6B, 9A, and 9B are examples of a first acoustic wave filter, and have, for example, the same circuit configuration and the same resonance characteristics of the acoustic wave resonator as those of any of the acoustic wave filter 1 according to the embodiment, the acoustic wave filter 1A according to Modification Example 1, and the acoustic wave filter 1B according to Modification Example 2.

The acoustic wave filter 6A includes an input/output terminal 251 (second input/output terminal) and an input/output terminal 261 (first input/output terminal), and has, for example, a pass band including at least a part of a band A belonging to a mid band group (1427 to 2200 MHZ, hereinafter referred to as MB).

The acoustic wave filter 6B includes an input/output terminal 252 (second input/output terminal) and an input/output terminal 262 (first input/output terminal), and has, for example, a pass band including at least a part of a band B belonging to the MB group. The acoustic wave filter 9A includes an input/output terminal 255 (second input/output terminal) and an input/output terminal 265 (first input/output terminal), and has, for example, a pass band including at least a part of a band E belonging to a high band group (2300 to 2690 MHz, hereinafter referred to as HB). The acoustic wave filter 9B includes an input/output terminal 256 (second input/output terminal) and an input/output terminal 266 (first input/output terminal), and has, for example, a pass band including at least a part of a band F belonging to the HB group.

The acoustic wave filter 6C includes an input/output terminal 253 (fourth input/output terminal) and an input/output terminal 263 (third input/output terminal), and has, for example, a pass band including at least a part of a band C belonging to the MB group. The acoustic wave filter 6D includes an input/output terminal 254 (fourth input/output terminal) and an input/output terminal 264 (third input/output terminal), and has, for example, a pass band including at least a part of a band D belonging to the MB group. The acoustic wave filter 8A includes an input/output terminal 257 (fourth input/output terminal) and an input/output terminal 267 (third input/output terminal), and has, for example, a pass band including at least a part of a band G belonging to the HB group. The acoustic wave filter 8B includes an input/output terminal 258 (fourth input/output terminal) and an input/output terminal 268 (third input/output terminal), and has, for example, a pass band including at least a part of a band H belonging to the HB group.

The low noise amplifiers 2A, 2B, 2E, and 2F are examples of a first low noise amplifier, and have the same circuit configuration and the same amplification characteristics as the low noise amplifier 2 according to the embodiment.

The low noise amplifier 2A includes an input terminal 131. The input terminal 131 is an example of a first input terminal and is connected to the input/output terminal 261 without necessarily passing through an inductor. The low noise amplifier 2B includes an input terminal 132. The input terminal 132 is an example of a first input terminal and is connected to the input/output terminal 262 without necessarily passing through an inductor. The low noise amplifier 2E includes an input terminal 135. The input terminal 135 is an example of a first input terminal and is connected to the input/output terminal 265 without necessarily passing through an inductor. The low noise amplifier 2F includes an input terminal 136. The input terminal 136 is an example of a first input terminal and is connected to the input/output terminal 266 necessarily passing through an inductor.

The low noise amplifiers 2C, 2D, 2G, and 2H are examples of a second low noise amplifier, and have the same circuit configuration and the same amplification characteristics as the low noise amplifier 2 according to the embodiment.

The low noise amplifier 2C includes an input terminal 133. The input terminal 133 is an example of a second input terminal and is connected to the input/output terminal 263 necessarily passing through an inductor. The low noise amplifier 2D includes an input terminal 134. The input terminal 134 is an example of a second input terminal and is connected to the input/output terminal 264 without necessarily passing through an inductor. The low noise amplifier 2G includes an input terminal 137. The input terminal 137 is an example of a second input terminal and is connected to the input/output terminal 267 without necessarily passing through an inductor. The low noise amplifier 2H includes an input terminal 138. The input terminal 138 is an example of a second input terminal and is connected to the input/output terminal 268 without necessarily passing through an inductor.

The acoustic wave filters 6A and 6B are included in the filter integrated component 211. The filter integrated component 211 is an example of a first integrated component, and has, for example, a configuration in which the acoustic wave resonators of the acoustic wave filters 6A and 6B are disposed on a common piezoelectric substrate. The acoustic wave filters 9A and 9B are included in the filter integrated component 213. The filter integrated component 213 is an example of a first integrated component, and has, for example, a configuration in which the acoustic wave resonators of the acoustic wave filters 9A and 9B are disposed on a common piezoelectric substrate.

The acoustic wave filters 6C and 6D are included in the filter integrated component 212. The filter integrated component 212 is an example of a second integrated component, and has, for example, a configuration in which the acoustic wave resonators of the acoustic wave filters 6C and 6D are disposed on a common piezoelectric substrate. The acoustic wave filters 8A and 8B are included in the filter integrated component 214. The filter integrated component 214 is an example of a second integrated component, and has, for example, a configuration in which the acoustic wave resonators of the acoustic wave filters 8A and 8B are disposed on a common piezoelectric substrate.

The low noise amplifiers 2A to 2H are included in the integrated circuit 210. The integrated circuit 210 is configured by using, for example, a CMOS, and specifically, may be manufactured by an SOI process. The integrated circuit 210 is not limited to the CMOS.

The switch 221 is an example of an antenna switch, includes a first common terminal, a first selection terminal, and a second selection terminal, and switches the connection between the first common terminal and the first selection terminal and a connection between the first common terminal and the first selection terminal. The first common terminal is connected to the antenna connection terminal 150, the first selection terminal is connected to the acoustic wave filters 6A and 6C, and the second selection terminal is connected to the acoustic wave filters 6B and 6D.

The switch 222 is an example of an antenna switch, includes a second common terminal, a third selection terminal, and a fourth selection terminal, and switches the connection between the second common terminal and the third selection terminal and a connection between the second common terminal and the fourth selection terminal. The second common terminal is connected to the antenna connection terminal 150, the third selection terminal is connected to the acoustic wave filter 9A, and the fourth selection terminal is connected to the acoustic wave filter 9B.

The switch 223 is an example of an antenna switch, includes a third common terminal, a fifth selection terminal, and a sixth selection terminal, and switches the connection between the third common terminal and the fifth selection terminal and a connection between the third common terminal and the sixth selection terminal. The third common terminal is connected to the antenna connection terminal 150, the fifth selection terminal is connected to the acoustic wave filter 8A, and the sixth selection terminal is connected to the acoustic wave filter 8B.

The switches 221, 222, and 223 constitute a switch circuit 224.

The switch 230 is an example of an output switch and includes, for example, four single pole single throw (SPST) switches. The switch 230 switches the connection and disconnection between the low noise amplifiers 2A and 2B and the first output terminal, switches the connection and disconnection between the low noise amplifiers 2C and 2D and the second output terminal, switches the connection and disconnection between the low noise amplifiers 2E and 2F and the third output terminal, and switches the connection and disconnection between the low noise amplifiers 2G and 2H and the fourth output terminal.

The inductor 241 is connected to a path connecting the switch 221 and the acoustic wave filters 6A and 6C. The inductor 242 is connected to a path connecting the switch 221 and the acoustic wave filters 6B and 6D. The inductor 243 is connected to a path connecting the switch 222 and the acoustic wave filter 9A. The inductor 244 is connected to a path connecting the switch 222 and the acoustic wave filter 9B. The inductor 245 is connected to a path connecting the switch 223 and the acoustic wave filter 8A. The inductor 246 is connected to a path connecting the switch 223 and the acoustic wave filter 8B.

According to the above configuration, the high frequency module 200 can switch and execute (1) simultaneous transmission of the signals of the bands A and C belonging to the MB or the signals of the bands B and D belonging to the MB, the signal of the band E belonging to the HB or the signal of the band F, and the signal of the band G belonging to the HB or the signal of the band H.

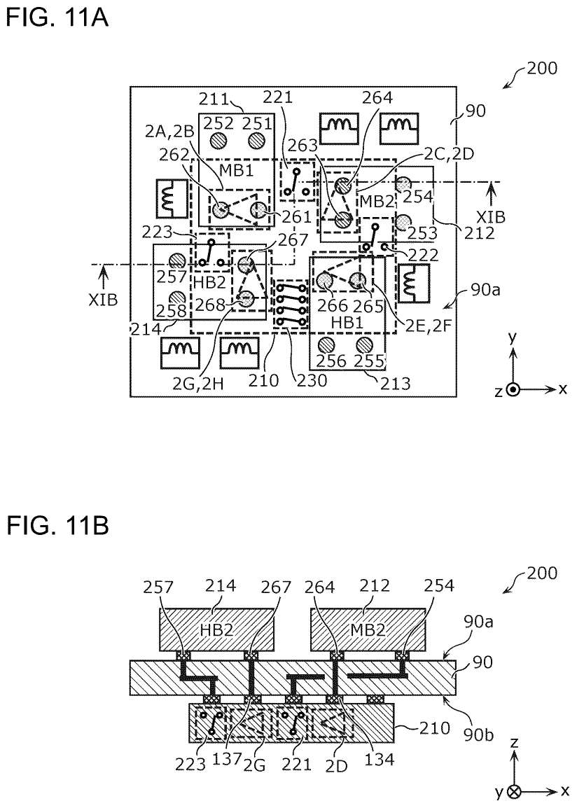

FIG. 11A is a plan view of a high frequency module 200 according to Modification Example 3. FIG. 11B is a cross-sectional view of the high frequency module 200 according to Modification Example 3. FIG. 11A illustrates the disposition of the circuit components in a case where the main surface 90a of the mounting substrate 90 is viewed from the z-axis positive direction side. In addition, FIG. 11B illustrates a cross-sectional view taken along the line XIB-XIB in FIG. 11A. In FIG. 11A, circuit components disposed on the main surface 90a side are illustrated by solid lines, and circuit components disposed on the main surface 90b side are illustrated by broken lines.

As illustrated in FIGS. 11A and 11B, the high frequency module 200 is further provided with the mounting substrate 90 in addition to the circuit components illustrated in FIG. 10.

The mounting substrate 90 has main surfaces 90a (first main surface) and 90b (second main surface) facing each other. As the mounting substrate 90, for example, an LTCC substrate or an HTCC substrate having a multilayer structure of a plurality of dielectric layers, a component-incorporated substrate, a substrate having an RDL, a printed board, or the like can be used, and the present disclosure is not limited thereto.

As illustrated in FIGS. 11A and 11B, the filter integrated components 211 to 214 are disposed on the main surface 90a, and the low noise amplifiers 2A to 2H and the switches 221, 222, 223, and 230 are disposed on the main surface 90b.

Accordingly, since the filter integrated components 211 to 214, the low noise amplifiers 2A to 2H, and the switches 221, 222, 223, and 230 are distributed and disposed on the main surfaces 90a and 90b of the mounting substrate 90, the high frequency module 200 can be reduced in size.

The main surface 90a includes a first outer peripheral region and a first central region located inside the first outer peripheral region, and the main surface 90b includes a second outer peripheral region and a second central region located inside the second outer peripheral region.

The input/output terminals 261 to 268 of the filter integrated components 211 to 214 are disposed in the first central region. In addition, the low noise amplifiers 2A to 2H are disposed in the second central region. In a case where the mounting substrate 90 is viewed in a plan view, each of the input/output terminals 261 and 262 overlaps with the low noise amplifier 2A or 2B, each of the input/output terminals 263 and 264 overlaps with the low noise amplifier 2C or 2D, each of the input/output terminals 265 and 266 overlaps with the low noise amplifier 2E or 2F, and each of the input/output terminals 267 and 268 overlaps with the low noise amplifier 2G or 2H.

Accordingly, since the input/output terminals 261 to 268 are disposed to overlap with the low noise amplifiers 2A to 2H in the plan view, the wiring connecting the input/output terminals 261 to 268 and the low noise amplifiers 2A to 2H can be shortened. As a result, since the transmission loss and the stray capacitance of the above-described wiring can be reduced, the noise figure of the low noise amplifiers 2A to 2H can be improved.

In addition, in the plan view, the input/output terminals 251 and 252 are disposed on the outer peripheral side with respect to the input/output terminals 261 and 262, the input/output terminals 253 and 254 are disposed on the outer peripheral side with respect to the input/output terminals 263 and 264, the input/output terminals 255 and 256 are disposed on the outer peripheral side with respect to the input/output terminals 265 and 266, and the input/output terminals 257 and 258 are disposed on the outer peripheral side with respect to the input/output terminals 267 and 268. In addition, in the plan view, the switches 221 to 223 are disposed in the second outer peripheral region.

Accordingly, since the input/output terminals 251 to 258 are disposed on the outer peripheral side with respect to the input/output terminals 261 to 268 in the plan view, and the switches 221 and 223 are disposed in the second outer peripheral region, the wiring connecting the input/output terminals 251 to 258 and the switches 221 and 223 can be shortened. As a result, since the transmission loss and the stray capacitance of the above-described wirings can be reduced, impedance matching between the antenna and the acoustic wave filters 6A to 6D, 9A, 9B, 8A, and 8B can be achieved with high accuracy.

### 8 Component Disposition of High Frequency Module 202 According to Modification Example 4

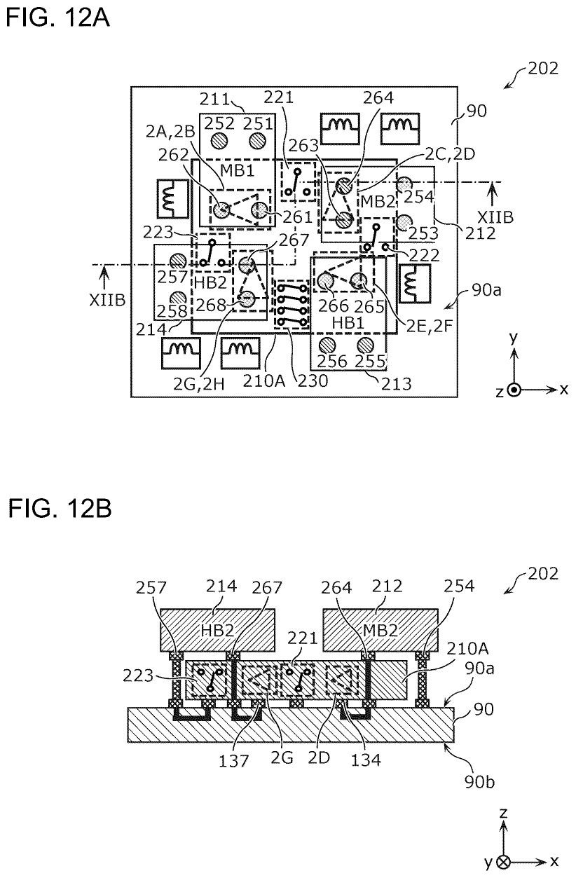

Next, the component disposition of the high frequency module 202 according to Modification Example 4 will be described. FIG. 12A is a plan view of a high frequency module 202 according to Modification Example 4. FIG. 12B is a cross-sectional view of the high frequency module 202 according to Modification Example 4. FIG. 12A illustrates the disposition of the circuit components in a case where the main surface 90a of the mounting substrate 90 is viewed from the z-axis positive direction side. In addition, FIG. 12B illustrates a cross-sectional view taken along the line XIIB-XIIB in FIG. 12A. In FIG. 12A, circuit components disposed on the main surface 90a side are illustrated by solid lines, and a portion overlapping with a circuit component on the z-axis positive direction side among the circuit components disposed on the main surface 90a side is illustrated by a broken line.

The high frequency module 202 according to the present modification example has the same circuit connection configuration as the high frequency module 200 according to Modification Example 3, and only the component disposition configuration is different. Therefore, in the following, the high frequency module 202 according to the present modification example will be described with a focus on the component disposition configuration.

As illustrated in FIGS. 12A and 12B, the high frequency module 202 is further provided with the mounting substrate 90 in addition to the circuit components illustrated in FIG. 10.

The mounting substrate 90 has main surfaces 90a (first main surface) and 90b (second main surface) facing each other. As the mounting substrate 90, for example, an LTCC substrate or an HTCC substrate having a multilayer structure of a plurality of dielectric layers, a component-incorporated substrate, a substrate having an RDL, a printed board, or the like can be used, and the present disclosure is not limited thereto.

The low noise amplifiers 2A to 2H and the switches 221, 222, 223, and 230 are included in the integrated circuit 210A. The integrated circuit 210A is an example of a third integrated component, and may be configured by using, for example, a CMOS, and specifically, may be manufactured by an SOI process. The integrated circuit 210A is not limited to the CMOS. The switches 221, 222, 223, and 230 do not need to be included in the integrated circuit 210A.

As illustrated in FIGS. 12A and 12B, the filter integrated components 211 to 214 and the integrated circuit 210A are disposed on the main surface 90a.

The filter integrated component 211 and the integrated circuit 210A are disposed on the main surface 90a in the order of the mounting substrate 90, the integrated circuit 210A, and the filter integrated component 211. The filter integrated component 212 and the integrated circuit 210A are disposed on the main surface 90a in the order of the mounting substrate 90, the integrated circuit 210A, and the filter integrated component 212. The filter integrated component 213 and the integrated circuit 210A are disposed on the main surface 90a in the order of the mounting substrate 90, the integrated circuit 210A, and the filter integrated component 213. The filter integrated component 214 and the integrated circuit 210A are disposed on the main surface 90a in the order of the mounting substrate 90, the integrated circuit 210A, and the filter integrated component 214.

That is, the integrated circuit 210A is disposed on the main surface 90a of the mounting substrate 90, and the filter integrated components 211 to 214 are disposed on the z-axis positive direction side of the integrated circuit 210A.

The main surface 90a includes a first outer peripheral region and a first central region located inside the first outer peripheral region.

The input/output terminals 261 to 268 of the filter integrated components 211 to 214 are disposed in the first central region. In addition, the low noise amplifiers 2A to 2H are disposed in the first central region. In a case where the mounting substrate 90 is viewed in a plan view, each of the input/output terminals 261 and 262 overlaps with the low noise amplifier 2A or 2B, each of the input/output terminals 263 and 264 overlaps with the low noise amplifier 2C or 2D, each of the input/output terminals 265 and 266 overlaps with the low noise amplifier 2E or 2F, and each of the input/output terminals 267 and 268 overlaps with the low noise amplifier 2G or 2H.

The input/output terminals 261 to 268 are connected to the low noise amplifiers 2A to 2H with a via conductor in the integrated circuit 210A and a wiring in the mounting substrate 90 interposed therebetween.

Accordingly, since the input/output terminals 261 to 268 are disposed to overlap with the low noise amplifiers 2A to 2H in the plan view, the wiring connecting the input/output terminals 261 to 268 and the low noise amplifiers 2A to 2H can be shortened. As a result, since the transmission loss and the stray capacitance of the above-described wiring can be reduced, the noise figure of the low noise amplifiers 2A to 2H can be improved.

In addition, in the plan view, the input/output terminals 251 and 252 are disposed on the outer peripheral side with respect to the input/output terminals 261 and 262, the input/output terminals 253 and 254 are disposed on the outer peripheral side with respect to the input/output terminals 263 and 264, the input/output terminals 255 and 256 are disposed on the outer peripheral side with respect to the input/output terminals 265 and 266, and the input/output terminals 257 and 258 are disposed on the outer peripheral side with respect to the input/output terminals 267 and 268. In addition, in the plan view, the switches 221 to 223 are disposed in the first outer peripheral region.

Accordingly, since the input/output terminals 251 to 258 are disposed on the outer peripheral side with respect to the input/output terminals 261 to 268 in the plan view, and the switches 221 and 223 are disposed in the first outer peripheral region, the wiring connecting the input/output terminals 251 to 258 and the switches 221 and 223 can be shortened. As a result, since the transmission loss and the stray capacitance of the above-described wiring can be reduced, impedance matching between the antenna and the acoustic wave filters 6A to 6D, 7A, 7B, 8A, and 8B can be achieved with high accuracy.

### 9 Component Disposition of High Frequency Module 203 According to Modification Example 5

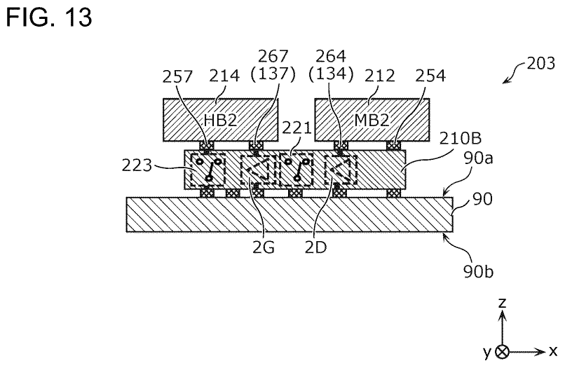

Next, the component disposition of the high frequency module 203 according to Modification Example 5 will be described. FIG. 13 is a cross-sectional view of a high frequency module 203 according to Modification Example 5.

The high frequency module 203 according to the present modification example has the same circuit connection configuration as the high frequency module 202 according to Modification Example 4, and only the connection configuration between the filter integrated components 211 to 214 and the integrated circuit 210B is different. Therefore, in the following, the high frequency module 203 according to the present modification example will be described with a focus on the above-described connection configuration.

The low noise amplifiers 2A to 2H and the switches 221, 222, 223, and 230 are included in the integrated circuit 210B. The integrated circuit 210B is an example of a third integrated component, and may be configured by using, for example, a CMOS, and specifically, may be manufactured by an SOI process. The integrated circuit 210B is not limited to the CMOS. The switches 221, 222, 223, and 230 do not need to be included in the integrated circuit 210B.

As illustrated in FIG. 13, the filter integrated components 211 to 214 and the integrated circuit 210B are disposed on the main surface 90a.

The filter integrated component 211 and the integrated circuit 210B are disposed on the main surface 90a in the order of the mounting substrate 90, the integrated circuit 210B, and the filter integrated component 211. The filter integrated component 212 and the integrated circuit 210B are disposed on the main surface 90a in the order of the mounting substrate 90, the integrated circuit 210B, and the filter integrated component 212. The filter integrated component 213 and the integrated circuit 210B are disposed on the main surface 90a in the order of the mounting substrate 90, the integrated circuit 210B, and the filter integrated component 213. The filter integrated component 214 and the integrated circuit 210B are disposed on the main surface 90a in the order of the mounting substrate 90, the integrated circuit 210B, and the filter integrated component 214.

That is, the integrated circuit 210B is disposed on the main surface 90a of the mounting substrate 90, and the filter integrated components 211 to 214 are disposed on the z-axis positive direction side of the integrated circuit 210B.

The filter integrated component 211 has main surfaces 211a (third main surface) and main surfaces 211b (fourth main surface) facing each other. The filter integrated component 213 has a main surface 213a (third main surface) and a main surface 213b (fourth main surface) facing each other. The filter integrated component 212 has a main surface 212a (fifth main surface) and a main surface 212b (sixth main surface) facing each other. The filter integrated component 214 has main surfaces 214a (fifth main surface) and main surfaces 214b (sixth main surface) facing each other. The integrated circuit 210B has a main surface 210a (seventh main surface) and a main surface 210b (eighth main surface) facing each other.

The main surface 210a faces the main surface 90a, and the main surface 210b faces the main surface 211a and the main surface 212a. The input/output terminals 261 and 262 are disposed on the main surface 211a, the input/output terminals 265 and 266 are disposed on the main surface 213a, the input/output terminals 263 and 264 are disposed on the main surface 212a, and the input/output terminals 267 and 268 are disposed on the main surface 214a. The input terminals 131 to 138 are disposed on the main surface 210b.

The main surface 90a includes a first outer peripheral region and a first central region located inside the first outer peripheral region.

The input/output terminals 261 to 268 of the filter integrated components 211 to 214 are disposed in the first central region. In addition, the low noise amplifiers 2A to 2H are disposed in the first central region. In a case where the mounting substrate 90 is viewed in a plan view, each of the input/output terminals 261 and 262 overlaps with the low noise amplifier 2A or 2B, each of the input/output terminals 263 and 264 overlaps with the low noise amplifier 2C or 2D, each of the input/output terminals 265 and 266 overlaps with the low noise amplifier 2E or 2F, and each of the input/output terminals 267 and 268 overlaps with the low noise amplifier 2G or 2H.

Accordingly, since the input/output terminals 261 to 268 of the filter integrated components 211 to 214 and the input terminals 131 to 138 of the low noise amplifiers 2A to 2H are disposed to face each other, the input/output terminals 261 to 268 and the input terminals 131 to 138 can be directly connected to each other without necessarily passing through the via conductors in the integrated circuit 210B. As a result, the wiring connecting the input/output terminals 261 to 268 and the low noise amplifiers 2A to 2H can be further shortened. As a result, since the transmission loss and the stray capacitance of the above-described wiring can be reduced, the noise figure of the low noise amplifiers 2A to 2H can be improved. Furthermore, since it is optional to form the via conductors connecting the input/output terminals 261 to 268 and the input terminals 131 to 138 in the integrated circuit 210B, the integrated circuit 210B can be reduced in size.

### 10 Component Disposition of High Frequency Module 204 According to Modification Example 6

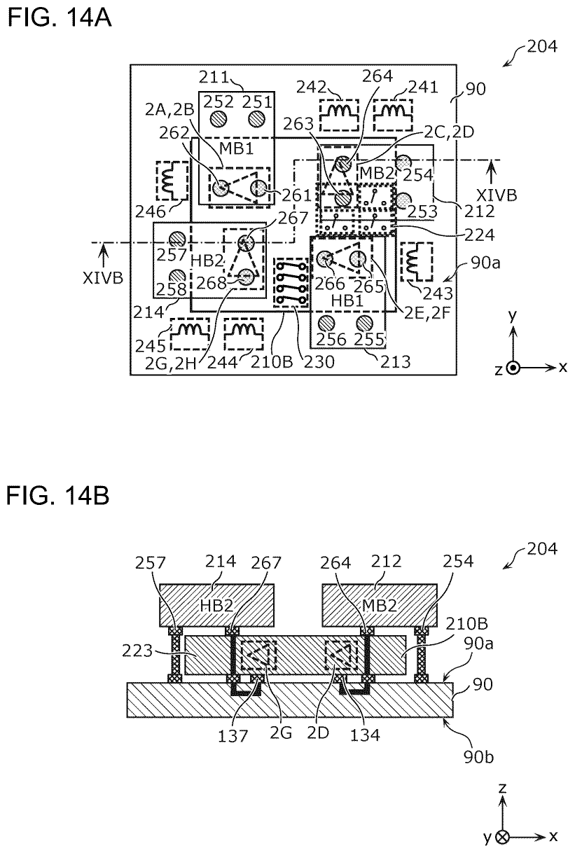

Next, the component disposition of the high frequency module 204 according to Modification Example 6 will be described. FIG. 14A is a plan view of a high frequency module 204 according to Modification Example 6. FIG. 14B is a cross-sectional view of the high frequency module 204 according to Modification Example 6. FIG. 14A illustrates the disposition of the circuit components in a case where the main surface 90a of the mounting substrate 90 is viewed from the z-axis positive direction side. In addition, FIG. 14B illustrates a cross-sectional view taken along the XIVB-XIVB line of FIG. 14A. In FIG. 14A, circuit components disposed on the main surface 90a side are illustrated by solid lines, and a portion overlapping with a circuit component on the z-axis positive direction side among the circuit components disposed on the main surface 90a side is illustrated by a broken line.

The high frequency module 204 according to the present modification example has the same circuit connection configuration as the high frequency module 200 according to Modification Example 3, and only the component disposition configuration is different. Therefore, in the following, the high frequency module 204 according to the present modification example will be described with a focus on the above-described component disposition configuration.

The high frequency module 204 according to the present modification example has the same circuit connection configuration as the high frequency module 202 according to Modification Example 4, and only the component disposition configuration is different. Therefore, in the following, the high frequency module 204 according to the present modification example will be described with a focus on the above-described component disposition configuration.

The switches 221, 222, and 223 constitute a switch circuit 224. The switch circuit 224 is an example of a first switch, switches the connection between the antenna connection terminal 150 and the input/output terminals 251 and 253 and a connection between the antenna connection terminal 150 and the input/output terminals 252 and 254, switches the connection between the antenna connection terminal 150 and the input/output terminal 255 and a connection between the antenna connection terminal 150 and the input/output terminal 256, and switches the connection between the antenna connection terminal 150 and the input/output terminal 257 and a connection between the antenna connection terminal 150 and the input/output terminal 258.

The low noise amplifiers 2A to 2H and the switch circuit 224 are included in the integrated circuit 210B. The integrated circuit 210B is an example of a third integrated component, and may be configured by using, for example, a CMOS, and specifically, may be manufactured by an SOI process. The integrated circuit 210B is not limited to the CMOS.

As illustrated in FIG. 14B, the filter integrated components 211 to 214 and the integrated circuit 210B are disposed on the main surface 90a.

The filter integrated component 211 and the integrated circuit 210B are disposed on the main surface 90a in the order of the mounting substrate 90, the integrated circuit 210B, and the filter integrated component 211. The filter integrated component 212 and the integrated circuit 210B are disposed on the main surface 90a in the order of the mounting substrate 90, the integrated circuit 210B, and the filter integrated component 212. The filter integrated component 213 and the integrated circuit 210B are disposed on the main surface 90a in the order of the mounting substrate 90, the integrated circuit 210B, and the filter integrated component 213. The filter integrated component 214 and the integrated circuit 210B are disposed on the main surface 90a in the order of the mounting substrate 90, the integrated circuit 210B, and the filter integrated component 214.

That is, the integrated circuit 210B is disposed on the main surface 90a of the mounting substrate 90, and the filter integrated components 211 to 214 are disposed on the z-axis positive direction side of the integrated circuit 210B.

The main surface 90a includes a first outer peripheral region and a first central region located inside the first outer peripheral region.

The input/output terminals 261 to 268 of the filter integrated components 211 to 214 are disposed in the first central region. In addition, the low noise amplifiers 2A to 2H are disposed in the first central region. In a case where the mounting substrate 90 is viewed in a plan view, each of the input/output terminals 261 and 262 overlaps with the low noise amplifier 2A or 2B, each of the input/output terminals 263 and 264 overlaps with the low noise amplifier 2C or 2D, each of the input/output terminals 265 and 266 overlaps with the low noise amplifier 2E or 2F, and each of the input/output terminals 267 and 268 overlaps with the low noise amplifier 2G or 2H.

Accordingly, since the input/output terminals 261 to 268 are disposed to overlap with the low noise amplifiers 2A to 2H in the plan view, the wiring connecting the input/output terminals 261 to 268 and the low noise amplifiers 2A to 2H can be shortened. As a result, since the transmission loss and the stray capacitance of the above-described wiring can be reduced, the noise figure of the low noise amplifiers 2A to 2H can be improved.

In addition, in the plan view, the input/output terminals 251 and 252 are disposed on the outer peripheral side with respect to the input/output terminals 261 and 262, the input/output terminals 253 and 254 are disposed on the outer peripheral side with respect to the input/output terminals 263 and 264, the input/output terminals 255 and 256 are disposed on the outer peripheral side with respect to the input/output terminals 265 and 266, and the input/output terminals 257 and 258 are disposed on the outer peripheral side with respect to the input/output terminals 267 and 268. In addition, in the plan view, the switches 221 and 223 of the switch circuit 224 are disposed close to each other in the first outer peripheral region.

Accordingly, since the input/output terminals 251 to 258 are disposed on the outer peripheral side with respect to the input/output terminals 261 to 268 in the plan view, and the switch circuit 224 is disposed in the first outer peripheral region, the wiring connecting the input/output terminals 251 to 258 and the switch circuit 224 can be shortened. In addition, the wiring connecting the switch circuit 224 and the antenna can be shortened. As a result, since the transmission loss and the stray capacitance of the above-described wiring can be reduced, impedance matching between the antenna and the acoustic wave filters 6A to 6D, 7A, 7B, 8A, and 8B can be achieved with high accuracy.

In addition, at least one of the inductors 241 to 246 may be formed inside the mounting substrate 90. Accordingly, since the number of components disposed on the main surface 90a can be reduced, the high frequency module 204 can be reduced in size.

### 11 Component Disposition of High Frequency Module 151 According to Modification Examples 7 to 9

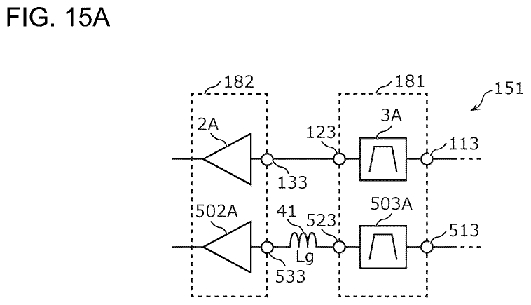

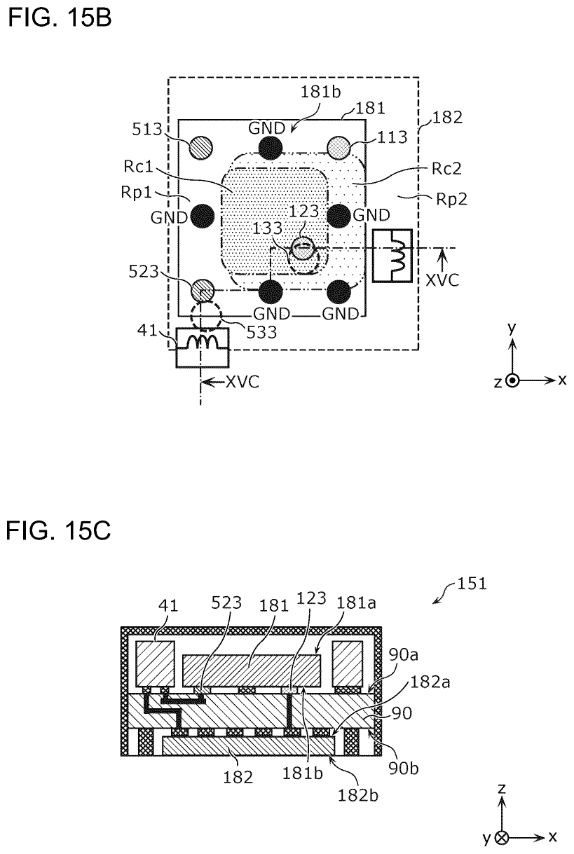

FIG. 15A is a circuit configuration diagram of a high frequency module 151 according to Modification Example 7. As illustrated in the figure, the high frequency module 151 according to the present modification example is provided with acoustic wave filters 3A and 503A, low noise amplifiers 2A and 502A, and the inductor 41.

The acoustic wave filter 3A is an example of a first acoustic wave filter, and has, for example, the same circuit configuration and the same resonance characteristics of the acoustic wave resonator as those of any of the acoustic wave filter 1 according to the embodiment, the acoustic wave filter 1A according to Modification Example 1, or the acoustic wave filter 1B according to Modification Example 2. The acoustic wave filter 3A includes an input/output terminal 113 (second input/output terminal) and an input/output terminal 123 (first input/output terminal).

The acoustic wave filter 503A is an example of a second acoustic wave filter, and has, for example, the same circuit configuration and the same resonance characteristics of the acoustic wave resonator as that of the acoustic wave filter 501 according to the comparative example. The acoustic wave filter 503A includes an input/output terminal 513 (fourth input/output terminal) and an input/output terminal 523 (third input/output terminal).

The low noise amplifier 2A is an example of a first low noise amplifier, and has the same circuit configuration and the same amplification characteristics as the low noise amplifier 2 according to the embodiment. The low noise amplifier 2A includes an input terminal 133. The input terminal 133 is an example of a first input terminal and is connected to the input/output terminal 123 without necessarily passing through an inductor. The low noise amplifier 502A is an example of a second low noise amplifier, and has the same circuit configuration and the same amplification characteristics as the low noise amplifier 2 according to the embodiment. The low noise amplifier 502A includes an input terminal 533. The input terminal 533 is an example of a second input terminal and is connected to the input/output terminal 523 with the inductor 41 interposed therebetween.

The inductor 41 is an example of a third inductor, and is disposed between the low noise amplifier 502A having a capacitive input impedance and the acoustic wave filter 503A. The inductor 41 having the inductive impedance enables the matching of the low noise amplifier 502A and the acoustic wave filter 503A at the reference impedance.

The acoustic wave filters 3A and 503A are included in the filter integrated component 181. The filter integrated component 181 is an example of a first integrated component, and has, for example, a configuration in which the acoustic wave resonators of the acoustic wave filters 3A and 503A are disposed on a common piezoelectric substrate.

The low noise amplifiers 2A and 502A are included in the integrated circuit 182. The integrated circuit 182 is an example of a second integrated component, and may be configured by using, for example, a CMOS, and specifically, may be manufactured by an SOI process. The integrated circuit 182 is not limited to the CMOS.

Next, the component disposition of the high frequency module 151 according to the present modification example will be described. FIG. 15B is a schematic plan view of the high frequency module 151 according to Modification Example 7. FIG. 15C is a cross-sectional view of the high frequency module 151 according to Modification Example 7. FIG. 15B illustrates the disposition of the circuit components in a case where the main surface 90a of the mounting substrate 90 (described in FIG. 15C) is viewed from the z-axis positive direction side. In addition, FIG. 15C illustrates a cross-sectional view taken along the line XVC-XVC in FIG. 15B. In FIG. 15B, the mounting substrate 90 is omitted, circuit components disposed on the main surface 90a side are illustrated by a solid line, and circuit components disposed on the main surface 90b side are illustrated by a broken line.

As illustrated in FIG. 15C, the high frequency module 151 is further provided with the mounting substrate 90 in addition to the circuit components illustrated in FIG. 15A.

The mounting substrate 90 has main surfaces 90a (first main surface) and 90b (second main surface) facing each other. As the mounting substrate 90, for example, an LTCC substrate or an HTCC substrate having a multilayer structure of a plurality of dielectric layers, a component-incorporated substrate, a substrate having an RDL, a printed board, or the like can be used, and the present disclosure is not limited thereto.

As illustrated in FIGS. 15B and 15C, the filter integrated component 181 and the inductor 41 are disposed on the main surface 90a, and the integrated circuit 182 is disposed on the main surface 90b. More specifically, as illustrated in FIG. 15C, the filter integrated component 181 has a main surface 181a (fourth main surface) and a main surface 181b (third main surface), and is disposed on the mounting substrate 90 such that the main surface 181b faces the main surface 90a. In addition, the integrated circuit 182 has a main surface 182a (fifth main surface) and a main surface 182b (sixth main surface), and is disposed on the mounting substrate 90 such that the main surface 182a faces the main surface 90b.

As illustrated in FIG. 15B, in the high frequency module 151, in a case where the mounting substrate 90 is viewed in a plan view, the filter integrated component 181 and the integrated circuit 182 at least partially overlap with each other. Accordingly, since the acoustic wave filters 3A and 503A and the low noise amplifiers 2A and 502A are distributed and disposed on the main surfaces 90a and 90b of the mounting substrate 90, and the filter integrated component 181 and the integrated circuit 182 are disposed to overlap with each other, the high frequency module 151 can be reduced in size.

In addition, the main surface 181b includes an outer peripheral region Rp1 (first outer peripheral region) and a central region Rc1 (first central region) located inside the outer peripheral region Rp1. The input/output terminal 123 is disposed in the central region Rc1, and the input/output terminal 523 is disposed in the outer peripheral region Rp1.

Accordingly, since the filter integrated component 181 and the integrated circuit 182 overlap with each other in the plan view, and the input/output terminal 123 is disposed in the central region Rc1, the wiring connecting the acoustic wave filter 3A and the low noise amplifier 2A can be shortened. Therefore, since the transmission loss and the stray capacitance of the above-described wiring can be reduced, the noise figure of the low noise amplifier 2A can be improved.

In addition, the input/output terminal 123 and the input terminal 133 may overlap with each other in the plan view. Accordingly, the wiring connecting the acoustic wave filter 3A and the low noise amplifier 2A can be made as short as possible.

In addition, the main surface 182a includes an outer peripheral region Rp2 (second outer peripheral region) and a central region Rc2 (second central region) located inside the outer peripheral region Rp2. The input terminal 133 may be disposed in the central region Rc2, and the input terminal 533 may be disposed in the outer peripheral region Rp2.

Accordingly, since the filter integrated component 181 and the integrated circuit 182 overlap with each other in the plan view, and the input terminal 133 is disposed in the central region Rc2, the wiring connecting the acoustic wave filter 3A and the low noise amplifier 2A can be shortened.

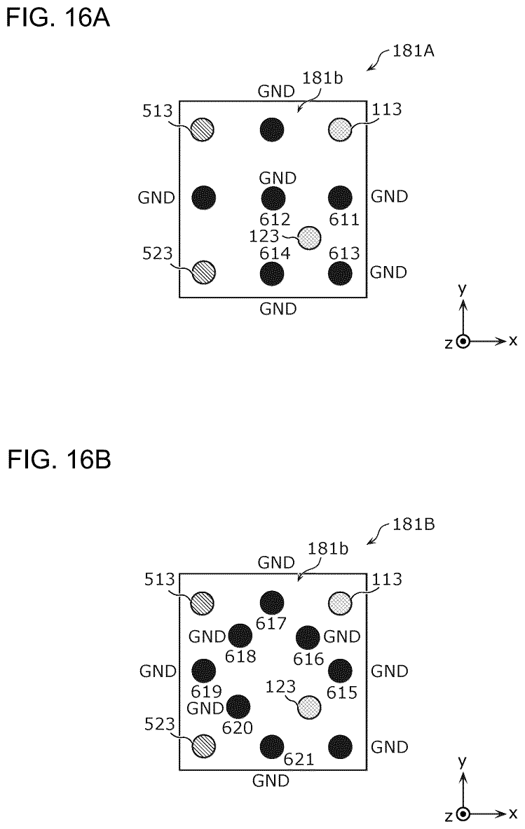

FIG. 16A is a plan view of a filter integrated component 181A according to Modification Example 8. The high frequency module according to Modification Example 8 is different from the high frequency module 151 according to Modification Example 7 only in the terminal disposition of the filter integrated component 181A. Therefore, the high frequency module according to the present modification example will be described with a focus on the terminal disposition of the filter integrated component 181A.

As illustrated in FIG. 16A, in a case where the main surface 181b is viewed in a plan view, the input/output terminal 123 is surrounded by four ground terminals 611, 612, 613, and 614. Accordingly, isolation between the input/output of the acoustic wave filter 3A can be improved.

FIG. 16B is a plan view of a filter integrated component 181B according to Modification Example 9. The high frequency module according to Modification Example 9 is different from the high frequency module 151 according to Modification Example 7 only in the terminal disposition of the filter integrated component 181B. Therefore, the high frequency module according to the present modification example will be described with a focus on the terminal disposition of the filter integrated component 181B.

As illustrated in FIG. 16B, in a case where the main surface 181b is viewed in a plan view, a ground terminal is disposed between the input/output terminal 123 and the other signal terminals. Specifically, ground terminals 615 and 616 are disposed between the input/output terminal 123 and the input/output terminal 113. In addition, ground terminals 617 and 618 are disposed between the input/output terminal 123 and the input/output terminal 513. In addition, ground terminals 619, 620, and 621 are disposed between the input/output terminal 123 and the input/output terminal 523. Accordingly, isolation between the input/output of the acoustic wave filter 3A and isolation between the acoustic wave filter 3A and the acoustic wave filter 503A can be improved.

### 12 Component Disposition of High Frequency Module 152 According to Modification Example 10

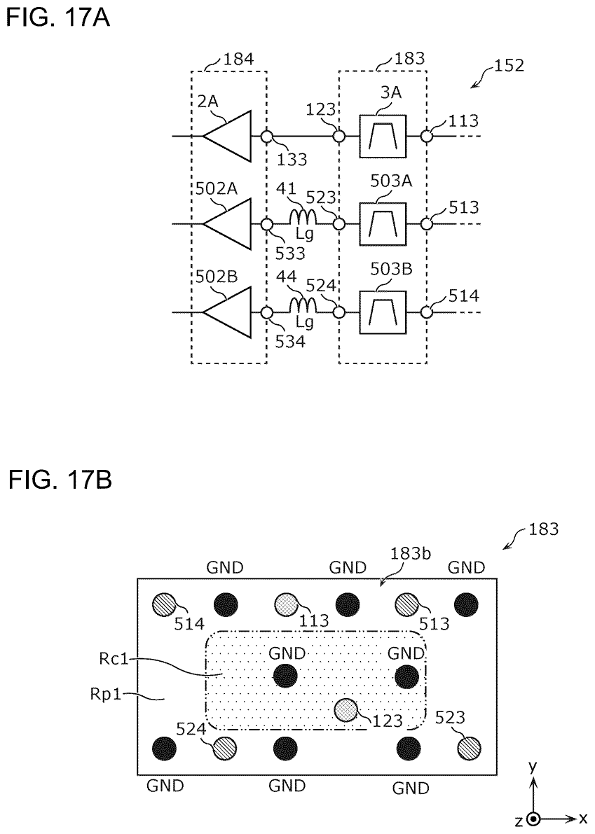

FIG. 17A is a circuit configuration diagram of a high frequency module 152 according to Modification Example 10. As illustrated in the figure, the high frequency module 152 according to the present modification example is provided with the acoustic wave filters 3A, 503A, and 503B, the low noise amplifiers 2A, 502A, and 502B, and the inductors 41 and 44. The high frequency module 152 according to the present modification example is different from the high frequency module 151 according to Modification Example 7 in that the acoustic wave filter 503B, the low noise amplifier 502B, and the inductor 44 are added as the circuit configuration. Therefore, in the following, the circuit configuration of the high frequency module 152 will be described with a focus on the circuit configuration of the acoustic wave filter 503B, the low noise amplifier 502B, and the inductor 44.

The acoustic wave filter 503B is an example of a second acoustic wave filter, and has, for example, the same circuit configuration and the same resonance characteristics of the acoustic wave resonator as those of the acoustic wave filter 501 according to the comparative example. The acoustic wave filter 503B includes input/output terminals 514 and 524.

The low noise amplifier 502B is an example of a second low noise amplifier, and has the same circuit configuration and the same amplification characteristics as the low noise amplifier 2 according to the embodiment. The low noise amplifier 502B includes an input terminal 534. The input terminal 534 is connected to the input/output terminal 524 with the inductor 44 interposed therebetween.

The inductor 44 is an example of a third inductor, and is disposed between the low noise amplifier 502B having a capacitive input impedance and the acoustic wave filter 503B.

The acoustic wave filters 3A, 503A, and 503B are included in the filter integrated component 183. The filter integrated component 183 is an example of a first integrated component, and has, for example, a configuration in which the acoustic wave resonators of the acoustic wave filters 3A, 503A, and 503B are disposed on a common piezoelectric substrate.

The low noise amplifiers 2A, 502A, and 502B are included in the integrated circuit 184. The integrated circuit 184 is an example of a second integrated component, and may be configured by using, for example, a CMOS, and specifically, may be manufactured by an SOI process. The integrated circuit 184 is not limited to the CMOS.

Next, the component disposition of the high frequency module 152 according to the present modification example will be described. FIG. 17B is a plan view of a filter integrated component 183 according to Modification Example 10. FIG. 17B illustrates a terminal disposition in a case where the main surface 183b of the filter integrated component 183 is viewed from the z-axis positive direction side.

The high frequency module 152 is further provided with the mounting substrate 90 in addition to the circuit components illustrated in FIG. 17A.

The filter integrated component 183 and the inductors 41 and 44 are disposed on the main surface 90a, and the integrated circuit 184 is disposed on the main surface 90b. More specifically, the filter integrated component 183 has a main surface 183a (fourth main surface) and a main surface 183b (third main surface), and is disposed on the mounting substrate 90 such that the main surface 183b faces the main surface 90a.

In the high frequency module 152, in a case where the mounting substrate 90 is viewed in a plan view, the filter integrated component 183 and the integrated circuit 184 at least partially overlap with each other. Accordingly, since the acoustic wave filters 3A, 503A, and 503B and the low noise amplifiers 2A, 502A, and 502B are distributed and disposed on the main surfaces 90a and 90b of the mounting substrate 90, and the filter integrated component 183 and the integrated circuit 184 are disposed to overlap with each other, the high frequency module 152 can be reduced in size.

In addition, as illustrated in FIG. 17B, the main surface 183b includes an outer peripheral region Rp1 (first outer peripheral region) and a central region Rc1 (first central region) located inside the outer peripheral region Rp1. The input/output terminal 123 is disposed in the central region Rc1, and the input/output terminals 523 and 524 are disposed in the outer peripheral region Rp1. In addition, the input/output terminals 113, 513, and 514 are disposed in the outer peripheral region Rp1.

Accordingly, since the filter integrated component 183 and the integrated circuit 184 overlap with each other in the plan view, and the input/output terminal 123 is disposed in the central region Rc1, the wiring connecting the acoustic wave filter 3A and the low noise amplifier 2A can be shortened. Therefore, since the transmission loss and the stray capacitance of the above-described wiring can be reduced, the noise figure of the low noise amplifier 2A can be improved. In addition, isolation between the input/output of the acoustic wave filter 3A and isolation between the acoustic wave filter 3A and the acoustic wave filters 503A and 503B can be improved.

### 13 Component Disposition of Filter Integrated Component 181C According to Modification Example 11

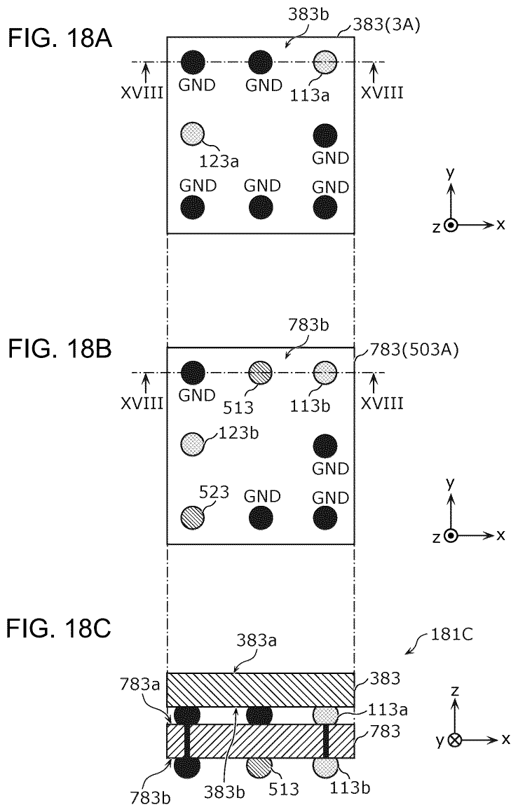

FIGS. 18A-18C include a plan view and a cross-sectional view of a filter integrated component 181C according to Modification Example 11. FIG. 18A illustrates a terminal disposition in a case where the main surface 383b of the filter chip 383 (acoustic wave filter 3A) is viewed from the z-axis positive direction side, and FIG. 18B illustrates a terminal disposition in a case where the main surface 783b of the filter chip 783 (acoustic wave filter 503A) is viewed from the z-axis positive direction side. In addition, FIG. 18C illustrates a cross-sectional view taken along the line XVIII-XVIII of FIGS. 18A and 18C.

The high frequency module according to Modification Example 11 is different from the high frequency module 151 according to Modification Example 7 only in the configuration of the filter integrated component 181C. Therefore, the high frequency module according to the present modification example will be described with a focus on the configuration of the filter integrated component 181C.

The filter integrated component 181C is an example of a first integrated component, and has a third main surface and a fourth main surface. The filter integrated component 181C is disposed on the mounting substrate 90 such that the third main surface faces the main surface 90a. The filter integrated component 181C includes filter chips 383 and 783. The filter chip 383 is an example of a first filter chip, has a main surface 383a (fourth main surface) and a main surface 383b, and includes the acoustic wave filter 3A. The filter chip 783 is an example of a second filter chip, has a main surface 783a and a main surface 783b (third main surface), and includes the acoustic wave filter 503A.

As illustrated in FIG. 18C, the filter chip 383 and the filter chip 783 are stacked. More specifically, the filter chips 383 and 783 are disposed on the mounting substrate 90 such that the main surface 90a and the main surface 783b face each other and the main surface 783a and the main surface 383b face each other.

The input/output terminal 123 of the acoustic wave filter 3A is configured with a terminal 123a of the filter chip 383, a terminal 123b of the filter chip 783, and a via conductor connecting the terminals 123a and 123b.

Accordingly, since the acoustic wave filters 3A and 503A are accommodated in the filter integrated component 181C having the multilayer structure, the high frequency module according to the present modification example can be reduced in size.

In addition, the filter integrated component 181C and the integrated circuit 182 overlap with each other in the plan view, and the wiring connecting the input/output terminal 123 of the acoustic wave filter 3A and the input terminal 133 of the low noise amplifier 2A can be shortened. Therefore, since the transmission loss and the stray capacitance of the above-described wiring can be reduced, the noise figure of the low noise amplifier 2A can be improved.

### 14 Component Disposition of High Frequency Module 153 According to Modification Example 12

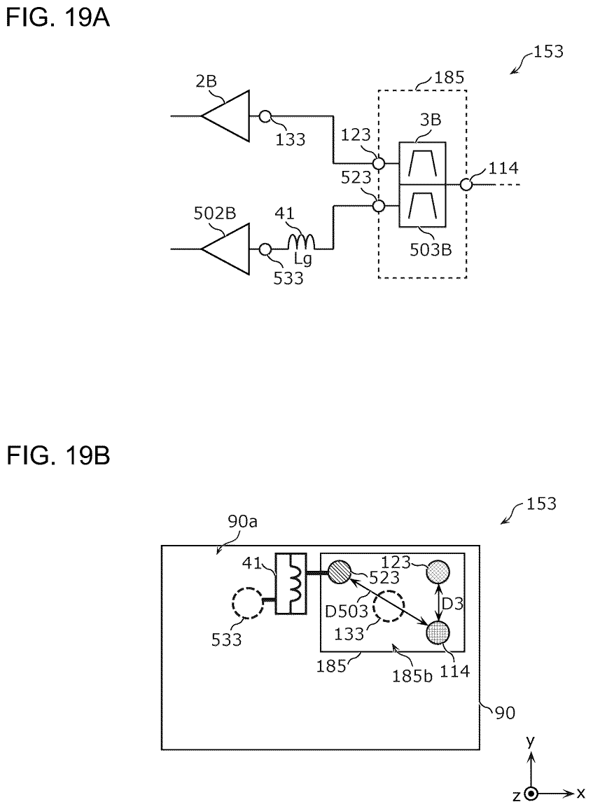

FIG. 19A is a circuit configuration diagram of a high frequency module 153 according to Modification Example 12. As illustrated in the figure, the high frequency module 153 according to the present modification example is provided with the acoustic wave filters 3B and 503B, the low noise amplifiers 2B and 502B, and the inductor 41.

The acoustic wave filter 3B is an example of a first acoustic wave filter, and has, for example, the same circuit configuration and the same resonance characteristics of the acoustic wave resonator as those of any of the acoustic wave filter 1 according to the embodiment, the acoustic wave filter 1A according to Modification Example 1, and the acoustic wave filter 1B according to Modification Example 2. The acoustic wave filter 3B includes a common terminal 114 (first common terminal) and an input/output terminal 123 (first input/output terminal). For example, the acoustic wave filter 3B has a pass band including at least a part of a band A.

The acoustic wave filter 503B is an example of a second acoustic wave filter, and has, for example, the same circuit configuration and the same resonance characteristics of the acoustic wave resonator as those of the acoustic wave filter 501 according to the comparative example. The acoustic wave filter 503B includes a common terminal 114 (first common terminal) and an input/output terminal 523 (third input/output terminal). For example, the acoustic wave filter 503B has a pass band including at least a part of a band B.

The acoustic wave filters 3B and 503B constitute a multiplexer in which the second input/output terminal and the fourth input/output terminal are shared as the common terminal 114.

The low noise amplifier 2B is an example of a first low noise amplifier, and has the same circuit configuration and the same amplification characteristics as the low noise amplifier 2 according to the embodiment. The low noise amplifier 2B includes an input terminal 133. The input terminal 133 is an example of a first input terminal and is connected to the input/output terminal 123 without necessarily passing through an inductor. The low noise amplifier 502B is an example of a second low noise amplifier, and has the same circuit configuration and the same amplification characteristics as the low noise amplifier 2 according to the embodiment. The low noise amplifier 502B includes an input terminal 533. The input terminal 533 is an example of a second input terminal and is connected to the input/output terminal 523 with the inductor 41 interposed therebetween.

The inductor 41 is an example of a third inductor, and is disposed between the low noise amplifier 502B having a capacitive input impedance and the acoustic wave filter 503B.

According to the above configuration, the high frequency module 153 can simultaneously transmit the signal of the band A and the signal of the band B.

In the present modification example, the band A is, for example, a band 25 for LTE or n25 for 5GNR, and the band B is, for example, a band 66 for LTE or n66 for 5GNR.

In a case where the high frequency module 153 simultaneously transmits the signal of the band A and the signal of the band B, since the inductor is not disposed between the acoustic wave filter 3B and the low noise amplifier 2B, it is possible to reduce the deterioration of isolation caused by interference between the signal of band A and the signal of the band B between a path connecting the acoustic wave filter 3B and the low noise amplifier 2B and a path connecting the acoustic wave filter 503B and the low noise amplifier 502B.

The acoustic wave filters 3B and 503B are included in the filter integrated component 185. The filter integrated component 185 is an example of a first integrated component, and has, for example, a configuration in which the acoustic wave resonators of the acoustic wave filters 3B and 503B are disposed on a common piezoelectric substrate.

Next, the component disposition of the high frequency module 153 according to the present modification example will be described. FIG. 19B is a plan view of the high frequency module 153 according to Modification Example 12. FIG. 19B illustrates the disposition of the circuit components in a case where the main surface 90a of the mounting substrate 90 is viewed from the z-axis positive direction side. In FIG. 19B, circuit components disposed on the main surface 90a side are illustrated by solid lines, and terminals disposed on the main surface 90b side are illustrated by broken lines.

As illustrated in FIG. 19B, the high frequency module 153 is further provided with the mounting substrate 90 in addition to the circuit components illustrated in FIG. 19A. The mounting substrate 90 has main surfaces 90a (first main surface) and 90b (second main surface) facing each other.

As illustrated in FIG. 19B, the filter integrated component 185 and the inductor 41 are disposed on the main surface 90a, and the input terminal 133 of the low noise amplifier 2B and the input terminal 533 of the low noise amplifier 502B are disposed on the main surface 90b. Although not illustrated in FIG. 19B, the low noise amplifier 2B and the low noise amplifier 502B are disposed on the main surface 90b. More specifically, the filter integrated component 185 has a main surface 185a (fourth main surface) and a main surface 185b (third main surface), and is disposed on the mounting substrate 90 such that the main surface 185b faces the main surface 90a. The input/output terminals 123 and 523 and the common terminal 114 are disposed on the main surface 185b.

Here, as illustrated in FIG. 19B, the distance D3 between the input/output terminal 123 and the common terminal 114 is smaller than the distance D503 between the input/output terminal 523 and the common terminal 114.

Accordingly, since the distance between the input/output terminal 523 to which the inductor 41 is connected and the common terminal 114 can be ensured, it is possible to reduce the interference between the signals input to the acoustic wave filters 3B and 503B and the signal output from the acoustic wave filter 503B. Therefore, the deterioration of isolation between the input/output of the multiplexer configured with the acoustic wave filters 3B and 503B can be reduced.

### 15 Component Disposition of High Frequency Module 154 According to Modification Example 13

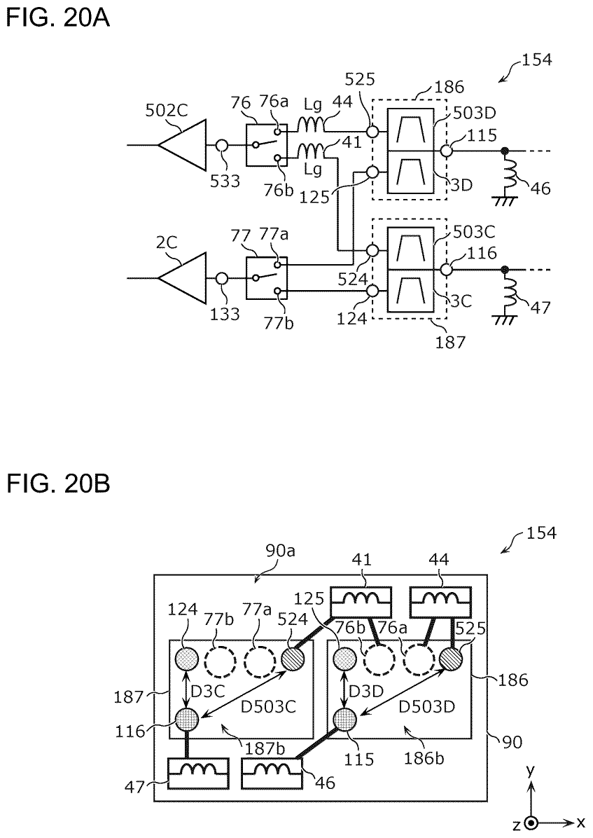

FIG. 20A is a circuit configuration diagram of a 13. As illustrated in the figure, the high frequency module 154 according to the present modification example is provided with acoustic wave filters 3C, 3D, 503C, and 503D, low noise amplifiers 2C and 502C, inductors 41, 44, 46, and 47, and switches 76 and 77.

Each of the acoustic wave filters 3C and 3D is an example of a first acoustic wave filter and has, for example, the same circuit configuration and the same resonance characteristics of the acoustic wave resonator as those of any of the acoustic wave filter 1 according to the embodiment, the acoustic wave filter 1A according to Modification Example 1, or the acoustic wave filter 1B according to Modification Example 2.

The acoustic wave filter 3C includes a common terminal 116 (first common terminal) and an input/output terminal 124 (first input/output terminal). For example, the acoustic wave filter 3C has a pass band including at least a part of a band A. The acoustic wave filter 3D includes a common terminal 115 and an input/output terminal 125. For example, the acoustic wave filter 3D has a pass band including at least a part of a band C.

Each of the acoustic wave filters 503C and 503D is an example of a second acoustic wave filter, and has, for example, the same circuit configuration and the same resonance characteristics of the acoustic wave resonator as that of the acoustic wave filter 501 according to the comparative example.

The acoustic wave filter 503C includes a common terminal 116 (first common terminal) and an input/output terminal 524 (third input/output terminal). For example, the acoustic wave filter 503C has a pass band including at least a part of a band B. The acoustic wave filter 503D includes a common terminal 115 and an input/output terminal 525. For example, the acoustic wave filter 503D has a pass band including at least a part of a band D.

The acoustic wave filters 3C and 503C constitute a multiplexer in which the second input/output terminal and the fourth input/output terminal are shared as the common terminal 116. The acoustic wave filters 3D and 503D constitute a multiplexer having a common terminal 115.

The low noise amplifier 2C is an example of a first low noise amplifier, and has the same circuit configuration and the same amplification characteristics as the low noise amplifier 2 according to the embodiment. The low noise amplifier 2C includes an input terminal 133. The input terminal 133 is an example of a first input terminal, and is connected to the input/output terminals 124 and 125 without necessarily passing through an inductor. The low noise amplifier 502C is an example of a second low noise amplifier, and has the same circuit configuration and the same amplification characteristics as the low noise amplifier 2 according to the embodiment. The low noise amplifier 502C includes an input terminal 533. The input terminal 533 is an example of a second input terminal, is connected to the input/output terminal 524 with the inductor 41 interposed therebetween, and is connected to the input/output terminal 525 with the inductor 44 interposed therebetween.

The inductor 41 is an example of a third inductor, and is disposed between the low noise amplifier 502C having a capacitive input impedance and the acoustic wave filter 503C. The inductor 44 is disposed between the low noise amplifier 502C having a capacitive input impedance and the acoustic wave filter 503D.

The inductor 46 is connected to the common terminal 115 and performs impedance matching between the acoustic wave filters 3D and 503D and an external circuit connected to the common terminal 115. The inductor 47 is connected to the common terminal 116 and performs impedance matching between the acoustic wave filters 3C and 503C and an external circuit connected to the common terminal 116.

The switch 76 includes a common terminal, and selection terminals 76a and 76b, and switches the connection between the common terminal and the selection terminal 76a and a connection between the common terminal and the selection terminal 76b. The common terminal is connected to the input terminal 533, the selection terminal 76a is connected to the acoustic wave filter 503D with the inductor 44 interposed therebetween, and the selection terminal 76b is connected to the acoustic wave filter 503C with the inductor 41 interposed therebetween.

The switch 77 includes a common terminal, and selection terminals 77a and 77b, and switches the connection between the common terminal and the selection terminal 77a and a connection between the common terminal and the selection terminal 77b. The common terminal is connected to the input terminal 133, the selection terminal 77a is connected to the acoustic wave filter 3D without necessarily passing through an inductor, and the selection terminal 77b is connected to the acoustic wave filter 3C without necessarily passing through an inductor.

According to the above configuration, the high frequency module 154 can switch and execute (1) simultaneous transmission of the signal of the band A and the signal of the band B and (2) simultaneous transmission of the signal of the band C and the signal of the band D.

In the present modification example, the band A is, for example, a band 25 for LTE or n25 for 5GNR, the band B is, for example, a band 66 for LTE or n66 for 5GNR, the band C is, for example, a band 3 for LTE or n3 for 5GNR, and the band D is, for example, a band 1 for LTE or n1 for 5GNR.

In a case where the high frequency module 154 simultaneously transmits the signal of the band A and the signal of the band B, since the inductor is not disposed between the acoustic wave filter 3C and the low noise amplifier 2C, it is possible to reduce the deterioration of isolation due to interference between the signal of band A and the signal of the band B between a path connecting the acoustic wave filter 3C and the low noise amplifier 2C and a path connecting the acoustic wave filter 503C and the low noise amplifier 502C. In addition, in a case where the high frequency module 154 simultaneously transmits the signal of the band C and the signal of the band D, since the inductor is not disposed between the acoustic wave filter 3D and the low noise amplifier 2C, it is possible to reduce the deterioration of isolation due to interference between the signal of band C and the signal of the band D between a path connecting the acoustic wave filter 3D and the low noise amplifier 2C and a path connecting the acoustic wave filter 503D and the low noise amplifier 502C.

Here, the band B is located on the high frequency side of the band A, and the band D is located on the high frequency side of the band C. From the viewpoint of impedance matching between the low noise amplifier and the acoustic wave filter, as the corresponding frequency of the transmission path is lower, it is suitable to increase the inductance value of the inductor disposed in the transmission path, and the resistance component of the inductor is increased. From this viewpoint, in the high frequency module 154 according to the present modification example, the inductor is not disposed in the transmission path (band A and band C) having a lower corresponding frequency of the two transmission paths for simultaneous transmission, and each of the inductors 41 and 44 is disposed in the transmission path (band B and band D) having a high corresponding frequency.

Accordingly, since the transmission loss of the wiring connecting the acoustic wave filter and the low noise amplifier can be reduced, the noise figure of the low noise amplifier 2C can be improved.

In addition, the bands A, B, C, and D may be located in the order of the band B, the band A (or the band C), the band C (or the band A), and the band D from the low frequency side or the high frequency side. As the frequency difference increases, the difference in the inductance value of the inductor disposed between the acoustic wave filter and the low noise amplifier increases, and the degree of magnetic coupling decreases. Accordingly, since the band B and the band D are not simultaneously transmitted and the frequency difference is maximum, the deterioration of isolation between different paths can be reduced.

In this case, the band A is, for example, a band 25 for LTE or n25 for 5GNR, the band B is, for example, a band 66 for LTE or n66 for 5GNR, the band C is, for example, a band 1 for LTE or n1 for 5GNR, and the band D is, for example, a band 3 for LTE or n3 for 5GNR. In addition, the acoustic wave filters 3D and 503C may be connected to the low noise amplifier 502C, and the acoustic wave filters 3C and 503D may be connected to the low noise amplifier 2C.

The acoustic wave filters 3C and 503C are included in the filter integrated component 187. The filter integrated component 187 is an example of a first integrated component, and has, for example, a configuration in which the acoustic wave resonators of the acoustic wave filters 3C and 503C are disposed on a common piezoelectric substrate. The acoustic wave filters 3D and 503D are included in the filter integrated component 186. The filter integrated component 186 is an example of a first integrated component, and has, for example, a configuration in which the acoustic wave resonators of the acoustic wave filters 3D and 503D are disposed on a common piezoelectric substrate.

Next, the component disposition of the high frequency module 154 according to the present modification example will be described. FIG. 20B is a plan view of the 13. FIG. 20B illustrates the disposition of the circuit components in a case where the main surface 90a of the mounting substrate 90 is viewed from the z-axis positive direction side. In FIG. 20B, circuit components disposed on the main surface 90a side are illustrated by solid lines, and terminals disposed on the main surface 90b side are illustrated by broken lines.

As illustrated in FIG. 20B, the high frequency module 154 is further provided with the mounting substrate 90 in addition to the circuit components illustrated in FIG. 20A. The mounting substrate 90 has main surfaces 90a (first main surface) and 90b (second main surface) facing each other.

As illustrated in FIG. 20B, the filter integrated components 186 and 187, and the inductors 41, 44, 46, and 47 are disposed on the main surface 90a, and the selection terminals 76a and 76b of the switch 76 and the selection terminals 77a and 77b of the switch 77 are disposed on the main surface 90b. Although not illustrated in FIG. 20B, the low noise amplifier 2C and the low noise amplifier 502C are disposed on the main surface 90b. More specifically, the filter integrated component 186 has a main surface 186a and a main surface 186b, and is disposed on the mounting substrate 90 such that the main surface 186b faces the main surface 90a. The input/output terminals 125 and 525 and the common terminal 115 are disposed on the main surface 186b. In addition, the filter integrated component 187 has a main surface 187a and a main surface 187b, and is disposed on the mounting substrate 90 such that the main surface 187b faces the main surface 90a. The input/output terminals 124 and 524 and the common terminal 116 are disposed on the main surface 187b.

Here, as illustrated in FIG. 20B, the distance D3D between the input/output terminal 125 and the common terminal 115 is smaller than the distance D503D between the input/output terminal 525 and the common terminal 115. In addition, the distance D3C between the input/output terminal 124 and the common terminal 116 is smaller than the distance D503C between the input/output terminal 524 and the common terminal 116.

Accordingly, since the distance between the input/output terminal 524 to which the inductor 41 is connected and the common terminal 116 can be ensured, it is possible to reduce the interference between the signals input to the acoustic wave filters 3D and 503D and the signal output from the acoustic wave filter 503D. Therefore, the deterioration of isolation between the input/output of the multiplexer configured with the acoustic wave filters 3D and 503D can be reduced. In addition, since the distance between the input/output terminal 525 to which the inductor 44 is connected and the common terminal 115 can be ensured, it is possible to reduce the interference between the signals input to the acoustic wave filters 3C and 503C and the signal output from the acoustic wave filter 503C. Therefore, the deterioration of isolation between the input/output of the multiplexer configured with the acoustic wave filters 3C and 503C can be reduced.

In addition, the inductors 41 and 44 are disposed to face the input/output terminals 125 and 525 of the filter integrated component 186, and the inductors 46 and 47 are disposed to face the common terminal 116 of the filter integrated component 187. Accordingly, since the distance between the inductor 47 connected to the input side of the acoustic wave filters 3C and 503C and the inductor 41 connected to the output side can be ensured, the magnetic field coupling between the inductors disposed at the input/output terminals of the acoustic wave filters 3C and 503C can be reduced. In addition, since the distance between the inductor 46 connected to the input side of the acoustic wave filters 3D and 503D and the inductor 44 connected to the output side can be ensured, the magnetic field coupling between the inductors disposed at the input/output terminals of the acoustic wave filters 3D and 503D can be reduced. Therefore, the deterioration of the isolation between the input/output of the acoustic wave filter can be reduced.

### 16 Component Disposition of High Frequency Module 155 According to Modification Example 14

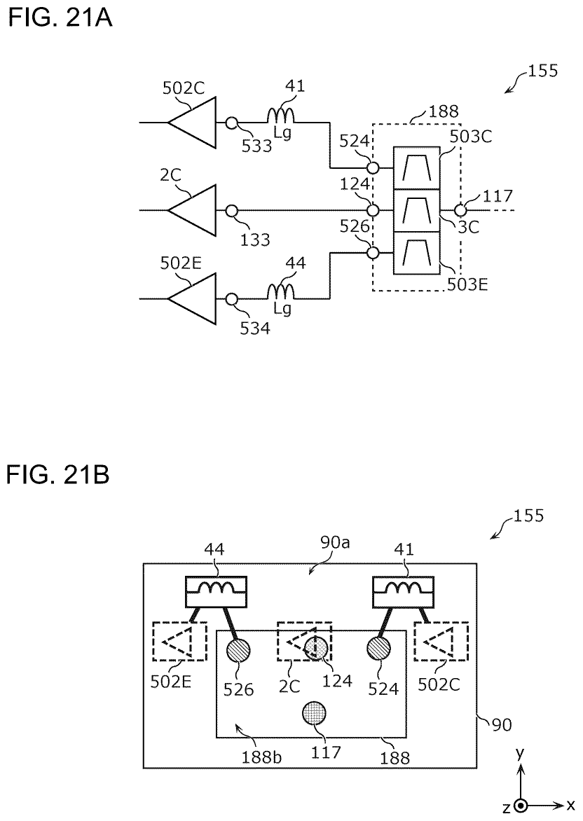

FIG. 21A is a circuit configuration diagram of a high frequency module 155 according to Modification Example 14. As illustrated in the figure, the high frequency module 155 according to the present modification example is provided with the acoustic wave filters 3C, 503C, and 503E, the low noise amplifiers 20, 502C, and 502E, and the inductors 41 and 44.

The acoustic wave filter 3C is an example of a first acoustic wave filter, and has, for example, the same circuit configuration and the same resonance characteristics of the acoustic wave resonator as those of any of the acoustic wave filter 1 according to the embodiment, the acoustic wave filter 1A according to Modification Example 1, or the acoustic wave filter 1B according to Modification Example 2. The acoustic wave filter 3C includes a common terminal 117 (first common terminal) and an input/output terminal 124 (first input/output terminal). For example, the acoustic wave filter 3C has a pass band including at least a part of a band A.

Each of the acoustic wave filters 503C and 503E is an example of a second acoustic wave filter, and has, for example, the same circuit configuration and the same resonance characteristics of the acoustic wave resonator as that of the acoustic wave filter 501 according to the comparative example. The acoustic wave filter 503C includes a common terminal 117 (first common terminal) and an input/output terminal 524 (third input/output terminal). For example, the acoustic wave filter 503C has a pass band including at least a part of a band B. The acoustic wave filter 503E includes a common terminal 117 and an input/output terminal 526. For example, the acoustic wave filter 503E has a pass band including at least a part of a band C.

The acoustic wave filters 3C, 503C, and 503E constitute a multiplexer connected to the common terminal 117 in common.

The low noise amplifier 2C is an example of a first low noise amplifier, and has the same circuit configuration and the same amplification characteristics as the low noise amplifier 2 according to the embodiment. The low noise amplifier 2C includes an input terminal 133. The input terminal 133 is an example of a first input terminal and is connected to the input/output terminal 124 without necessarily passing through an inductor. The low noise amplifier 502C is an example of a second low noise amplifier, and has the same circuit configuration and the same amplification characteristics as the low noise amplifier 2 according to the embodiment. The low noise amplifier 502C includes an input terminal 533. The input terminal 533 is an example of a second input terminal and is connected to the input/output terminal 524 with the inductor 41 interposed therebetween. The low noise amplifier 502E is an example of a second low noise amplifier, and has the same circuit configuration and the same amplification characteristics as the low noise amplifier 2 according to the embodiment. The low noise amplifier 502E includes an input terminal 534. The input terminal 534 is an example of a second input terminal and is connected to the input/output terminal 526 with the inductor 44 interposed therebetween.

The inductor 41 is an example of a third inductor, and is disposed between the low noise amplifier 502C having a capacitive input impedance and the acoustic wave filter 503C. The inductor 44 is an example of a third inductor, and is disposed between the low noise amplifier 502E having a capacitive input impedance and the acoustic wave filter 503E.

According to the above configuration, the high frequency module 155 can execute (1) simultaneous transmission of the signal of the band A, the signal of the band B, and the signal of the band C.

In the present modification example, the band A is, for example, a band 25 for LTE or n25 for 5GNR, the band B is, for example, a band 66 for LTE or n66 for 5GNR, and the band C is, for example, a band 30 for LTE or n30 for 5GNR.

The acoustic wave filters 3C, 503C, and 503E are included in the filter integrated component 188. The filter integrated component 188 is an example of a first integrated component, and has, for example, a configuration in which the acoustic wave resonators of the acoustic wave filters 3C, 503C, and 503E are disposed on a common piezoelectric substrate.

Next, the component disposition of the high frequency module 155 according to the present modification example will be described. FIG. 21B is a plan view of the high frequency module 155 according to Modification Example 14. FIG. 21B illustrates the disposition of the circuit components in a case where the main surface 90a of the mounting substrate 90 is viewed from the z-axis positive direction side. In FIG. 21B, circuit components disposed on the main surface 90a side are illustrated by solid lines, and circuit components disposed on the main surface 90b side are illustrated by broken lines.

As illustrated in FIG. 21B, the high frequency module 155 is further provided with the mounting substrate 90 in addition to the circuit components illustrated in FIG. 21A. The mounting substrate 90 has main surfaces 90a (first main surface) and 90b (second main surface) facing each other.

As illustrated in FIG. 21B, the filter integrated component 188, the inductors 41 and 44 are disposed on the main surface 90a, and the low noise amplifiers 2C, 502C, and 502E are disposed on the main surface 90b. More specifically, the filter integrated component 188 has a main surface 188a and a main surface 188b, and is disposed on the mounting substrate 90 such that the main surface 188b faces the main surface 90a. The input/output terminals 124, 524, and 526 and the common terminal 117 are disposed on the main surface 188b.

Here, as illustrated in FIG. 21B, in a case where the mounting substrate 90 is viewed in a plan view, the input/output terminal 124 and the low noise amplifier 2C overlap with each other, the input/output terminal 524 and the low noise amplifier 502C do not overlap with each other, and the input/output terminal 526 and the low noise amplifier 502E do not overlap with each other.

Accordingly, the wiring connecting the acoustic wave filter 3C and the low noise amplifier 2C connected without necessarily passing through the inductor can be shortened. Therefore, since the transmission loss and the stray capacitance of the wiring can be reduced, the noise figure of the low noise amplifier 2C can be improved.

### 17 Component Disposition of High Frequency Module 156 According to Modification Example 15

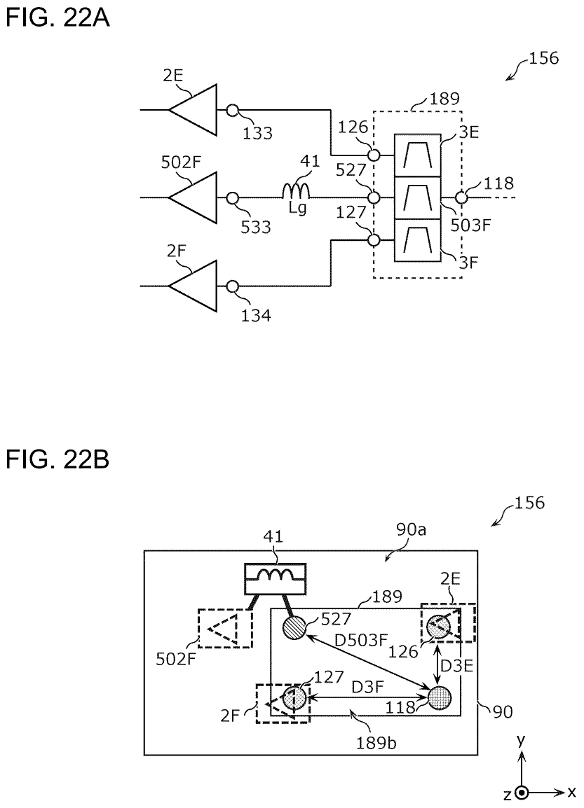

FIG. 22A is a circuit configuration diagram of a high frequency module 156 according to Modification Example 15. As illustrated in the figure, the high frequency module 156 according to the present modification example is provided with acoustic wave filters 3E, 3F, and 503F, low noise amplifiers 2E, 2F, and 502F, and the inductor 41.

Each of the acoustic wave filters 3E and 3F is an example of a first acoustic wave filter, and has, for example, the same circuit configuration and the same resonance characteristics of the acoustic wave resonator as those of any of the acoustic wave filter 1 according to the embodiment, the acoustic wave filter 1A according to Modification Example 1, or the acoustic wave filter 1B according to Modification Example 2. The acoustic wave filter 3E includes a common terminal 118 (first common terminal) and an input/output terminal 126 (first input/output terminal). For example, the acoustic wave filter 3E has a pass band including at least a part of a band B. The acoustic wave filter 3F includes a common terminal 118 (first common terminal) and an input/output terminal 127. For example, the acoustic wave filter 3F has a pass band including at least a part of a band C.

The acoustic wave filter 503F is an example of a second acoustic wave filter, and has, for example, the same circuit configuration and the same resonance characteristics of the acoustic wave resonator as that of the acoustic wave filter 501 according to the comparative example. The acoustic wave filter 503F includes a common terminal 118 (first common terminal) and an input/output terminal 527 (third input/output terminal). For example, the acoustic wave filter 503F has a pass band including at least a part of a band A.

The acoustic wave filters 3E, 3F, and 503F constitute a multiplexer connected to the common terminal 118 in common.

Each of the low noise amplifiers 2E and 2F is an example of a first low noise amplifier, and has the same circuit configuration and the same amplification characteristics as the low noise amplifier 2 according to the embodiment. The low noise amplifier 2E includes an input terminal 133. The input terminal 133 is an example of a first input terminal and is connected to the input/output terminal 126 without necessarily passing through an inductor. The low noise amplifier 2F includes an input terminal 134. The input terminal 134 is connected to the input/output terminal 127 without necessarily passing through an inductor. The low noise amplifier 502F is an example of a second low noise amplifier, and has the same circuit configuration and the same amplification characteristics as the low noise amplifier 2 according to the embodiment. The low noise amplifier 502F includes an input terminal 533. The input terminal 533 is an example of a second input terminal and is connected to the input/output terminal 527 with the inductor 41 interposed therebetween.

The inductor 41 is an example of a third inductor, and is disposed between a low noise amplifier 502F having a capacitive input impedance and the acoustic wave filter 503F.

According to the above configuration, the high frequency module 156 can execute (1) simultaneous transmission of the signal of the band A, the signal of the band B, and the signal of the band C.

In the present modification example, the band A is, for example, a band 25 for LTE or n25 for 5GNR, the band B is, for example, a band 66 for LTE or n66 for 5GNR, and the band C is, for example, a band 30 for LTE or n30 for 5GNR.

The acoustic wave filters 3E, 3F, and 503F are included in the filter integrated component 189. The filter integrated component 189 is an example of a first integrated component, and has, for example, a configuration in which the acoustic wave resonators of the acoustic wave filters 3E, 3F, and 503F are disposed on a common piezoelectric substrate.

Next, the component disposition of the high frequency module 156 according to the present modification example will be described. FIG. 22B is a plan view of the high frequency module 156 according to Modification Example 15. FIG. 22B illustrates the disposition of the circuit components in a case where the main surface 90a of the mounting substrate 90 is viewed from the z-axis positive direction side. In FIG. 22B, circuit components disposed on the main surface 90a side are illustrated by solid lines, and circuit components disposed on the main surface 90b side are illustrated by broken lines.

As illustrated in FIG. 22B, the high frequency module 156 is further provided with the mounting substrate 90 in addition to the circuit components illustrated in FIG. 22A. The mounting substrate 90 has main surfaces 90a (first main surface) and 90b (second main surface) facing each other.

As illustrated in FIG. 22B, the filter integrated component 189 and the inductor 41 are disposed on the main surface 90a, and the low noise amplifiers 2E, 2F, and 502F are disposed on the main surface 90b. More specifically, the filter integrated component 189 has a main surface 189a and a main surface 189b, and is disposed on the mounting substrate 90 such that the main surface 189b faces the main surface 90a. The input/output terminals 126, 127, and 527 and the common terminal 118 are disposed on the main surface 189b.

Here, as illustrated in FIG. 22B, in a case where the mounting substrate 90 is viewed in a plan view, the input/output terminal 126 and the low noise amplifier 2E overlap with each other, the input/output terminal 127 and the low noise amplifier 2F overlap with each other, and the input/output terminal 527 and the low noise amplifier 502F do not overlap with each other.

Accordingly, the wiring connecting the acoustic wave filter 3E and the low noise amplifier 2E connected without necessarily passing through the inductor, and the wiring connecting the acoustic wave filter 3F and the low noise amplifier 2F connected without necessarily passing through the inductor can be shortened. Therefore, since the transmission loss and the stray capacitance of the wiring can be reduced, the noise figure of the low noise amplifiers 2E and 2F can be improved.

In addition, the main surface 189b of the filter integrated component 189 has a rectangular shape in a case where the main surface 189b is viewed in a plan view. Each of the input/output terminals 126, 127, and 527 and the common terminal 118 is disposed at a corner portion of the main surface 189b. Accordingly, it is possible to ensure isolation between the input terminal and the output terminal of each of the acoustic wave filters 3E, 3F, and 503F and to ensure isolation between the output terminal of the acoustic wave filter 3E, the output terminal of the acoustic wave filter 3F, and the output terminal of the acoustic wave filter 503F.

In addition, the distance D503F between the input/output terminal 527 and the common terminal 118 is the longest among the distance D3E between the input/output terminal 126 and the common terminal 118, the distance D3F between the input/output terminal 127 and the common terminal 118, and the distance D503F. Accordingly, since the input/output terminal 527 of the acoustic wave filter 503F in which the inductor 41 is disposed on the output side is disposed farthest from the common terminal 118 among the input/output terminals 126, 127, and 527, it is possible to reduce the deterioration of isolation due to magnetic field coupling between the inductor 41 and the common terminal 118.

### 18 Component Disposition of High Frequency Module 157 According to Modification Example 16

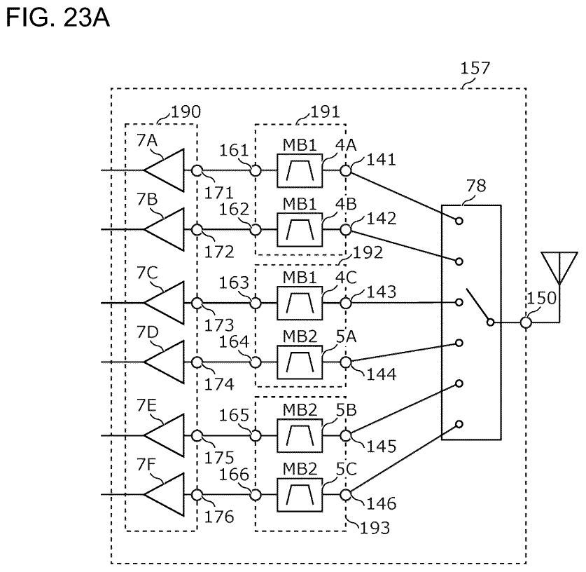

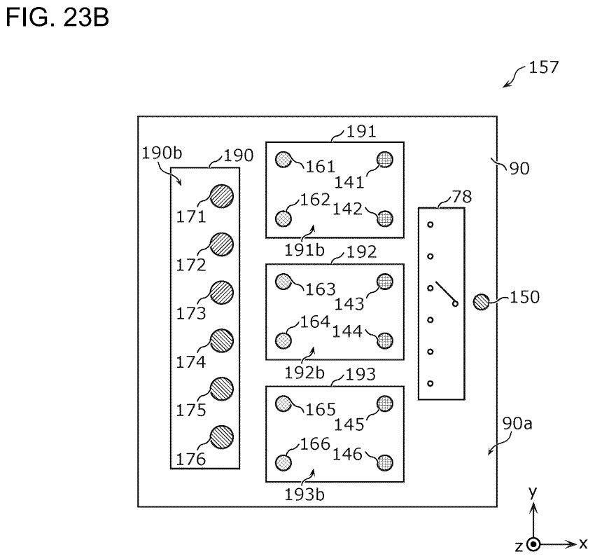

FIG. 23A is a circuit configuration diagram of a high frequency module 157 according to Modification Example 16. As illustrated in the figure, the high frequency module 157 according to the present modification example is provided with acoustic wave filters 4A, 4B, 4C, 5A, 5B, and 5C, low noise amplifiers 7A, 7B, 7C, 7D, 7E, and 7F, a switch 78, and an antenna connection terminal 150.

Each of the acoustic wave filters 4A to 4C and 5A to 5C is an example of a first acoustic wave filter, and has, for example, the same circuit configuration and the same resonance characteristics of the acoustic wave resonator as those of any of the acoustic wave filter 1 according to the embodiment, the acoustic wave filter 1A according to Modification Example 1, or the acoustic wave filter 1B according to Modification Example 2.

The acoustic wave filter 4A includes an input/output terminal 161 (first input/output terminal) and an input/output terminal 141 (second input/output terminal), and has, for example, a pass band including at least a part of a band A belonging to a mid band group (1427 to 2200 MHZ, hereinafter referred to as MB). The acoustic wave filter 4B includes input/output terminals 142 and 162, and has, for example, a pass band including at least a part of a band B belonging to the MB. The acoustic wave filter 4C includes input/output terminals 143 and 163, and has, for example, a pass band including at least a part of a band C belonging to the MB. The band A, the band B, and the band C may be the same band.

The acoustic wave filter 5A includes input/output terminals 144 and 164, and has, for example, a pass band including at least a part of a band D belonging to the MB. The acoustic wave filter 5B includes input/output terminals 145 and 165, and has, for example, a pass band including at least a part of a band E belonging to the MB. The acoustic wave filter 5C includes input/output terminals 146 and 166, and has, for example, a pass band including at least a part of a band F belonging to the MB. The band D, the band E, and the band F may be the same band.

Each of the low noise amplifiers 7A to 7F is an example of a first low noise amplifier, and has the same circuit configuration and the same amplification characteristics as the low noise amplifier 2 according to the embodiment. The low noise amplifier 7A includes an input terminal 171. The input terminal 171 is an example of a first input terminal and is connected to the input/output terminal 161 without necessarily passing through an inductor. The low noise amplifier 7B includes an input terminal 172. The input terminal 172 is connected to the input/output terminal 162 without necessarily passing through an inductor. The low noise amplifier 7C includes an input terminal 173. The input terminal 173 is connected to the input/output terminal 163 without necessarily passing through an inductor. The low noise amplifier 7D includes an input terminal 174. The input terminal 174 is connected to the input/output terminal 164 without necessarily passing through an inductor. The low noise amplifier 7E includes an input terminal 175. The input terminal 175 is connected to the input/output terminal 165 without necessarily passing through an inductor. The low noise amplifier 7F includes an input terminal 176. The input terminal 176 is connected to the input/output terminal 166 without necessarily passing through an inductor.

The switch 78 is connected between the antenna connection terminal 150 and the acoustic wave filters 4A to 4C and 5A to 5C, and includes a common terminal and a plurality of selection terminals. The antenna connection terminal 150 is connected to a common terminal of the switch 78 and the antenna. A plurality of selection terminals of the switch 78 are connected to the acoustic wave filters 4A to 4C and 5A to 5C in a one-to-one manner.

According to the above configuration, the high frequency module 157 can execute (1) the single transmission of any of the signals of the band A to the band F and (2) the simultaneous transmission of two or more signals of the band A to the band F.

The acoustic wave filters 4A and 4B are included in the filter integrated component 191. The filter integrated component 191 is an example of a first integrated component, and has, for example, a configuration in which the acoustic wave resonators of the acoustic wave filters 4A and 4B are disposed on a common piezoelectric substrate. The acoustic wave filters 4C and 5A are included in the filter integrated component 192. For example, the filter integrated component 192 has a configuration in which the acoustic wave resonators of the acoustic wave filters 4C and 5A are disposed on a common piezoelectric substrate. The acoustic wave filters 5B and 5C are included in the filter integrated component 193. For example, the filter integrated component 193 has a configuration in which the acoustic wave resonators of the acoustic wave filters 5B and 5C are disposed on a common piezoelectric substrate.

The low noise amplifiers 7A to 7F are included in the integrated circuit 190. The integrated circuit 190 is an example of a second integrated component, and may be configured by using, for example, a CMOS, and specifically, may be manufactured by an SOI process. The integrated circuit 190 is not limited to the CMOS.

Next, the component disposition of the high frequency module 157 according to the present modification example will be described. FIG. 23B is a plan view of the high frequency module 157 according to Modification Example 16. FIG. 23B illustrates the disposition of the circuit components in a case where the main surface 90a of the mounting substrate 90 is viewed from the z-axis positive direction side.

As illustrated in FIG. 23B, the high frequency module 157 is further provided with the mounting substrate 90 in addition to the circuit components illustrated in FIG. 23A. The mounting substrate 90 has main surfaces 90a (first main surface) and 90b (second main surface) facing each other.

As illustrated in FIG. 23B, the filter integrated components 191, 192, and 193, the integrated circuit 190, the switch 78, and the antenna connection terminal 150 are disposed on the main surface 90a. More specifically, the filter integrated component 191 has a main surface 191a and a main surface 191b, and is disposed on the mounting substrate 90 such that the main surface 191b faces the main surface 90a. The input/output terminals 141, 142, 161, and 162 are disposed on the main surface 191b. The filter integrated component 192 has a main surface 192a and a main surface 192b, and is disposed on the mounting substrate 90 such that the main surface 192b faces the main surface 90a. The input/output terminals 143, 144, 163, and 164 are disposed on the main surface 192b. The filter integrated component 193 has a main surface 193a and a main surface 193b, and is disposed on the mounting substrate 90 such that the main surface 193b faces the main surface 90a. The input/output terminals 145, 146, 165, and 166 are disposed on the main surface 193b.

Here, as illustrated in FIG. 23B, in a case where the mounting substrate 90 is viewed in a plan view, the input/output terminal 161 and the input terminal 171 are close to each other, the input/output terminal 162 and the input terminal 172 are close to each other, the input/output terminal 163 and the input terminal 173 are close to each other, the input/output terminal 164 and the input terminal 174 are close to each other, the input/output terminal 165 and the input terminal 175 are close to each other, and the input/output terminal 166 and the input terminal 176 are close to each other.

Accordingly, the wiring connecting the acoustic wave filters 4A to 4C and 5A to 5C and the low noise amplifiers 7A to 7F can be shortened. Therefore, since the transmission loss and the stray capacitance of the wiring can be reduced, the noise figure of the low noise amplifiers 7A to 7F can be improved. In addition, since overlapping of each of the wirings can be reduced, isolation between the signals passing through the acoustic wave filters 4A to 4C and 5A to 5C can be improved.

In the disposition relationship between the acoustic wave filters 4A to 4C and 5A to 5C and the low noise amplifiers 7A to 7F, in other words, each of the main surfaces 191b, 192b, 193b, and 190b has a rectangular shape, an outer side of the main surface 191b in closest contact with the input/output terminals 161 and 162 faces an outer side of the main surface 190b in closest contact with the input terminals 171 and 172, an outer side of the main surface 192b in closest contact with the input/output terminals 163 and 164 faces an outer side of the main surface 190b in closest contact with the input terminals 173 and 174, and an outer side of the main surface 193b in closest contact with the input/output terminals 165 and 166 faces an outer side of the main surface 190b in closest contact with the input terminals 175 and 176. Accordingly, the wiring connecting the acoustic wave filters 4A to 4C and 5A to 5C and the low noise amplifiers 7A to 7F can be shortened.

### 19 Component Disposition of High Frequency Module 158 According to Modification Example 17

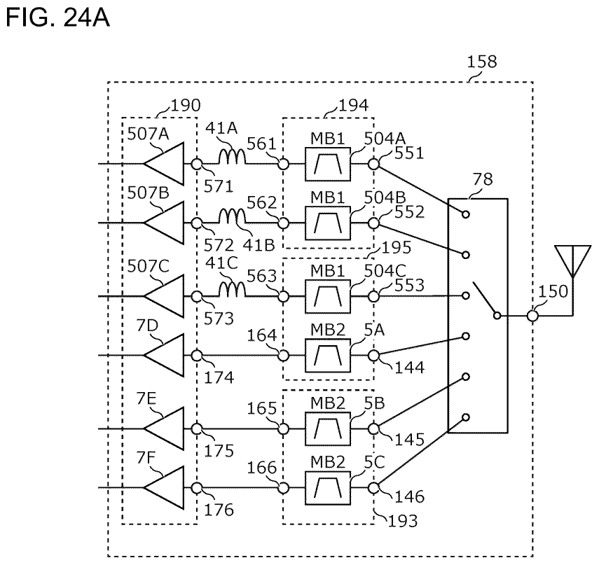

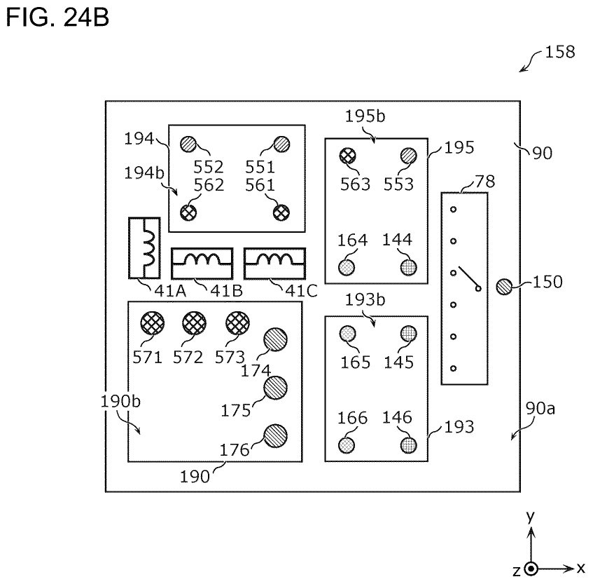

FIG. 24A is a circuit configuration diagram of a high frequency module 158 according to Modification Example 17. As illustrated in the figure, the high frequency module 158 according to the present modification example is provided with acoustic wave filters 504A, 504B, 504C, 5A, 5B, and 5C, low noise amplifiers 507A, 507B, 507C, 7D, 7E, and 7F, inductors 41A, 41B, and 41C, a switch 78, and an antenna connection terminal 150.

Each of the acoustic wave filters 5A to 5C is an example of a first acoustic wave filter, and has, for example, the same circuit configuration and the same resonance characteristics of the acoustic wave resonator as those of any of the acoustic wave filter 1 according to the embodiment, the acoustic wave filter 1A according to Modification Example 1, or the acoustic wave filter 1B according to Modification Example 2. The acoustic wave filter 5A includes an input/output terminal 164 (first input/output terminal) and an input/output terminal 144 (second input/output terminal), and has, for example, a pass band including at least a part of a band D belonging to the MB. The acoustic wave filter 5B includes input/output terminals 145 and 165, and has, for example, a pass band including at least a part of a band E belonging to the MB. The acoustic wave filter 5C includes input/output terminals 146 and 166, and has, for example, a pass band including at least a part of a band F belonging to the MB. The band D, the band E, and the band F may be the same band.

Each of the acoustic wave filters 504A to 504C is an example of a second acoustic wave filter, and has, for example, the same circuit configuration and the same resonance characteristics of the acoustic wave resonator as that of the acoustic wave filter 501 according to the comparative example. The acoustic wave filter 504A includes an input/output terminal 561 (third input/output terminal) and an input/output terminal 551 (fourth input/output terminal), and has, for example, a pass band including at least a part of a band A belonging to the MB. The acoustic wave filter 504B includes input/output terminals 552 and 562, and has, for example, a pass band including at least a part of a band B belonging to the MB. The acoustic wave filter 504C includes input/output terminals 553 and 563 and has, for example, a pass band including at least a part of a band C belonging to the MB. The band A, the band B, and the band C may be the same band.

Each of the low noise amplifiers 7D to 7F is an example of a first low noise amplifier, and has the same circuit configuration and the same amplification characteristics as the low noise amplifier 2 according to the embodiment. The low noise amplifier 7D includes an input terminal 174. The input terminal 174 is an example of a first input terminal and is connected to the input/output terminal 164 without necessarily passing through an inductor. The low noise amplifier 7E includes an input terminal 175. The input terminal 175 is connected to the input/output terminal 165 without necessarily passing through an inductor. The low noise amplifier 7F includes an input terminal 176. The input terminal 176 is connected to the input/output terminal 166 without necessarily passing through an inductor.

Each of the low noise amplifiers 507A to 507C is an example of a second low noise amplifier, and has the same circuit configuration and the same amplification characteristics as the low noise amplifier 2 according to the embodiment. The low noise amplifier 507A includes an input terminal 571. The input terminal 571 is an example of a second input terminal and is connected to the input/output terminal 561 with the inductor 41A interposed therebetween. The low noise amplifier 507B includes an input terminal 572. The input terminal 572 is connected to the input/output terminal 562 with the inductor 41B interposed therebetween. The low noise amplifier 507C includes an input terminal 573. The input terminal 573 is connected to the input/output terminal 563 with the inductor 41C interposed therebetween.

The inductor 41A is an example of a third inductor, and is disposed between the low noise amplifier 507A having a capacitive input impedance and the acoustic wave filter 504A. The inductor 41B is disposed between the low noise amplifier 507B having a capacitive input impedance and the acoustic wave filter 504B. The inductor 41C is disposed between the low noise amplifier 507C having a capacitive input impedance and the acoustic wave filter 504C.

The switch 78 is connected between the antenna connection terminal 150 and the acoustic wave filters 5A to 4C and 504A to 504C, and includes a common terminal and a plurality of selection terminals. The antenna connection terminal 150 is connected to a common terminal of the switch 78 and the antenna. The plurality of selection terminals of the switch 78 are connected to the acoustic wave filters 5A to 4C and 504A to 504C in a one-to-one manner.

According to the above configuration, the high frequency module 158 can execute (1) the single transmission of any of the signals of the band A to the band F and (2) the simultaneous transmission of two or more signals of the band A to the band F.

The acoustic wave filters 504A and 504B are included in the filter integrated component 194. For example, the filter integrated component 194 has a configuration in which the acoustic wave resonators of the acoustic wave filters 504A and 504B are disposed on a common piezoelectric substrate. The acoustic wave filters 504C and 5A are included in the filter integrated component 195. For example, the filter integrated component 195 has a configuration in which the acoustic wave resonators of the acoustic wave filters 504C and 5A are disposed on a common piezoelectric substrate. The acoustic wave filters 5B and 5C are included in the filter integrated component 193. For example, the filter integrated component 193 has a configuration in which the acoustic wave resonators of the acoustic wave filters 5B and 5C are disposed on a common piezoelectric substrate.

The low noise amplifiers 507A to 507C and 7D to 7F are included in the integrated circuit 190. The integrated circuit 190 is an example of a second integrated component, and may be configured by using, for example, a CMOS, and specifically, may be manufactured by an SOI process. The integrated circuit 190 is not limited to the CMOS.

Next, the component disposition of the high frequency module 158 according to the present modification example will be described. FIG. 24B is a plan view of the high frequency module 158 according to Modification Example 17. FIG. 24B illustrates the disposition of the circuit components in a case where the main surface 90a of the mounting substrate 90 is viewed from the z-axis positive direction side.

As illustrated in FIG. 24B, the high frequency module 158 is further provided with the mounting substrate 90 in addition to the circuit components illustrated in FIG. 24A. The mounting substrate 90 has main surfaces 90a (first main surface) and 90b (second main surface) facing each other.

As illustrated in FIG. 24B, the filter integrated components 193, 194, and 195, the integrated circuit 190, the inductors 41A, 41B, and 41C, the switch 78, and the antenna connection terminal 150 are disposed on the main surface 90a. More specifically, the filter integrated component 194 has a main surface 194a and a main surface 194b, and is disposed on the mounting substrate 90 such that the main surface 194b faces the main surface 90a. The input/output terminals 551, 552, 561, and 562 are disposed on the main surface 194b. The filter integrated component 195 has a main surface 195a and a main surface 195b, and is disposed on the mounting substrate 90 such that the main surface 195b faces the main surface 90a. The input/output terminals 553, 144, 563, and 164 are disposed on the main surface 195b. The filter integrated component 193 has a main surface 193a and a main surface 193b, and is disposed on the mounting substrate 90 such that the main surface 193b faces the main surface 90a. The input/output terminals 145, 146, 165, and 166 are disposed on the main surface 193b.

Here, as illustrated in FIG. 24B, in a case where the mounting substrate 90 is viewed in a plan view, the filter integrated component 193 is closer to the integrated circuit 190 with respect to the filter integrated component 194. Accordingly, the wiring connecting the acoustic wave filters 5B and 5C and the low noise amplifiers 7E and 7F can be shortened. Therefore, since the transmission loss and the stray capacitance of the wiring can be reduced, the noise figure of the low noise amplifiers 7E and 7F can be improved.

In addition, the distance between the input/output terminal 164 and the input terminal 174, the distance between the input/output terminal 165 and the input terminal 175, and the distance between the input/output terminal 166 and the input terminal 176 are shorter than the distance between the input/output terminal 561 and the input terminal 571, the distance between the input/output terminal 562 and the input terminal 572, and the distance between the input/output terminal 563 and the input terminal 573. Accordingly, the wiring connecting the acoustic wave filters 5A, 5B, and 5C and the low noise amplifiers 7D, 7E, and 7F can be shortened. Therefore, since the transmission loss and the stray capacitance of the wiring can be reduced, the noise figure of the low noise amplifiers 7D, 7E, and 7F can be improved.

In addition, the main surface 190b has a rectangular shape, the input terminals 174, 175, and 176 are disposed close to a first outer side of the main surface 190b, and the input terminals 571, 572, and 573 are disposed close to a second outer side of the main surface 190b. Accordingly, since the filter integrated component 193 faces the first outer side, and the filter integrated component 195 is disposed close to the integrated circuit 190, the wiring connecting the acoustic wave filters 5A, 5B, and 5C and the low noise amplifiers 7D, 7E, and 7F can be shortened. Furthermore, since the inductors 41A, 41B, and 41C are disposed between the filter integrated component 194 and the second outer side, the wiring connecting the acoustic wave filters 504A, 504B, and 504C and the low noise amplifiers 507A, 507B, and 507C can be shortened. Therefore, the noise figure of the low noise amplifiers 507A, 507B, 507C, 7D, 7E, and 7F can be improved.

### 20 Component Disposition of High Frequency Modules 159 and 160 According to Modification Examples 18 and 19

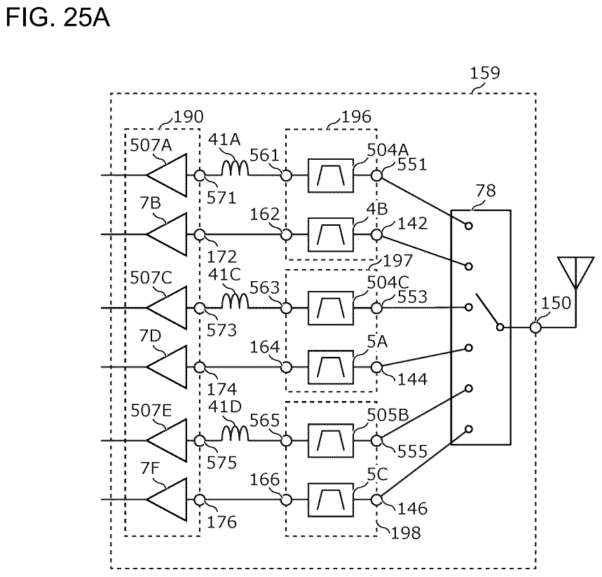

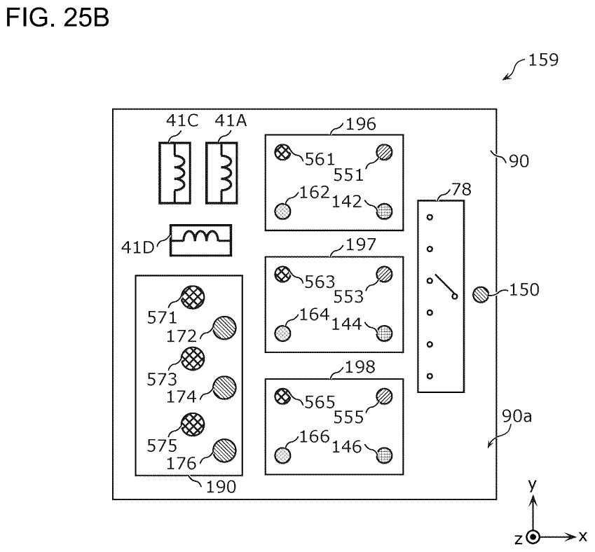

FIG. 25A is a circuit configuration diagram of a high frequency module 159 according to Modification Example 18. As illustrated in the figure, the high frequency module 159 according to the present modification example is provided with acoustic wave filters 504A, 504C, 505B, 4B, 5A, and 5C, low noise amplifiers 507A, 507C, 507E, 7B, 7D, and 7F, inductors 41A, 41C, and 41D, a switch 78, and an antenna connection terminal 150.

Each of the acoustic wave filters 4B, 5A, and 5C is an example of a first acoustic wave filter, and has, for example, the same circuit configuration and the same resonance characteristics of the acoustic wave resonator as those of any of the acoustic wave filter 1 according to the embodiment, the acoustic wave filter 1A according to Modification Example 1, or the acoustic wave filter 1B according to Modification Example 2. The acoustic wave filter 4B includes an input/output terminal 162 (first input/output terminal) and an input/output terminal 142 (second input/output terminal), and has, for example, a pass band including at least a part of a band B belonging to the MB. The acoustic wave filter 5A includes input/output terminals 144 and 164, and has, for example, a pass band including at least a part of a band D belonging to the MB. The acoustic wave filter 5C includes input/output terminals 146 and 166, and has, for example, a pass band including at least a part of a band F belonging to the MB.

Each of the acoustic wave filters 504A, 504C, and 505B is an example of a second acoustic wave filter, and has, for example, the same circuit configuration and the same resonance characteristics of the acoustic wave resonator as that of the acoustic wave filter 501 according to the comparative example. The acoustic wave filter 504A includes an input/output terminal 561 (third input/output terminal) and an input/output terminal 551 (fourth input/output terminal), and has, for example, a pass band including at least a part of a band A belonging to the MB. The acoustic wave filter 504C includes input/output terminals 553 and 563 and has, for example, a pass band including at least a part of a band C belonging to the MB. The acoustic wave filter 505B includes input/output terminals 555 and 565, and has, for example, a pass band including at least a part of a band E belonging to the MB.

The band A, the band B, and the band C may be the same band. In addition, the band D, the band E, and the band F may be the same band.

Each of the low noise amplifiers 7B, 7D, and 7F is an example of a first low noise amplifier, and has the same circuit configuration and the same amplification characteristics as the low noise amplifier 2 according to the embodiment. The low noise amplifier 7B includes an input terminal 172. The input terminal 172 is an example of a first input terminal and is connected to the input/output terminal 162 without necessarily passing through an inductor. The low noise amplifier 7D includes an input terminal 174. The input terminal 174 is connected to the input/output terminal 164 without necessarily passing through an inductor. The low noise amplifier 7F includes an input terminal 176. The input terminal 176 is connected to the input/output terminal 166 without necessarily passing through an inductor.

Each of the low noise amplifiers 507A, 507C, and 507E is an example of a second low noise amplifier, and has the same circuit configuration and the same amplification characteristics as the low noise amplifier 2 according to the embodiment. The low noise amplifier 507A includes an input terminal 571. The input terminal 571 is an example of a second input terminal and is connected to the input/output terminal 561 with the inductor 41A interposed therebetween. The low noise amplifier 507C includes an input terminal 573. The input terminal 573 is connected to the input/output terminal 563 with the inductor 41C interposed therebetween. The low noise amplifier 507E includes an input terminal 575. The input terminal 575 is connected to the input/output terminal 565 with the inductor 41D interposed therebetween.

The inductor 41A is an example of a third inductor, and is disposed between the low noise amplifier 507A having a capacitive input impedance and the acoustic wave filter 504A. The inductor 41C is disposed between the low noise amplifier 507C having a capacitive input impedance and the acoustic wave filter 504C. The inductor 41D is disposed between the low noise amplifier 507E having a capacitive input impedance and the acoustic wave filter 505B.

The switch 78 is connected between the antenna connection terminal 150 and the acoustic wave filters 4B, 5A, 5C, 504A, 504C, and 505B, and includes a common terminal and a plurality of selection terminals. The antenna connection terminal 150 is connected to a common terminal of the switch 78 and the antenna. The plurality of selection terminals of the switch 78 are connected to the acoustic wave filters 4B, 5A, 5C, 504A, 504C, and 505B in a one-to-one manner.

According to the above configuration, the high frequency module 159 can execute (1) the single transmission of any of the signals of the band A to the band F and (2) the simultaneous transmission of two or more signals of the band A to the band F.

The acoustic wave filters 504A and 4B are included in the filter integrated component 196. For example, the filter integrated component 196 has a configuration in which the acoustic wave resonators of the acoustic wave filters 504A and 4B are disposed on a common piezoelectric substrate. The acoustic wave filters 504C and 5A are included in the filter integrated component 197. For example, the filter integrated component 197 has a configuration in which the acoustic wave resonators of the acoustic wave filters 504C and 5A are disposed on a common piezoelectric substrate. The acoustic wave filters 505B and 5C are included in the filter integrated component 198. For example, the filter integrated component 198 has a configuration in which the acoustic wave resonators of the acoustic wave filters 505B and 5C are disposed on a common piezoelectric substrate.

The low noise amplifiers 507A, 507C, 507E, 7B, 7D, and 7F are included in the integrated circuit 190. The integrated circuit 190 is an example of a second integrated component, and may be configured by using, for example, a CMOS, and specifically, may be manufactured by an SOI process. The integrated circuit 190 is not limited to the CMOS.

Next, the component disposition of the high frequency module 159 according to the present modification example will be described. FIG. 25B is a plan view of the high frequency module 159 according to Modification Example 18. FIG. 25B illustrates the disposition of the circuit components in a case where the main surface 90a of the mounting substrate 90 is viewed from the z-axis positive direction side.

As illustrated in FIG. 25B, the high frequency module 159 is further provided with the mounting substrate 90 in addition to the circuit components illustrated in FIG. 25A. The mounting substrate 90 has main surfaces 90a (first main surface) and 90b (second main surface) facing each other.

As illustrated in FIG. 25B, the filter integrated components 196, 197, and 198, the integrated circuit 190, the inductors 41A, 41C, and 41D, the switch 78, and the antenna connection terminal 150 are disposed on the main surface 90a. More specifically, the input/output terminals 142, 162, 551, and 561 are disposed on the main surface of the filter integrated component 196. The input/output terminals 144, 164, 553, and 563 are disposed on the main surface of the filter integrated component 197. The input/output terminals 146, 166, 555, and 565 are disposed on the main surface of the filter integrated component 198.

Here, as illustrated in FIG. 25B, in a case where the mounting substrate 90 is viewed in a plan view, the input/output terminals 162, 164, 166, 561, 563, and 565 are closer to the integrated circuit 190 with respect to the input/output terminals 142, 144, 146, 551, 553, and 555. Accordingly, the wiring connecting the acoustic wave filters 4B, 5A, 5C, 504A, 504C, and 505B and the low noise amplifiers 7B, 7D, 7F, 507A, 507C, and 507E can be shortened. Therefore, since the transmission loss and the stray capacitance of the wiring can be reduced, the noise figure of the low noise amplifiers 7B, 7D, 7F, 507A, 507C, and 507E can be improved.

In addition, the input terminals 172, 174, and 176 are closer to the first outer side of the integrated circuit 190 with respect to the input terminals 571, 573, and 575. The first outer side faces the filter integrated components 197 and 198. In other words, the main surface of the integrated circuit 190 includes the first outer peripheral region and the first central region located inside the first outer peripheral region, the input terminals 172, 174, and 176 are disposed in the first outer peripheral region, and the input terminals 571, 573, and 575 are disposed in the first central region. Accordingly, the wiring connecting the acoustic wave filters 4B, 5A, and 5C to which the inductors 41A, 41C, and 41D are not connected and the low noise amplifiers 7B, 7D, and 7F can be shortened. Therefore, since the transmission loss and the stray capacitance of the wiring can be reduced, the noise figure of the low noise amplifiers 7B, 7D, and 7F can be improved.

In addition, the input/output terminals 162, 164, and 166 to which the inductor is not connected and the input/output terminals 561, 563, and 565 to which the inductor is connected are alternately disposed. Accordingly, the inductor 41A is disposed close to the input/output terminal 561, and each of the inductors 41C and 41D is disposed between the input/output terminal 162 and the input/output terminal 563 and between the input/output terminal 164 and the input/output terminal 565. Therefore, the wiring connecting the acoustic wave filters 504A, 504C, and 505B and the low noise amplifiers 507A, 507C, and 507E can be shortened, and the magnetic field coupling between the inductors 41A, 41C, and 41D can be reduced. Therefore, the noise figure of the low noise amplifiers 507A, 507C, and 507E can be improved.

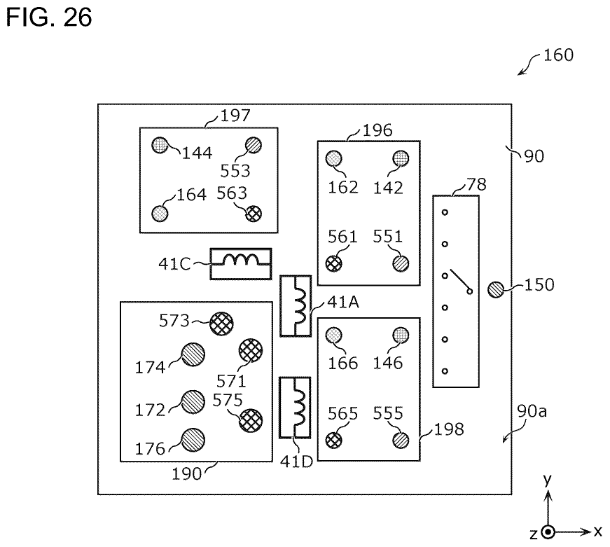

FIG. 26 is a plan view of a high frequency module 160 according to Modification Example 19. As illustrated in the figure, the high frequency module 160 according to the present modification example is provided with the filter integrated components 196, 197, and 198, the integrated circuit 190, the inductors 41A, 41C, and 41D, the switch 78, the antenna connection terminal 150, and the mounting substrate 90. The high frequency module 160 according to the present modification example is different from the high frequency module 159 according to Modification Example 18 only in the disposition configuration of the circuit components. Therefore, in the following, the high frequency module 160 according to the present modification example will be described with a focus on different configurations from those of the high frequency module 159 according to Modification Example 18, and the same configurations will be omitted.

As illustrated in FIG. 26, the filter integrated components 196, 197, and 198, the integrated circuit 190, the inductors 41A, 41C, and 41D, the switch 78, and the antenna connection terminal 150 are disposed on the main surface 90a. Here, as illustrated in FIG. 26, in a case where the mounting substrate 90 is viewed in a plan view, the input/output terminal 162 is closer to the integrated circuit 190 with respect to the input/output terminal 142, the input/output terminal 164 is closer to the integrated circuit 190 with respect to the input/output terminal 144, the input/output terminal 166 is closer to the integrated circuit 190 with respect to the input/output terminal 146, the input/output terminal 561 is closer to the integrated circuit 190 with respect to the input/output terminal 551, the input/output terminal 563 is closer to the integrated circuit 190 with respect to the input/output terminal 553, and the input/output terminal 565 is closer to the integrated circuit 190 with respect to the input/output terminal 555. Accordingly, the wiring connecting the acoustic wave filters 4B, 5A, 5C, 504A, 504C, and 505B and the low noise amplifiers 7B, 7D, 7F, 507A, 507C, and 507E can be shortened. Therefore, since the transmission loss and the stray capacitance of the wiring can be reduced, the noise figure of the low noise amplifiers 7B, 7D, 7F, 507A, 507C, and 507E can be improved.

In addition, the input terminals 571, 573, and 575 are closer to the first outer side of the integrated circuit 190 with respect to the input terminals 172, 174, and 176. The first outer side faces the filter integrated components 196, 197, and 198 with the inductors 41A, 41C, and 41D interposed therebetween. Since the planar electrodes for connecting the inductors 41A, 41C, and 41D are disposed in the wiring connecting the acoustic wave filters 504A, 504C, and 505B and the low noise amplifiers 507A, 507C, and 507E, the stray capacitance increases. Accordingly, the wiring connecting the acoustic wave filters the 504A, 504C, and 505B to which the inductors 41A, 41C, and 41D are connected and the low noise amplifiers 507A, 507C, and 507E can be shortened, so that a balance between the stray capacitance of the wirings and the stray capacitance of the wiring connecting the acoustic wave filters 4B, 5A, and 5C and the low noise amplifiers 7B, 7D, and 7F can be obtained.

### 21 Component Disposition of High Frequency Module 271 According to Modification Example 20

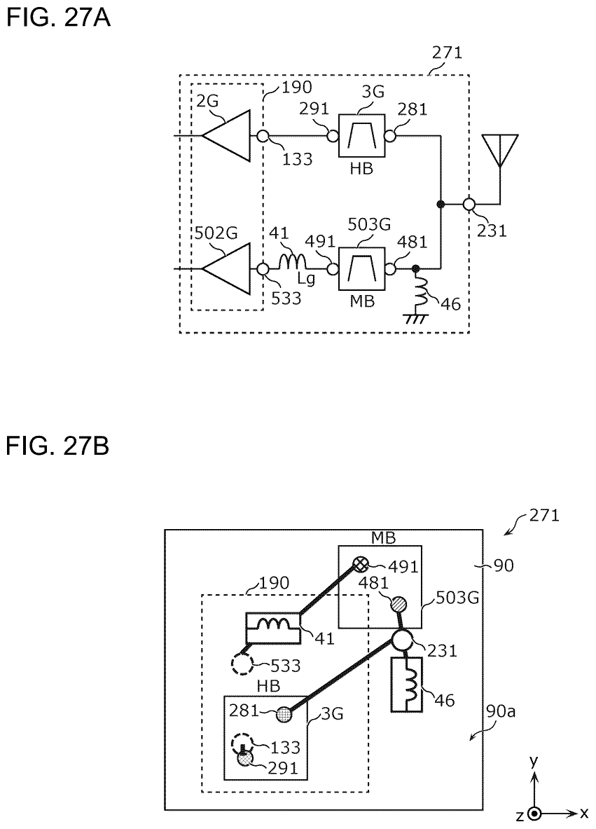

FIG. 27A is a circuit configuration diagram of a high frequency module according to Modification Example 20.

FIG. 27A is a circuit configuration diagram of a high frequency module 271 according to Modification Example 20. As illustrated in the figure, the high frequency module 271 according to the present modification example is provided with acoustic wave filters 3G and 503G, low noise amplifiers 2G and 502G, the inductors 41 and 46, and an antenna connection terminal 231.

The acoustic wave filter 3G is an example of a first acoustic wave filter, and has, for example, the same circuit configuration and the same resonance characteristics of the acoustic wave resonator as those of any of the acoustic wave filter 1 according to the embodiment, the acoustic wave filter 1A according to Modification Example 1, or the acoustic wave filter 1B according to Modification Example 2. The acoustic wave filter 3G includes an input/output terminal 291 (first input/output terminal) and an input/output terminal 281 (second input/output terminal), and has, for example, a pass band including at least a part of a band A belonging to high band group (2300 to 2690 MHZ, hereinafter referred to as HB).

The acoustic wave filter 503G is an example of a second acoustic wave filter, and has, for example, the same circuit configuration and the same resonance characteristics of the acoustic wave resonator as that of the acoustic wave filter 501 according to the comparative example. The acoustic wave filter 503G includes an input/output terminal 491 (third input/output terminal) and an input/output terminal 481 (fourth input/output terminal), and has, for example, a pass band including at least a part of a band B belonging to the MB.

The low noise amplifier 2G is an example of a first low noise amplifier, and has the same circuit configuration and the same amplification characteristics as the low noise amplifier 2 according to the embodiment. The low noise amplifier 2G includes an input terminal 133. The input terminal 133 is an example of a first input terminal and is connected to the input/output terminal 291 without necessarily passing through an inductor.

The low noise amplifier 502G is an example of a second low noise amplifier, and has the same circuit configuration and the same amplification characteristics as the low noise amplifier 2 according to the embodiment. The low noise amplifier 502G includes an input terminal 533. The input terminal 533 is an example of a second input terminal and is connected to the input/output terminal 491 with the inductor 41 interposed therebetween.

The inductor 41 is an example of a third inductor, and is disposed between the low noise amplifier 502G having a capacitive input impedance and the acoustic wave filter 503G.

The inductor 46 is connected to the antenna connection terminal 231 and performs impedance matching between the acoustic wave filter 503G and an external circuit connected to the antenna connection terminal 231.

According to the above configuration, the high frequency module 271 can simultaneously transmit the signal of the band A and the signal of the band B.

The higher the frequency of the signal, the larger the shift amount of the impedance due to the influence of the stray capacitance of the wiring. According to the configuration of the present modification example, since the inductor is not disposed in the acoustic wave filter 3G and the low noise amplifier 2G that transmit the signal of the HB located on the high frequency side, the transmission loss of the signal of the HB can be reduced.

The low noise amplifiers 2G and 502G are included in the integrated circuit 190. The integrated circuit 190 is an example of a second integrated component, and may be configured by using, for example, a CMOS, and specifically, may be manufactured by an SOI process. The integrated circuit 190 is not limited to the CMOS.

Next, the component disposition of the high frequency module 271 according to the present modification example will be described. FIG. 27B is a plan view of the high frequency module 271 according to Modification Example 20. FIG. 27B illustrates the disposition of the circuit components in a case where the main surface 90a of the mounting substrate 90 is viewed from the z-axis positive direction side. In FIG. 27B, circuit components disposed on the main surface 90a side are illustrated by solid lines, and terminals disposed on the main surface 90b side are illustrated by broken lines.

As illustrated in FIG. 27B, the high frequency module 271 is further provided with the mounting substrate 90 in addition to the circuit components illustrated in FIG. 27A. The mounting substrate 90 has main surfaces 90a (first main surface) and 90b (second main surface) facing each other.

As illustrated in FIG. 27B, the acoustic wave filters 3G and 503G, the inductors 41 and 46, and the antenna connection terminal 231 are disposed on the main surface 90a. In addition, the integrated circuit 190 is disposed on the main surface 90b.

Here, as illustrated in FIG. 27B, in a case where the mounting substrate 90 is viewed in a plan view, the input/output terminal 291 of the acoustic wave filter 3G overlaps with the integrated circuit 190. On the other hand, the input/output terminal 491 and the antenna connection terminal 231 of the acoustic wave filter 503G do not overlap with the integrated circuit 190. Accordingly, the input/output terminal 291 connected to the low noise amplifier 2G without necessarily passing through the inductor is disposed close to the low noise amplifier 2G, and the input/output terminal 491 connected to the low noise amplifier 502G with the inductor 41 interposed therebetween is connected away from the low noise amplifier 502G. As a result, the wiring connecting the acoustic wave filter 3G to which the inductor 41 is not connected and the low noise amplifier 2G can be shortened. Therefore, since the transmission loss and the stray capacitance of the wiring can be reduced, the noise figure of the low noise amplifier 2G can be improved.

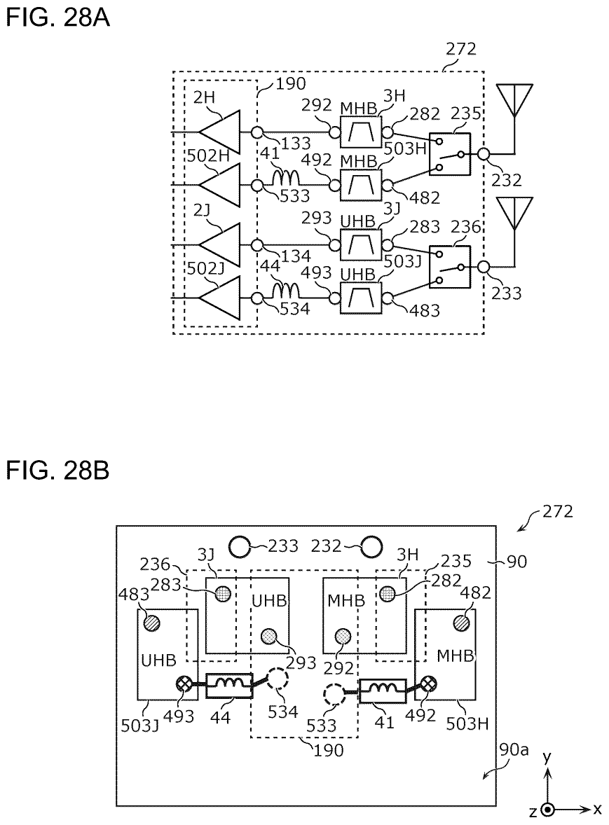

FIG. 28A is a circuit configuration diagram of a high frequency module 272 according to Modification Example 21. The high frequency module 272 according to Modification Example 21 is different from the high frequency module 271 according to Modification Example 20 in that the number of acoustic wave filters and antenna connection terminals is increased as the configuration. Hereinafter, the high frequency module 272 according to Modification Example 21 will be described with a focus on points different from the high frequency module 271 according to Modification Example 20.

As illustrated in FIG. 28A, the high frequency module 272 is provided with acoustic wave filters 3H, 3J, 503H, and 503J, low noise amplifiers 2H, 2J, 502H, and 502J, the inductors 41 and 44, switches 235 and 236, and antenna connection terminals 232 and 233.

The acoustic wave filters 3H and 3J are examples of a first acoustic wave filter, and have, for example, the same circuit configuration and the same resonance characteristics of the acoustic wave resonator as those of any of the acoustic wave filter 1 according to the embodiment, the acoustic wave filter 1A according to Modification Example 1, or the acoustic wave filter 1B according to Modification Example 2. The acoustic wave filter 3H includes an input/output terminal 292 (first input/output terminal) and an input/output terminal 282 (second input/output terminal), and has, for example, a pass band including at least a part of a band A belonging to a mid high band group (MHB: 1710 to 2370 MHz, hereinafter, referred to as MHB). The acoustic wave filter 3J includes input/output terminals 293 and 283, and has, for example, a pass band including at least a part of a band C belonging to an ultra high band group (UHB: 3.3 to 5 GHZ, hereinafter referred to as UHB).

The acoustic wave filters 503H and 503J are examples of a second acoustic wave filter, and have, for example, the same circuit configuration and the same resonance characteristics of the acoustic wave resonator as that of the acoustic wave filter 501 according to the comparative example. The acoustic wave filter 503H includes an input/output terminal 492 (third input/output terminal) and an input/output terminal 482 (fourth input/output terminal), and has, for example, a pass band including at least a part of a band B belonging to the MHB. The acoustic wave filter 503J includes input/output terminals 493 and 483 and has, for example, a pass band including at least a part of a band D belonging to the UHB.

The low noise amplifiers 2H and 2J are examples of a first low noise amplifier, and have the same circuit configuration and the same amplification characteristics as the low noise amplifier 2 according to the embodiment. The low noise amplifier 2H includes an input terminal 133. The input terminal 133 is an example of a first input terminal and is connected to the input/output terminal 292 without necessarily passing through an inductor. The low noise amplifier 2J includes an input terminal 134. The input terminal 134 is connected to the input/output terminal 293 without necessarily passing through an inductor.

The low noise amplifiers 502H and 502J are examples of a second low noise amplifier, and have the same circuit configuration and the same amplification characteristics as the low noise amplifier 2 according to the embodiment. The low noise amplifier 502H includes an input terminal 533. The input terminal 533 is an example of a second input terminal and is connected to the input/output terminal 492 with the inductor 41 interposed therebetween. The low noise amplifier 502J includes an input terminal 534. The input terminal 534 is connected to the input/output terminal 493 with the inductor 44 interposed therebetween.

The inductor 41 is an example of a third inductor, and is disposed between the low noise amplifier 502H having a capacitive input impedance and the acoustic wave filter 503H. The inductor 44 is disposed between the low noise amplifier 502J having a capacitive input impedance and the acoustic wave filter 503J.

The switch 235 includes a common terminal, a first selection terminal, and a second selection terminal, and switches the connection between the common terminal and the first selection terminal and a connection between the common terminal and the second selection terminal. The common terminal is connected to the antenna connection terminal 232, the first selection terminal is connected to the acoustic wave filter 3H, and the second selection terminal is connected to the acoustic wave filter 503H.

The switch 236 includes a common terminal, a third selection terminal, and a fourth selection terminal, and switches the connection between the common terminal and the third selection terminal and a connection between the common terminal and the fourth selection terminal. The common terminal is connected to the antenna connection terminal 233, the third selection terminal is connected to the acoustic wave filter 3J, and the fourth selection terminal is connected to the acoustic wave filter 503J.

The low noise amplifiers 2H, 2J, 502H, and 502J are included in the integrated circuit 190. The integrated circuit 190 is an example of a second integrated component, and may be configured by using, for example, a CMOS, and specifically, may be manufactured by an SOI process. The integrated circuit 190 is not limited to the CMOS.

Next, the component disposition of the high frequency module 272 according to the present modification example will be described. FIG. 28B is a plan view of the high frequency module 272 according to Modification Example 21. FIG. 28B illustrates the disposition of the circuit components in a case where the main surface 90a of the mounting substrate 90 is viewed from the z-axis positive direction side. In FIG. 28B, circuit components disposed on the main surface 90a side are illustrated by solid lines, and terminals disposed on the main surface 90b side are illustrated by broken lines.

As illustrated in FIG. 28B, the high frequency module 272 is further provided with the mounting substrate 90 in addition to the circuit components illustrated in FIG. 28A. The mounting substrate 90 has main surfaces 90a (first main surface) and 90b (second main surface) facing each other.

As illustrated in FIG. 28B, the acoustic wave filters 3H, 3J, 503H, and 503J, the inductors 41 and 44, and the antenna connection terminals 232 and 233 are disposed on the main surface 90a. In addition, the integrated circuit 190, the switches 235 and 236 are disposed on the main surface 90b. The switches 235 and 236 may be included in the integrated circuit 190.

Here, as illustrated in FIG. 28B, in a case where the mounting substrate 90 is viewed in a plan view, the input/output terminal 292 of the acoustic wave filter 3H overlaps with the integrated circuit 190, and the input/output terminal 293 of the acoustic wave filter 3J overlaps with the integrated circuit 190. On the other hand, the input/output terminal 492 of the acoustic wave filter 503H and the input/output terminal 493 of the acoustic wave filter 503J do not overlap with the integrated circuit 190. Accordingly, the wiring connecting the acoustic wave filter 3H to which the inductor 41 is not connected and the low noise amplifier 2H, and the wiring connecting the acoustic wave filter 3J to which the inductor 44 is not connected and the low noise amplifier 2J can be shortened. Therefore, since the transmission loss and the stray capacitance of the wiring can be reduced, the noise figure of the low noise amplifiers 2H and 2J can be improved.

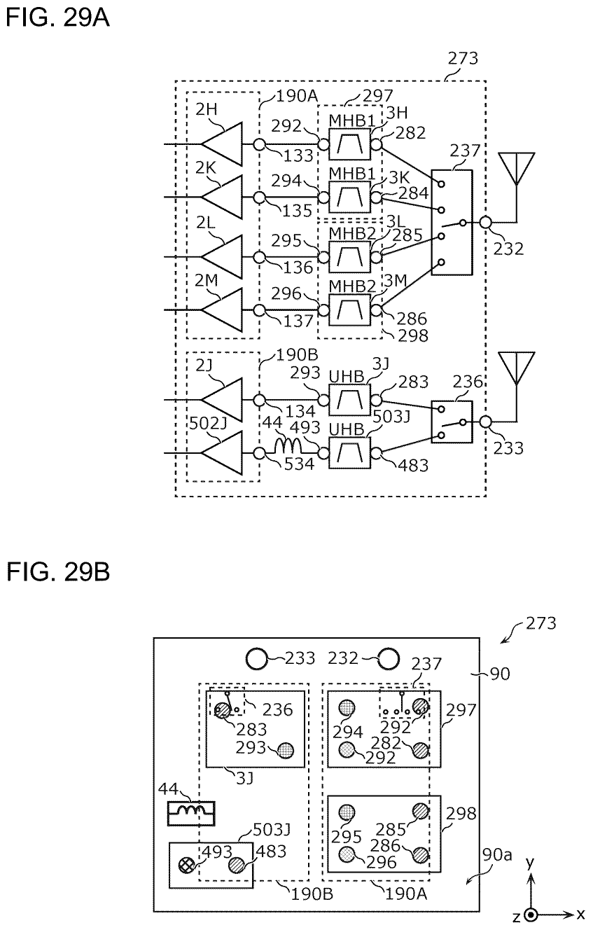

FIG. 29A is a circuit configuration diagram of a high frequency module 273 according to Modification Example 22. The high frequency module 273 according to Modification Example 22 is different from the high frequency module 271 according to Modification Example 20 in that the number of acoustic wave filters and antenna connection terminals is increased and the integrated circuit is divided as the configuration. Hereinafter, the high frequency module 273 according to Modification Example 22 will be described with a focus on points different from the high frequency module 271 according to Modification Example 20.

As illustrated in FIG. 29A, the high frequency module 273 is provided with acoustic wave filters 3H, 3J, 3K, 3L, 3M, and 503J, low noise amplifiers 2H, 2J, 2K, 2L, 2M, and 502J, the inductor 44, the switches 236 and 237, and the antenna connection terminals 232 and 233.

The acoustic wave filters 3H, 3J, 3K, 3L, and 3M are examples of a first acoustic wave filter, and have, for example, the same circuit configuration and the same resonance characteristics of the acoustic wave resonator as those of any of the acoustic wave filter 1 according to the embodiment, the acoustic wave filter 1A according to Modification Example 1, or the acoustic wave filter 1B according to Modification Example 2. The acoustic wave filter 3K includes input/output terminals 294 and 284 and has, for example, a pass band including at least a part of a band K belonging to the MHB. The acoustic wave filter 3L includes input/output terminals 295 and 285 and has, for example, a pass band including at least a part of a band L belonging to MHB. The acoustic wave filter 3M includes input/output terminals 296 and 286, and has, for example, a pass band including at least a part of a band M belonging to MHB.

The low noise amplifiers 2H, 2J, 2K, 2L, 2M, and 502J are examples of a first low noise amplifier, and have the same circuit configuration and the same amplification characteristics as the low noise amplifier 2 according to the embodiment. The low noise amplifier 2K includes an input terminal 135. The input terminal 135 is connected to the input/output terminal 294 without necessarily passing through an inductor. The low noise amplifier 2L includes an input terminal 136. The input terminal 136 is connected to the input/output terminal 295 without necessarily passing through an inductor. The low noise amplifier 2M includes an input terminal 137. The input terminal 137 is connected to the input/output terminal 296 without necessarily passing through an inductor.

The switch 237 includes a common terminal, a first selection terminal, a second selection terminal, a third selection terminal, and a fourth selection terminal, and switches the connection between the common terminal and the first selection terminal, a connection between the common terminal and the second selection terminal, a connection between the common terminal and the third selection terminal, and a connection between the common terminal and the fourth selection terminal. The common terminal is connected to the antenna connection terminal 232, the first selection terminal is connected to the acoustic wave filter 3H, the second selection terminal is connected to the acoustic wave filter 3K, the third selection terminal is connected to the acoustic wave filter 3L, and the fourth selection terminal is connected to the acoustic wave filter 3M.

The acoustic wave filters 3H and 3K are included in the filter integrated component 297. For example, the filter integrated component 297 has a configuration in which the acoustic wave resonators of the acoustic wave filters 3H and 3K are disposed on a common piezoelectric substrate. The acoustic wave filters 3L and 3M are included in the filter integrated component 298. For example, the filter integrated component 298 has a configuration in which the acoustic wave resonators of the acoustic wave filters 3L and 3M are disposed on a common piezoelectric substrate.

The low noise amplifiers 2H, 2K, 2L, and 2M are included in the integrated circuit 190A. The low noise amplifiers 2J and 502J are included in the integrated circuit 190B.

Next, the component disposition of the high frequency module 273 according to the present modification example will be described. FIG. 29B is a plan view of the high frequency module 273 according to Modification Example 22. FIG. 29B illustrates the disposition of the circuit components in a case where the main surface 90a of the mounting substrate 90 is viewed from the z-axis positive direction side. In FIG. 29B, circuit components disposed on the main surface 90a side are illustrated by solid lines, and terminals disposed on the main surface 90b side are illustrated by broken lines.

As illustrated in FIG. 29B, the high frequency module 273 is further provided with the mounting substrate 90 in addition to the circuit components illustrated in FIG. 29A. The mounting substrate 90 has main surfaces 90a (first main surface) and 90b (second main surface) facing each other.

As illustrated in FIG. 29B, the filter integrated components 297 and 298, the acoustic wave filters 3J and 503J, the inductor 44, and the antenna connection terminals 232 and 233 are disposed on the main surface 90a. In addition, the integrated circuits 190A and 190B and the switches 236 and 237 are disposed on the main surface 90b. The switch 236 may be included in the integrated circuit 190B, and the switch 237 may be included in the integrated circuit 190A.

Here, as illustrated in FIG. 29B, in a case where the mounting substrate 90 is viewed in a plan view, the input/output terminals 292, 294, 295, and 296 overlap with the integrated circuit 190A, and the input/output terminal 293 overlaps with the integrated circuit 190B. On the other hand, the input/output terminal 493 does not overlap with the integrated circuits 190A and 190B. Accordingly, the wiring connecting the acoustic wave filter and the low noise amplifier to which the inductor 44 is not connected can be shortened. Therefore, since the transmission loss and the stray capacitance of the wiring can be reduced, the noise figure of the low noise amplifiers 2H, 2J, 2K, 2L, and 2M can be improved.

In addition, since the integrated circuit 190A and the integrated circuit 190B are disposed to face each other, in a case where a switch is disposed between the low noise amplifiers 2H to 2M and 502J and the output terminal of the high frequency module 273, the wiring connecting the switch and the low noise amplifiers 2H to 2M and 502J can be shortened. Therefore, the signal output from the high frequency module 273 can be reduced in the loss.

### 22 Effects or the Like

As described above, the acoustic wave filter 1 according to the present embodiment is provided with the series arm resonator 14 (first series arm resonance unit) disposed in the series arm path connecting the input/output terminals 110 and 120, and the parallel arm resonator 23 (first parallel arm resonance unit) connected between the series arm path and the ground, each of the series arm resonator 14 and the parallel arm resonator 23 includes the acoustic wave resonator, the resonant frequency frs14 (first resonant frequency) of the series arm resonator 14 and the resonant frequency frp23 (second resonant frequency) of the parallel arm resonator 23 are equal to or lower than the low frequency end of the pass band of the acoustic wave filter 1, the anti-resonant frequency fas14 (first anti-resonant frequency) of the series arm resonator 14 and the anti-resonant frequency fap23 (second anti-resonant frequency) of the parallel arm resonator 23 are equal to or higher than the high frequency end of the pass band, the resonant frequency frs14 is higher than the resonant frequency frp23, and the anti-resonant frequency fas14 is higher than the anti-resonant frequency fap23.

Accordingly, since the impedance of the series arm resonator 14 and the parallel arm resonator 23 in the pass band is inductive, it is possible to set the impedance in the pass band of the acoustic wave filter 1 to be inductive. Therefore, in a case where the acoustic wave filter 1 is connected to an external circuit having capacitive impedance, it is possible to make the impedance of the combination of the acoustic wave filter 1 and the external circuit close to the reference impedance without necessarily adding an inductor for impedance matching. Therefore, the matching loss of the acoustic wave filter 1 and the high frequency module 100 can be reduced. Furthermore, a low impedance band of the inductive impedance band of the series arm resonator 14 overlaps with the pass band, and a high impedance band of the inductive impedance band of the parallel arm resonator 23 overlaps with the pass band. Accordingly, the insertion loss of the acoustic wave filter 1 can be reduced. Therefore, it is possible to provide the acoustic wave filter 1 in which the low loss characteristics are ensured from both the viewpoints of the matching loss and the insertion loss.

In addition, for example, the acoustic wave filter 1 is provided with a plurality of series arm resonance units and a plurality of parallel arm resonance units, the series arm resonator 14 is connected closest to the input/output terminal 120 among the plurality of series arm resonance units, and the parallel arm resonator 23 is connected closest to the input/output terminal 120 among the plurality of parallel arm resonance units.

Accordingly, in a case where the external circuit connected to the input/output terminal 120 has capacitive impedance, the acoustic wave resonance unit that exhibits inductive impedance in the pass band is disposed closest to the external circuit, so that impedance matching between the acoustic wave filter 1 and the external circuit can be performed with high efficiency and high accuracy.

In addition, for example, in the acoustic wave filter 1, the number of acoustic wave resonance units in which the resonant frequency is equal to or lower than the low frequency end of the pass band and the anti-resonant frequency is equal to or higher than the high frequency end of the pass band is larger than the number of acoustic wave resonance units in which the resonant frequency is higher than the low frequency end of the pass band or the anti-resonant frequency is lower than the high frequency end of the pass band, among the plurality of acoustic wave resonance units.

Accordingly, since the number of acoustic wave resonance units in which the impedance of the pass band is inductive is larger than the number of acoustic wave resonance units in which the impedance of the pass band is capacitive, the impedance of the pass band of the entire acoustic wave filter 1 is inductive. Therefore, impedance matching between the external circuit having capacitive impedance and the acoustic wave filter 1 can be achieved with higher accuracy. Therefore, it is possible to provide the acoustic wave filter 1 in which the matching loss is further reduced.

In addition, for example, the acoustic wave filter 1 is further provided with at least one of the capacitor 15 arranged in series in the series arm path, and the capacitor 24 arranged in series in the parallel arm path connecting the series arm path and the ground.

Accordingly, it is easy to design an acoustic wave filter having a narrow pass band using the acoustic wave resonator having a wide resonance band width.

In addition, for example, in the acoustic wave filter 1B according to Modification Example 2, the parallel arm resonance unit 20 includes the parallel arm resonator 25 and the inductor 45 which are connected in series.

Accordingly, the parallel arm resonance unit 20 having a wide resonance band can be formed without necessarily preparing the acoustic wave resonator having a resonance band wider than the above-described pass band.

In addition, for example, in the acoustic wave filter 1B, a frequency difference Δfa between the anti-resonant frequency fap20 and the high frequency end of the pass band is smaller than a frequency difference Δfr between the low frequency end of the pass band and the resonant frequency frp20.

Accordingly, a high impedance band of the inductive impedance band of the parallel arm resonance unit 20 overlaps with the pass band. Therefore, the insertion loss of the acoustic wave filter 1B can be reduced.

In addition, for example, in the acoustic wave filter 1B, the first series arm resonance unit includes the second acoustic wave resonator and the second inductor which are connected in parallel.

Accordingly, the first series arm resonance unit having a wide resonance band can be formed without necessarily preparing the acoustic wave resonator having a resonance band wider than the above-described pass band.

In addition, for example, in the acoustic wave filter 1B, a frequency difference between the first resonant frequency and the low frequency end of the pass band is smaller than a frequency difference between the high frequency end of the pass band and the first anti-resonant frequency.

Accordingly, a low impedance band of the inductive impedance band of the first series arm resonance unit overlaps with the pass band. Therefore, the insertion loss of the acoustic wave filter 1B can be reduced.

In addition, for example, in the acoustic wave filter 1B, all the acoustic wave resonators included in the acoustic wave filter 1B are formed on the same piezoelectric substrate.

Accordingly, the resonance band widths of all the acoustic wave resonators forming the pass band of the acoustic wave filter 1B can be set to be substantially the same as the pass band width. On the other hand, the parallel arm resonance unit 20 that requires a resonance band wider than the above-described pass band can be set by connecting the inductor 45 in series to the parallel arm resonator 25. Therefore, since it is optional to prepare an acoustic wave resonator having a wide resonance band width, and all the acoustic wave resonators can be integrated on one piezoelectric substrate, the acoustic wave filter 1B can be reduced in size.

In addition, the high frequency module 100 according to the present embodiment is provided with the mounting substrate 90 having the main surfaces 90a and 90b facing each other, the acoustic wave filter 1 (or 1A or 1B), and the low noise amplifier 2, the low noise amplifier 2 includes the input terminal 240, the input terminal 240 is connected to the input/output terminal 120 of the acoustic wave filter 1 without necessarily passing through the inductor, the acoustic wave filter 1 is disposed on the main surface 90a, the low noise amplifier 2 is disposed on the main surface 90b, and in a case where the mounting substrate 90 is viewed in a plan view, the acoustic wave filter 1 and the low noise amplifier 2 at least partially overlap with each other.

Accordingly, since the wiring connecting the acoustic wave filter 1 and the low noise amplifier 2 can be shortened, the high frequency module 100 can be reduced in the loss and size.

In addition, in the high frequency module 100, in a case where the mounting substrate 90 is viewed in a plan view, the input/output terminal 120 and the input terminal 240 at least partially overlap with each other.

Accordingly, since the acoustic wave filter 1 and the low noise amplifier 2 can be connected to each other only through the via conductor 300, the high frequency module 100 can be further reduced in the loss.

In addition, for example, the high frequency module 200 according to Modification Example 3 is provided with the acoustic wave filter 6A having the input/output terminals 251 and 261, the acoustic wave filter 6C having the input/output terminals 253 and 263, the low noise amplifier 2A having the input terminal 131, and the low noise amplifier 2C having the input terminal 133, the acoustic wave filters 6A and 6C have the same configuration as that of the acoustic wave filter 1 (or 1A or 1B), the input terminal 131 is connected to the input/output terminal 261 without necessarily passing through the inductor, the input terminal 132 is connected to the input/output terminal 262 without necessarily passing through the inductor, the acoustic wave filter 6A is included in the filter integrated component 211, the acoustic wave filter 6C is included in the filter integrated component 212, the filter integrated components 211 and 212 are disposed on the main surface 90a, the low noise amplifiers 2A and 2C are disposed on the main surface 90b, the main surface 90a includes the first outer peripheral region and the first central region located inside the first outer peripheral region, the main surface 90b includes the second outer peripheral region and the second central region located inside the second outer peripheral region, the input/output terminals 261 and 263 are disposed in the first central region, the low noise amplifiers 2A and 2C are disposed in the second central region, in a case where the mounting substrate 90 is viewed in a plan view, the input/output terminal 261 overlaps with the low noise amplifier 2A, the input/output terminal 263 overlaps with the low noise amplifier 2C, the input/output terminal 251 is disposed on the outer peripheral side with respect to the input/output terminal 261, and the input/output terminal 253 is disposed on the outer peripheral side with respect to the input/output terminal 263.

Accordingly, since the input/output terminals 261 and 263 are disposed to overlap with the low noise amplifiers 2A and 2C in the plan view, the wiring connecting the input/output terminals 261 and 263 and the low noise amplifiers 2A and 2C can be shortened. As a result, since the transmission loss and the stray capacitance of the wiring can be reduced, the noise figure of the low noise amplifiers 2A and 2C can be improved.

In addition, for example, the high frequency module 202 (203 or 204) according to Modification Example 4 (or Modification Example 5 or 6) is provided with the acoustic wave filter 6A having the input/output terminals 251 and 261, the acoustic wave filter 6C having the input/output terminals 253 and 263, the low noise amplifier 2A having the input terminal 131, and the low noise amplifier 2C having the input terminal 133, the acoustic wave filters 6A and 6C have the same configuration as that of the acoustic wave filter 1 (or 1A or 1B), the input terminal 131 is connected to the input/output terminal 261 without necessarily passing through the inductor, the input terminal 132 is connected to the input/output terminal 262 without necessarily passing through the inductor, the acoustic wave filter 6A is included in the filter integrated component 211, the acoustic wave filter 6C is included in the filter integrated component 212, the low noise amplifiers 2A and 2C are included in the integrated circuit 210A (210B), the filter integrated component 211 and the integrated circuit 210A (210B) are disposed on the main surface 90a in the order of the mounting substrate 90, the integrated circuit 210A (210B), and the filter integrated component 211, the filter integrated component 213 and the integrated circuit 210A (210B) are disposed on the main surface 90a in the order of the mounting substrate 90, the integrated circuit 210A (210B), and the filter integrated component 213, the main surface 90a includes the first outer peripheral region and the first central region located inside the first outer peripheral region, the input/output terminals 261 and 263 and the low noise amplifiers 2A and 2C are disposed in the first central region, and in a case where the mounting substrate 90 is viewed in a plan view, the input/output terminal 261 overlaps with the low noise amplifier 2A, the input/output terminal 263 overlaps with the low noise amplifier 2C, the input/output terminal 251 is disposed on the outer peripheral side with respect to the input/output terminal 261, and the input/output terminal 253 is disposed on the outer peripheral side with respect to the input/output terminal 263.

Accordingly, since the input/output terminals 261 and 263 are disposed to overlap with the low noise amplifiers 2A and 2C in the plan view, the wiring connecting the input/output terminals 261 and 263 and the low noise amplifiers 2A and 2C can be shortened. As a result, since the transmission loss and the stray capacitance of the wiring can be reduced, the noise figure of the low noise amplifiers 2A and 2C can be improved.

In addition, for example, in the high frequency module 203 according to Modification Example 5, the filter integrated component 211 has the main surfaces 211a and 211b facing each other, the filter integrated component 213 has the main surfaces 213a and 213b facing each other, the integrated circuit 210B has the main surfaces 210a and 210b facing each other, the main surface 210a faces the main surface 90a, the main surfaces 211a and 213a face the main surface 210b, the input/output terminal 261 is disposed on the main surface 211a, the input/output terminal 263 is disposed on the main surface 213a, and the input terminals 131 and 133 are disposed on the main surface 210b.

Accordingly, since it is optional to form the via conductors connecting the input/output terminals 261 and 263 and the input terminals 131 and 133 in the integrated circuit 210B, the integrated circuit 210B can be reduced in size.

In addition, for example, the high frequency module 200 (202, 203, or 204) according to Modification Example 3 (or Modification Examples 4, 5, or 6) is further provided with the antenna connection terminal 150 and the switch 221 that switches the connection of the antenna connection terminal 150 and the input/output terminal 251 and connection of the antenna connection terminal 150 and the input/output terminal 253, and in a case where the mounting substrate 90 is viewed in a plan view, the switch 221 is disposed on the outer peripheral side with respect to the input/output terminals 251 and 253.

Accordingly, in the plan view, since the input/output terminals 251 and 253 are disposed on the outer peripheral side with respect to the input/output terminals 261 and 263, and the switch 221 is disposed in the second outer peripheral region, the wirings connecting the input/output terminals 251 and 253 and the switch 221 can be shortened. As a result, since the transmission loss and the stray capacitance of the wiring can be reduced, impedance matching between the antenna and the acoustic wave filters 6A and 6C can be achieved with high accuracy.

In addition, for example, the high frequency module 151 according to Modification Example 7 (or Modification Example 8 or 9) is provided with the acoustic wave filter 3A having the input/output terminals 113 and 123, the acoustic wave filter 503A having the input/output terminals 513 and 523, the low noise amplifier 2A having the input terminal 133, the low noise amplifier 502A having the input terminal 533, and the inductor 41, the acoustic wave filter 3A has the same configuration as that of the acoustic wave filter 1 (or 1A or 1B), the input terminal 133 is connected to the input/output terminal 123 without necessarily passing through the inductor, the input terminal 533 is connected to the input/output terminal 523 with the inductor 41 interposed therebetween, the acoustic wave filters 3A and 503A are included in the filter integrated component 181, the low noise amplifiers 2A and 502A are included in the integrated circuit 182, the filter integrated component 181 has the main surfaces 181a and 181b, the main surface 181b is disposed on the mounting substrate 90 to face the main surface 90a, the integrated circuit 182 is disposed on the main surface 90b, and in a case where the mounting substrate 90 is viewed in a plan view, the filter integrated component 181 and the integrated circuit 182 at least partially overlap with each other.

Accordingly, since the acoustic wave filters 3A and 503A and the low noise amplifiers 2A and 502A are distributed and disposed on the main surfaces 90a and 90b of the mounting substrate 90, and the filter integrated component 181 and the integrated circuit 182 are disposed to overlap with each other, the high frequency module 151 can be reduced in size.

In addition, for example, in the high frequency module 151 (152) according to Modification Example 7 (or Modification Examples 8, 9, or 10), the main surface 181b includes the outer peripheral region Rp1 and the central region Rc1 located inside the outer peripheral region Rp1, the input/output terminal 123 is disposed in the central region Rc1, and the input/output terminal 523 is disposed in the outer peripheral region Rp1.

Accordingly, since the filter integrated component 181 and the integrated circuit 182 overlap with each other in the plan view, and the input/output terminal 123 is disposed in the central region Rc1, the wiring connecting the acoustic wave filter 3A and the low noise amplifier 2A can be shortened. Therefore, since the transmission loss and the stray capacitance of the above-described wiring can be reduced, the noise figure of the low noise amplifier 2A can be improved.

In addition, for example, in the high frequency module according to Modification Example 11, the filter integrated component 181C includes a filter chip 383 including the acoustic wave filter 3A and having a main surface 383b, and a filter chip 783 including the acoustic wave filter 503A and having a main surface 783b, and the filter chip 383 and the filter chip 783 are stacked.

Accordingly, since the acoustic wave filters 3A and 503A are accommodated in the filter integrated component 181C having the multilayer structure, the high frequency module according to the present modification example can be reduced in size.

In addition, for example, in the high frequency module 151 according to Modification Example 7, the integrated circuit 182 has main surfaces 182a and 182b, and is disposed on the mounting substrate 90 such that the main surface 182a faces the main surface 90b, the main surface 182a includes the outer peripheral region Rp2 and the central region Rc2 located inside the outer peripheral region Rp2, the input terminal 133 is disposed in the central region Rc2, and the input terminal 533 is disposed in the outer peripheral region Rp2.

Accordingly, since the filter integrated component 181 and the integrated circuit 182 overlap with each other in the plan view, and the input terminal 133 is disposed in the central region Rc2, the wiring connecting the acoustic wave filter 3A and the low noise amplifier 2A can be shortened.

In addition, for example, in the high frequency module 153 according to Modification Example 12, the high frequency module 153 is provided with the acoustic wave filter 3B having the common terminal 114 and the input/output terminal 123, the acoustic wave filter 503B having the common terminal 114 and the input/output terminal 523, the low noise amplifier 2B having the input terminal 133, the low noise amplifier 502B having the input terminal 533, and the inductor 41, the acoustic wave filter 3B has the same configuration as that of the acoustic wave filter 1 (or 1A or 1B), the input terminal 133 is connected to the input/output terminal 123 without necessarily passing through the inductor, the input terminal 533 is connected to the input/output terminal 523 with the inductor 41 interposed therebetween, and the acoustic wave filters 3B and 503B are multiplexers in which the input/output terminals are shared as the common terminal 114.

Accordingly, the high frequency module 153 can simultaneously transmit the signal of the band A and the signal of the band B.

In addition, for example, in the high frequency module 153 according to Modification Example 12, the input/output terminal 123, the input/output terminal 523, and the common terminal 114 are disposed on the main surface 185b, and the distance D3 between the input/output terminal 123 and the common terminal 114 is shorter than the distance D503 between the input/output terminal 523 and the common terminal 114.

Accordingly, since the distance between the input/output terminal 523 to which the inductor 41 is connected and the common terminal 114 can be ensured, it is possible to reduce the interference between the signals input to the acoustic wave filters 3B and 503B and the signal output from the acoustic wave filter 503B. Therefore, the deterioration of isolation between the input/output of the multiplexer configured with the acoustic wave filters 3B and 503B can be reduced.

In addition, for example, in the high frequency module 154 according to Modification Example 13, the acoustic wave filter 3C has a pass band including at least a part of a band A, and the acoustic wave filter 503C has a pass band including at least a part of a band B located on the high frequency side with respect to a band A.

From the viewpoint of impedance matching between the low noise amplifier and the acoustic wave filter, as the corresponding frequency of the transmission path is lower, it is suitable to increase the inductance value of the inductor disposed in the transmission path, and the resistance component of the inductor is increased. From this viewpoint, in the high frequency module 154 according to the present modification example, the inductor 41 is disposed in the transmission path (band B) having a higher corresponding frequency, without necessarily disposing the inductor in the transmission path (band A) having a lower corresponding frequency, among the two transmission paths for simultaneous transmission. Accordingly, since the transmission loss of the wiring connecting the acoustic wave filter and the low noise amplifier can be reduced, the noise figure of the low noise amplifier 2C can be improved.

In addition, for example, the high frequency module 271 according to Modification Example 20 is provided with the acoustic wave filter 3G having the input/output terminals 281 and 291, the acoustic wave filter 503G having the input/output terminals 481 and 491, the low noise amplifier 2G having the input terminal 133, the low noise amplifier 502G having the input terminal 533, and the inductor 41, the acoustic wave filter 3G has the same configuration as that of the acoustic wave filter 1 (or 1A or 1B), the input terminal 133 is connected to the input/output terminal 291 without necessarily passing through the inductor, the input terminal 533 is connected to the input/output terminal 491 with the inductor 41 interposed therebetween, the acoustic wave filters 3G and 503G are disposed on the main surface 90a, the low noise amplifiers 2G and 502G are disposed on the main surface 90b, and in a case where the mounting substrate 90 is viewed in a plan view, the input/output terminal 291 overlaps with the low noise amplifier 2G, and the input/output terminal 491 does not overlap with the low noise amplifiers 2G and 502G.

Accordingly, the input/output terminal 291 connected to the low noise amplifier 2G without necessarily passing through the inductor is disposed close to the low noise amplifier 2G, and the input/output terminal 491 connected to the low noise amplifier 502G with the inductor 41 interposed therebetween is connected away from the low noise amplifier 502G. As a result, the wiring connecting the acoustic wave filter 3G to which the inductor 41 is not connected and the low noise amplifier 2G can be shortened. Therefore, since the transmission loss and the stray capacitance of the wiring can be reduced, the noise figure of the low noise amplifier 2G can be improved.

In addition, for example, the high frequency module 158 according to Modification Example 17 is provided with the mounting substrate 90 having the main surfaces 90a and 90b facing each other, the acoustic wave filter 5A having the input/output terminals 144 and 164, the acoustic wave filter 504A having the input/output terminals 551 and 561, the low noise amplifier 7D having the input terminal 174, the low noise amplifier 507A having the input terminal 571, and the inductor 41A, the acoustic wave filter 5A has the same configuration as that of the acoustic wave filter 1 (or 1A or 1B), the input terminal 174 is connected to the input/output terminal 164 without necessarily passing through the inductor, the input terminal 571 is connected to the input/output terminal 561 with the inductor 41A interposed therebetween, the acoustic wave filter 5A and 504A, and the low noise amplifier 7D and 507A are disposed on the main surface 90a, and the distance between the input/output terminal 164 and the input terminal 174 is shorter than the distance between the input/output terminal 561 and the input terminal 571.

Accordingly, the wiring connecting the acoustic wave filter 5A and the low noise amplifier 7D can be shortened. Therefore, since the transmission loss and the stray capacitance of the wiring can be reduced, the noise figure of the low noise amplifier 7D can be improved.

In addition, for example, in the high frequency module 159 according to Modification Example 18, the low noise amplifiers 7D and 507A are included in the integrated circuit 190, the integrated circuit 190 has main surfaces 190a and 190b, and is disposed on the mounting substrate 90 such that the main surface 190b faces the main surface 90a, the main surface 190b includes a first outer peripheral region and a first central region located inside the first outer peripheral region, the input terminal 174 is disposed in the first outer peripheral region, and the input terminal 571 is disposed in the first central region.

Accordingly, the wiring connecting the acoustic wave filter 5A and the low noise amplifier 7D to which the inductor 41A is not connected can be shortened. Therefore, since the transmission loss and the stray capacitance of the wiring can be reduced, the noise figure of the low noise amplifier 7D can be improved.

### OTHER EMBODIMENTS

Hereinbefore, the acoustic wave filter and the high frequency module according to the present disclosure have been described with reference to the embodiment and the modification examples, and the present disclosure is not limited to the above-described embodiment and modification examples. The present disclosure also includes modification examples obtained by subjecting various modifications that can be conceived by those skilled in the art to the above-described embodiments and modification examples within the scope not departing from the spirit of the present disclosure, as well as various devices incorporating the acoustic wave filter and the high frequency module according to the present disclosure.

In addition, for example, in the acoustic wave filter and the high frequency module according to the embodiment and the modification example described above, a matching element such as an inductor and a capacitor, and a switch circuit may be connected between each of the components.

Hereinafter, the characteristics of the acoustic wave filter and the high frequency module described based on the above-described embodiment and modification examples will be illustrated.

<1> An acoustic wave filter that is a band pass type acoustic wave filter, the filter including a first series arm resonance unit disposed in a series arm path connecting a first input/output terminal and a second input/output terminal, and a first parallel arm resonance unit connected between the series arm path and a ground, in which each of the first series arm resonance unit and the first parallel arm resonance unit includes an acoustic wave resonator, a first resonant frequency, which is a resonant frequency of the first series arm resonance unit, and a second resonant frequency, which is a resonant frequency of the first parallel arm resonance unit, are equal to or lower than a low frequency end of a pass band of the acoustic wave filter, a first anti-resonant frequency, which is an anti-resonant frequency of the first series arm resonance unit, and a second anti-resonant frequency, which is an anti-resonant frequency of the first parallel arm resonance unit, are equal to or higher than a high frequency end of the pass band, and the first resonant frequency is higher than the second resonant frequency, and the first anti-resonant frequency is higher than the second anti-resonant frequency.

<2> The acoustic wave filter according to <1>, further including a plurality of series arm resonance units that includes the first series arm resonance unit, and a plurality of parallel arm resonance units that includes the first parallel arm resonance unit, in which the first series arm resonance unit is connected closest to the first input/output terminal among the plurality of series arm resonance units, and the first parallel arm resonance unit is connected closest to the first input/output terminal among the plurality of parallel arm resonance units.

<3> The acoustic wave filter according to <1>, further including a plurality of acoustic wave resonance units that includes the first series arm resonance unit and the first parallel arm resonance unit, in which among the plurality of acoustic wave resonance units, the number of acoustic wave resonance units in which a resonant frequency is equal to or lower than the low frequency end of the pass band and an anti-resonant frequency is equal to or higher than the high frequency end of the pass band is larger than the number of acoustic wave resonance units in which a resonant frequency is higher than the low frequency end of the pass band or an anti-resonant frequency is lower than the high frequency end of the pass band.

<4> The acoustic wave filter according to any one of <1> to <3>, further including at least one of a first capacitor that is arranged in series in the series arm path, and a second capacitor that is arranged in series in a parallel arm path connecting the series arm path and the ground.

<5> The acoustic wave filter according to any one of <1> to <4>, in which the first parallel arm resonance unit includes a first acoustic wave resonator and a first inductor which are connected in series.

<6> The acoustic wave filter according to <5>, in which a frequency difference between the second anti-resonant frequency and the high frequency end of the pass band is smaller than a frequency difference between the low frequency end of the pass band and the second resonant frequency.

<7> The acoustic wave filter according to any one of <1> to <4>, in which the first series arm resonance unit includes a second acoustic wave resonator and a second inductor which are connected in parallel.

<8> The acoustic wave filter according to <7>, in which a frequency difference between the first resonant frequency and the low frequency end of the pass band is smaller than a frequency difference between the high frequency end of the pass band and the first anti-resonant frequency.

<9> The acoustic wave filter according to any one of <1> to <8>, further including a plurality of acoustic wave resonance units that includes the first series arm resonance unit and the first parallel arm resonance unit, in which each of the plurality of acoustic wave resonance units includes an acoustic wave resonator, and all the acoustic wave resonators included in the acoustic wave filter are formed on the same piezoelectric substrate.

<10> A high frequency module including a mounting substrate that has a first main surface and a second main surface facing each other, the acoustic wave filter according to any one of <1> to <9>, and a low noise amplifier in which an input terminal is connected to a first input/output terminal, in which the acoustic wave filter is disposed on the first main surface, the low noise amplifier is disposed on the second main surface, and in a plan view of the mounting substrate, the acoustic wave filter and the low noise amplifier at least partially overlap with each other.

<11> The high frequency module according to <10>, in which in a case where the mounting substrate is viewed in a plan view, the first input/output terminal and the input terminal at least partially overlap with each other.

### Industrial Availability

The present disclosure can be widely used as a low-loss acoustic wave filter and a high frequency module that can be applied to a multi-band frequency standard, in communication devices such as a mobile phone.

What is claimed is:

1. An acoustic wave filter that is a band pass type acoustic wave filter, the filter comprising:
a first series arm resonance circuit in a series arm path connecting a first input/output terminal and a second input/output terminal, the first series arm resonance circuit having a first resonant frequency and a first anti-resonant frequency; and
a first parallel arm resonance circuit connected between the series arm path and a ground, the first parallel arm resonance circuit having a first resonant frequency and a first anti-resonant frequency,
wherein the first series arm resonance circuit and the first parallel arm resonance circuit each comprises an acoustic wave resonator,
wherein the first resonant frequency and the second resonant frequency are equal to or lower than a low frequency end of a pass band of the acoustic wave filter,
wherein the first anti-resonant frequency and the second anti-resonant frequency are equal to or higher than a high frequency end of the pass band, and
wherein the first resonant frequency is higher than the second resonant frequency, and the first anti-resonant frequency is higher than the second anti-resonant frequency.

2. The acoustic wave filter according to claim 1, further comprising:
a plurality of series arm resonance circuits including the first series arm resonance circuit; and
a plurality of parallel arm resonance circuits including the first parallel arm resonance circuit,
wherein, among the plurality of series arm resonance circuits, the first series arm resonance circuit element is connected closest to the first input/output terminal, and
wherein, among the plurality of parallel arm resonance circuits, the first parallel arm resonance circuit is connected closest to the first input/output terminal.

3. The acoustic wave filter according to claim 1, further comprising:
a plurality of acoustic wave resonance circuits including the first series arm resonance circuit and the first parallel arm resonance circuit,
wherein among the plurality of acoustic wave resonance circuits, the number of acoustic wave resonance circuits in which a resonant frequency is equal to or lower than the low frequency end of the pass band and an anti-resonant frequency is equal to or higher than the high frequency end of the pass band is larger than the number of acoustic wave resonance circuits in which a resonant frequency is higher than the low frequency end of the pass band or an anti-resonant frequency is lower than the high frequency end of the pass band.

4. The acoustic wave filter according to claim 1, further comprising:
a first capacitor that is in series in the series arm path, or a second capacitor that is in series in a parallel arm path connecting the series arm path to ground.

5. The acoustic wave filter according to claim 1, wherein the first parallel arm resonance circuit comprises a first acoustic wave resonator and a first inductor connected in series.

6. The acoustic wave filter according to claim 5, wherein a frequency difference between the second anti-resonant frequency and the high frequency end of the pass band is smaller than a frequency difference between the low frequency end of the pass band and the second resonant frequency.

7. The acoustic wave filter according to claim 1, wherein the first series arm resonance circuit comprises a second acoustic wave resonator and a second inductor connected in parallel.

8. The acoustic wave filter according to claim 7, wherein a frequency difference between the first resonant frequency and the low frequency end of the pass band is smaller than a frequency difference between the high frequency end of the pass band and the first anti-resonant frequency.

9. The acoustic wave filter according to claim 1, further comprising:
a plurality of acoustic wave resonance circuits including the first series arm resonance circuit and the first parallel arm resonance circuit,
wherein each of the plurality of acoustic wave resonance circuits comprises an acoustic wave resonator, and
wherein all the acoustic wave resonators included in the acoustic wave filter are formed on the same piezoelectric substrate.

10. A high frequency module comprising:
a mounting substrate that has a first main surface and a second main surface facing each other;
a first acoustic wave filter according to claim 1; and
a first low noise amplifier,
wherein the first low noise amplifier comprises a first input terminal,
wherein the first input terminal is connected to the first input/output terminal of the first acoustic wave filter without passing through an inductor,
wherein the first acoustic wave filter is on the first main surface,
wherein the first low noise amplifier is on the second main surface, and
wherein when the mounting substrate is viewed in a plan view, the first acoustic wave filter and the first low noise amplifier at least partially overlap with each other.

11. The high frequency module according to claim 10, wherein when the mounting substrate is viewed in the plan view, the first input/output terminal and the first input terminal at least partially overlap with each other.

12. The high frequency module according to claim 10, further comprising:
a second acoustic wave filter comprising a third input/output terminal and a fourth input/output terminal; and
a second low noise amplifier comprising a second input terminal,
wherein the second input terminal is connected to the third input/output terminal of the second acoustic wave filter without passing through an inductor,
wherein the first acoustic wave filter is in a first integrated component,
wherein the second acoustic wave filter is in a second integrated component,
wherein the first integrated component and the second integrated component are on the first main surface,
wherein the first low noise amplifier and the second low noise amplifier are on the second main surface,
wherein the first main surface includes a first outer peripheral region and a first central region located inside the first outer peripheral region,
wherein the second main surface includes a second outer peripheral region and a second central region located inside the second outer peripheral region,
wherein the first input/output terminal and the third input/output terminal are in the first central region,
wherein the first low noise amplifier and the second low noise amplifier are in the second central region, and
wherein when the mounting substrate is viewed in the plan view, the first input/output terminal overlaps with the first low noise amplifier, the third input/output terminal overlaps with the second low noise amplifier, the second input/output terminal is on an outer peripheral side with respect to the first input/output terminal, and the fourth input/output terminal is on an outer peripheral side with respect to the third input/output terminal.

13. The high frequency module according to claim 10, further comprising:
a second acoustic wave filter comprising a third input/output terminal and a fourth input/output terminal; and
a second low noise amplifier comprising a second input terminal,
wherein the second input terminal is connected to the third input/output terminal of the second acoustic wave filter without passing through an inductor,
the first acoustic wave filter is in a first integrated component,
the second acoustic wave filter is in a second integrated component,
the first low noise amplifier and the second low noise amplifier are in a third integrated component,
wherein the first integrated component and the third integrated component are on the first main surface in a vertical order of the mounting substrate, the third integrated component, and the first integrated component,
wherein the second integrated component and the third integrated component are on the first main surface in a vertical order of the mounting substrate, the third integrated component, and the second integrated component,
wherein the first main surface includes a first outer peripheral region and a first central region located inside the first outer peripheral region,
wherein the first input/output terminal, the third input/output terminal, the first low noise amplifier, and the second low noise amplifier are in the first central region, and
wherein when the mounting substrate is viewed in the plan view, the first input/output terminal overlaps with the first low noise amplifier, the third input/output terminal overlaps with the second low noise amplifier, the second input/output terminal is on an outer peripheral side with respect to the first input/output terminal, and the fourth input/output terminal is on an outer peripheral side with respect to the third input/output terminal.

14. The high frequency module according to claim 13,
wherein the first integrated component has a third main surface and a fourth main surface facing each other,
wherein the second integrated component has a fifth main surface and a sixth main surface facing each other,
wherein the third integrated component has a seventh main surface and an eighth main surface facing each other,
wherein the seventh main surface faces the first main surface,
wherein the third main surface and the fifth main surface face the eighth main surface,
wherein the first input/output terminal is on the third main surface,
wherein the third input/output terminal is on the fifth main surface, and
wherein the first input terminal and the second input terminal are on the eighth main surface.

15. The high frequency module according to claim 12, further comprising:
an antenna connection terminal; and
a first switch configured to selectively connect the antenna connection terminal and the second input/output terminal, and selectively connect the antenna connection terminal and the fourth input/output terminal,
wherein when the mounting substrate is viewed in the plan view, the first switch is on an outer peripheral side with respect to the first input/output terminal and the third input/output terminal.

16. The high frequency module according to claim 10, further comprising:
a second acoustic wave filter comprising a third input/output terminal and a fourth input/output terminal;
a second low noise amplifier comprising a second input terminal; and
a third inductor,
wherein the second input terminal is connected to the third input/output terminal with the third inductor interposed therebetween,
the first acoustic wave filter and the second acoustic wave filter are in a first integrated component,
the first low noise amplifier and the second low noise amplifier are in a second integrated component,
wherein the first integrated component has a third main surface and a fourth main surface, and is on the mounting substrate such that the third main surface faces the first main surface,
wherein the second integrated component is on the second main surface, and
wherein when the mounting substrate is viewed in the plan view, the first integrated component and the second integrated component at least partially overlap with each other.

17. The high frequency module according to claim 16,
wherein the third main surface includes a first outer peripheral region and a first central region located inside the first outer peripheral region,
wherein the first input/output terminal is in the first central region, and
wherein the third input/output terminal is in the first outer peripheral region.

18. The high frequency module according to claim 16,
wherein the first integrated component comprises:
a first filter chip comprising the first acoustic wave filter, and that has the fourth main surface, and
a second filter chip comprising the second acoustic wave filter, and that has the third main surface, and
wherein the first filter chip and the second filter chip are stacked.

19. The high frequency module according to claim 16,
wherein the second integrated component has a fifth main surface and a sixth main surface, and is on the mounting substrate such that the fifth main surface faces the second main surface,
wherein the fifth main surface includes a second outer peripheral region and a second central region located inside the second outer peripheral region,
wherein the first input terminal is in the second central region, and
wherein the second input terminal is in the second outer peripheral region.

20. The high frequency module according to claim 16, wherein the first acoustic wave filter and the second acoustic wave filter are multiplexers in which the second input/output terminal and the fourth input/output terminal are shared as a first common terminal.
